(19) United States
(12) Patent Application Publication
(10) Pub. No.: US 2025/0014890 A1
(43) Pub. Date: Jan. 9, 2025

(54) CONFORMAL, CARBON-DOPED SILICON NITRIDE FILMS AND METHODS THEREOF

(71) Applicant: Lam Research Corporation, Fremont, CA (US)

(72) Inventors: Awnish Gupta, Hillsboro, OR (US); Bart J. Van Schravendijk, Palo Alto, CA (US); Jon Henri, West Linn, OR (US); Oksana Savchak, Tualatin, OR (US); Fengyan Wei, Meridian, ID (US); Easwar Srinivasan, Portland, OR (US); Dustin Zachary Austin, Tigard, OR (US)

(21) Appl. No.: 18/709,780

(22) PCT Filed: Nov. 30, 2022
(86) PCT No.: PCT/US2022/080683

§ 371 Date: May 13, 2024

Related U.S. Application Data
(60) Provisional application No. 63/264,932, filed on Dec. 3, 2021.

(51) Int. Cl. H01L 21/02; C07F 7/18; C23C 16/34; C23C 16/455

(52) U.S. Cl. CPC H01L 21/0217; C07F 7/1804; C23C 16/345; C23C 16/45536; C23C 16/45553; H01L 21/02211; H01L 21/0228

(57) ABSTRACT

The present disclosure relates to methods for providing a silicon nitride film. In particular, the film can be a carbon-doped, silicon nitride film. Methods can include depositing a doped silicon nitride and then plasma treating the doped silicon nitride to provide a conformal film.

### RELATED APPLICATIONS

A PCT Request Form is filed concurrently with this specification as part of the present application. Each application that the present application claims benefit of or priority to as identified in the concurrently filed PCT Request Form is incorporated by reference herein in its entirety.

### FIELD

The present disclosure relates to methods for providing a silicon nitride film. In particular, the film can be a carbon-doped, silicon nitride film. Methods can include depositing a doped silicon nitride and then plasma treating the doped silicon nitride to provide a conformal film.

### BACKGROUND

Typically, conformal deposition of silicon nitride includes the use of furnace-based thermal processes with halosilane-based precursors. The presence of halogen atoms in the precursor can, in some instances, provide halogen as an undesired impurity within the deposited film.

The background description provided herein is for the purpose of generally presenting the context of the present technology. Work of the presently named inventors, to the extent it is described in this background section, as well as aspects of the description that may not otherwise qualify as prior art at the time of filing, are neither expressly nor impliedly admitted as prior art against the present technology.

### SUMMARY

The present disclosure relates to methods of depositing a doped silicon nitride and then plasma treating the doped silicon nitride. In some instances, this method provides a conformal film including a carbon-doped silicon nitride. The presence of carbon can provide film having beneficial Si—C defects, which can act as high energy electron traps. Such traps can be useful, for example, within a trapping layer in memory cells. In other embodiments, the film can be used in a device (e.g., a solar cell). The presence of carbon can provide a film having a decreased wet etch rate. In one embodiment, the film can be employed as an etch stop layer, in which carbon-doped silicon nitride can have a decreased wet etch rate, as compared to silicon nitride alone. Additional uses are described herein.

In some embodiments, the method is characterized as a hybrid atomic layer deposition (hybrid ALD) process, which includes thermal ALD conversion followed by plasma treatment within every cycle. For instance, thermal ALD conversion can include converting a deposited carbon- and silicon-containing layer in the presence of a nitrogen-containing reactant to form a doped silicon nitride. Furthermore, plasma treatment can include exposing the doped silicon nitride to an energetic species obtained from a source gas. In some embodiments, the energetic species can include a nitrogen atom. In other embodiments, the energetic species can include a radical.

In non-limiting embodiments, the methods herein avoid the presence of halogen within the film by avoiding deposition precursors having halogen atoms. In particular embodiments, the deposition precursor is an organic silicon-containing precursor. Such precursors typically include at least one silicon atom and at least one carbon atom. Non-limiting examples of precursors are described herein.

In a first aspect, the present disclosure encompasses a method of depositing a film. In some embodiments, the method includes: exposing a substrate within a chamber to an organic silicon-containing precursor; exposing the substrate to a nitrogen-containing reactant; and

exposing the substrate to an energetic species, thereby forming a film comprising silicon nitride. In particular embodiments, the energetic species is a radical species.

In some embodiments, the film includes a doped silicon nitride. In particular embodiments, the doped silicon nitride includes carbon-doped silicon nitride. In other embodiments, the film includes a conformal film. In further embodiments, the substrate includes a high aspect ratio (HAR) structure, wherein the conformal film is deposited on a surface of said HAR structure.

In some embodiments, the organic silicon-containing precursor includes a structure of formula (I):

Si(R′)₄,
wherein at least one R′ includes a carbon atom.

In other embodiments, the organic silicon-containing precursor includes a structure of formula (II):

(R′)₃Si-[L-Si(R′)₂]—R′,
wherein at least one R′ includes a carbon atom and L is a linker.

In some embodiments, the nitrogen-containing reactant includes ammonia (NH₃), singly deuterated ammonia (NH₂D), doubly deuterated ammonia (NHD₂), or triply deuterated ammonia (ND₃).

In some embodiments, said exposing the substrate to the nitrogen-containing reactant includes providing the nitrogen-containing reactant in the presence of hydrogen (H₂).

In other embodiments, said exposing the substrate to an energetic species (e.g., a radical species) includes a source gas selected from the group of ammonia (NH₃), nitrogen (N₂), hydrogen (H₂), or a combination thereof. In particular embodiments, the energetic species includes a nitrogen-containing energetic species or a nitrogen-containing radical in a remote plasma.

In some embodiments, the method further includes purging the chamber with an inert gas after said exposing the substrate to the organic silicon-containing precursor, said exposing the substrate to the nitrogen-containing reactant, and/or said exposing the substrate to the energetic species. In other embodiments, the method further includes repeating said exposing the substrate to the organic silicon-containing precursor, said exposing the substrate to the nitrogen-containing reactant, and said exposing the substrate to the energetic species in cycles to form the film.

In other embodiments, the method includes a remote plasma-based atomic layer deposition process.

In a second aspect, the present disclosure encompasses a method of depositing a film, the method including: depositing a carbon- and silicon-containing layer on a surface of a substrate, wherein the substrate is provided within a chamber; thermally converting the carbon- and silicon-containing layer in the presence of a nitrogen-containing reactant to form a doped silicon nitride; and plasma treating the doped silicon nitride in the presence of a source gas, thereby forming the film.

In some embodiments, said depositing includes exposing the surface of the substrate within a chamber to an organic silicon-containing precursor. In particular embodiments, the organic silicon-containing precursor includes a structure of formula (I), (II), or any formula described herein.

In some embodiments, said thermally converting includes exposing the surface of the substrate to a nitrogen-containing reactant. Non-limiting examples of nitrogen-containing reactants include ammonia (NH₃) and can optionally be employed with hydrogen (H₂).

In some embodiments, said plasma treating includes exposing the substrate to an energetic species (e.g., a radical species) within a source gas. Non-limiting energetic species can include a nitrogen-containing energetic species or a nitrogen-containing radical. In some embodiments, the source gas is selected from ammonia (NH₃), nitrogen (N₂), hydrogen (H₂), or a combination thereof.

In some embodiments, the method further includes purging the chamber with an inert gas after said depositing, said thermally converting, and/or said plasma treating. In other embodiments, the method further includes repeating said depositing, said thermally converting, and said plasma treating in cycles to form the film.

In any embodiment herein, the film includes a conformal, carbon-doped silicon nitride film.

In any embodiment herein, the substrate includes a high aspect ratio (HAR) structure.

In some embodiments, a film (e.g., a conformal, carbon-doped silicon nitride film) is deposited on a surface of said HAR structure.

In any embodiment herein, the organic silicon-containing precursor includes any formula described herein.

Additional embodiments are described herein.

### Definitions

The term “acyl,” or “alkanoyl,” as used interchangeably herein, represents groups of 1, 2, 3, 4, 5, 6, 7, 8 or more carbon atoms of a straight, branched, cyclic configuration, saturated, unsaturated and aromatic, and combinations thereof, or hydrogen, attached to the parent molecular group through a carbonyl group, as defined herein. This group is exemplified by formyl (—C(O)H), acetyl (Ac or —C(O)Me), propionyl, isobutyryl, butanoyl, and the like. In some embodiments, the acyl or alkanoyl group is —C(O)—R, in which R is hydrogen, an aliphatic group, or an aromatic group, as defined herein.

By “alkanoyloxy” is meant an alkanoyl group, as defined herein, attached to the parent molecular group through an oxy group, as defined herein. This group is exemplified by acetoxy (—OAc or —OC(O)Me). In some embodiments, the alkanoyloxy group is —OC(O)—R, in which R is hydrogen, an aliphatic group, or an aromatic group, as defined herein.

By “aliphatic” is meant a hydrocarbon group having at least one carbon atom to 50 carbon atoms (C₁₋₅₀), such as one to 25 carbon atoms (C₁₋₂₅), or one to ten carbon atoms (C₁₋₁₀), and which includes alkanes (or alkyl), alkenes (or alkenyl), alkynes (or alkynyl), including cyclic versions thereof, and further including straight- and branched-chain arrangements, and all stereo and position isomers as well. An aliphatic group is unsubstituted or substituted, e.g., by a functional group described herein. For example, the aliphatic group can be substituted with one or more substitution groups, as described herein for alkyl.

By “aliphatic-carbonyl” is meant an aliphatic group that is or can be coupled to a compound disclosed herein, wherein the aliphatic group is or becomes coupled through a carbonyl group (—C(O)—). In some embodiments, the aliphatic-carbonyl group is —C(O)—R, in which R is an optionally substituted aliphatic group, as defined herein.

By “aliphatic-carbonyloxy” is meant an aliphatic group that is or can be coupled to a compound disclosed herein, wherein the aliphatic group is or becomes coupled through a carbonyloxy group (—OC(O)—). In some embodiments, the aliphatic-carbonyloxy group is —OC(O)—R, in which R is an optionally substituted aliphatic group, as defined herein.

By “aliphatic-oxy” is meant an aliphatic group that is or can be coupled to a compound disclosed herein, wherein the aliphatic group is or becomes coupled through an oxy group (—C(O)—). In some embodiments, the aliphatic-oxy group is —O—R, in which R is an optionally substituted aliphatic group, as defined herein.

By “aliphatic-oxycarbonyl” is meant an aliphatic group that is or can be coupled to a compound disclosed herein, wherein the aliphatic group is or becomes coupled through an oxycarbonyl group (—C(O)O—). In some embodiments, the aliphatic-oxycarbonyl group is —C(O)O—R, in which R is an optionally substituted aliphatic group, as defined herein.

By “alkyl-aryl,” “alkenyl-aryl,” and “alkynyl-aryl” is meant an alkyl, alkenyl, or alkynyl group, respectively and as defined herein, that is or can be coupled (or attached) to the parent molecular group through an aryl group, as defined herein. The alkyl-aryl, alkenyl-aryl, and/or alkynyl-aryl group can be substituted or unsubstituted. For example, the alkyl-aryl, alkenyl-aryl, and/or alkynyl-aryl group can be substituted with one or more substitution groups, as described herein for alkyl and/or aryl. Exemplary unsubstituted alkyl-aryl groups are of from 7 to 16 carbons (C₇₋₁₆ alkyl-aryl), as well as those having an alkyl group with 1 to 6 carbons and an aryl group with 4 to 18 carbons (i.e., C₁₋₆ alkyl-C₄₋₁₈ aryl). Exemplary unsubstituted alkenyl-aryl groups are of from 7 to 16 carbons (C₇₋₁₆ alkenyl-aryl), as well as those having an alkenyl group with 2 to 6 carbons and an aryl group with 4 to 18 carbons (i.e., C₂₋₆ alkenyl-C₄₋₁₈ aryl). Exemplary unsubstituted alkynyl-aryl groups are of from 7 to 16 carbons (C₇₋₁₆ alkynyl-aryl), as well as those having an alkynyl group with 2 to 6 carbons and an aryl group with 4 to 18 carbons (i.e., C₂₋₆ alkynyl-C₄₋₁₈ aryl). In some embodiments, the alkyl-aryl group is -L-R, in which L is an aryl group or an arylene group, as defined herein, and R is an alkyl group, as defined herein.

In some embodiments, the alkenyl-aryl group is -L-R, in which L is an aryl group or an arylene group, as defined herein, and R is an alkenyl group, as defined herein. In some embodiments, the alkynyl-aryl group is -L-R, in which L is an aryl group or an arylene group, as defined herein, and R is an alkynyl group, as defined herein.

By “alkenyl” is meant an unsaturated monovalent hydrocarbon having at least two carbon atom to 50 carbon atoms (C₂₋₅₀), such as two to 25 carbon atoms (C₂₋₂₅), or two to ten carbon atoms (C₂₋₁₀), and at least one carbon-carbon double bond, wherein the unsaturated monovalent hydrocarbon can be derived from removing one hydrogen atom from one carbon atom of a parent alkene. An alkenyl group can be branched, straight-chain, cyclic (e.g., cycloalkenyl), cis, or trans (e.g., E or Z). An exemplary alkenyl includes an optionally substituted C₂₋₂₄ alkyl group having one or more double bonds. The alkenyl group can be monovalent or multivalent (e.g., bivalent) by removing one or more hydrogens to form appropriate attachment to the parent molecular group or appropriate attachment between the parent molecular group and another substitution. The alkenyl group can also be substituted or unsubstituted. For example, the alkenyl group can be substituted with one or more substitution groups, as described herein for alkyl. Non-limiting alkenyl groups include allyl (All), vinyl (Vi), 1-butenyl, 2-butenyl, and the like.

By “alkoxy” is meant —OR, where R is an optionally substituted aliphatic group, as described herein. Exemplary alkoxy groups include, but are not limited to, methoxy, ethoxy, n-propoxy, isopropoxy, n-butoxy, t-butoxy, sec-butoxy, n-pentoxy, trihaloalkoxy, such as trifluoromethoxy, etc. The alkoxy group can be substituted or unsubstituted. For example, the alkoxy group can be substituted with one or more substitution groups, as described herein for alkyl. Exemplary unsubstituted alkoxy groups include C₁₋₃, C₁₋₆, C₁₋₁₂, C₁₋₁₆, C₁₋₁₈, C₁₋₂₀, or C₁₋₂₄ alkoxy groups.

By “alkoxyalkyl” is meant an alkyl group, as defined herein, which is substituted with an alkoxy group, as defined herein. Exemplary unsubstituted alkoxyalkyl groups include between 2 to 12 carbons (C₂₋₁₂ alkoxyalkyl), as well as those having an alkyl group with 1 to 6 carbons and an alkoxy group with 1 to 6 carbons (i.e., C₁₋₆ alkoxy-C₁₋₆ alkyl). In some embodiments, the alkoxyalkyl group is -L-O—R, in which each of L and R is, independently, an alkyl group, as defined herein.

By “alkoxycarbonyl” is meant —C(O)—OR, where R is an optionally substituted aliphatic group, as described herein. In particular embodiments, the alkoxycarbonyl group is —C(O)—OAk, in which Ak is an alkyl group, as defined herein. The alkoxycarbonyl group can be substituted or unsubstituted. For example, the alkoxycarbonyl group can be substituted with one or more substitution groups, as described herein for alkyl. Exemplary unsubstituted alkoxycarbonyl groups include C₂₋₃, C₂₋₆, C₂₋₇, C₂₋₁₂, C₂₋₁₆, C₂₋₁₈, C₂₋₂₀, or C₂₋₂₄ alkoxycarbonyl groups.

By “alkyl” is meant a saturated monovalent hydrocarbon having at least one carbon atom to 50 carbon atoms (C₁₋₅₀), such as one to 25 carbon atoms (C₁₋₂₅), or one to ten carbon atoms (C₁₋₁₀), wherein the saturated monovalent hydrocarbon can be derived from removing one hydrogen atom from one carbon atom of a parent compound (e.g., alkane). An alkyl group can be branched, straight-chain, or cyclic (e.g., cycloalkyl). An exemplary alkyl includes a branched or unbranched saturated hydrocarbon group of 1 to 24 carbon atoms, such as methyl (Me), ethyl (Et), n-propyl (nPr), iso-propyl (iPr), n-butyl (nBu), iso-butyl (iBu), sec-butyl (sBu), tert-butyl (tBu), pentyl (Pe), n-pentyl (nPe), isopentyl (iPe), s-pentyl (sPe), neopentyl (neoPe), tert-pentyl (tPe), hexyl (Hx), heptyl (Hp), octyl (Oc), nonyl (Nn), decyl (De), dodecyl, tetradecyl, hexadecyl, eicosyl, tetracosyl, and the like. The alkyl group can also be substituted or unsubstituted. The alkyl group can be monovalent or multivalent (e.g., bivalent) by removing one or more hydrogens to form appropriate attachment to the parent molecular group or appropriate attachment between the parent molecular group and another substitution. For example, the alkyl group can be substituted with one, two, three or, in the case of alkyl groups of two carbons or more, four substituents independently selected from the group consisting of: (1) C₁₋₆ alkoxy (e.g., —O—R, in which R is C₁₋₆ alkyl); (2) C₁₋₆ alkylsulfinyl (e.g., —S(O)—R, in which R is C₁₋₆ alkyl); (3) C₁₋₆ alkylsulfonyl (e.g., —SO₂—R, in which R is C₁₋₆ alkyl); (4) amino (e.g., —NR¹R², where each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, can form a heterocyclyl group, as defined herein); (5) aryl; (6) arylalkoxy (e.g., —O-L-R, in which L is alkyl and R is aryl); (7) aryloyl (e.g., —C(O)—R, in which R is aryl); (8) azido (e.g., —N₃); (9) cyano (e.g., —CN); (10) aldehyde (e.g., —C(O)H); (11) C₃₋₈ cycloalkyl; (12) halo; (13) heterocyclyl (e.g., as defined herein, such as a 5-, 6- or 7-membered ring containing one, two, three, or four non-carbon heteroatoms); (14) heterocyclyloxy (e.g., —O—R, in which R is heterocyclyl, as defined herein); (15) heterocyclyloyl (e.g., —C(O)—R, in which R is heterocyclyl, as defined herein); (16) hydroxyl (e.g., —OH); (17) N-protected amino; (18) nitro (e.g., —NO₂); (19) oxo (e.g., ═O); (20) C₁₋₆ thioalkyl (e.g., —S—R, in which R is alkyl); (21) thiol (e.g., —SH); (22) —CO₂R¹, where R¹ is selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (23) —C(O)NR¹R², where each of R¹ and R² is, independently, selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (24) —SO₂R¹, where R¹ is selected from the group consisting of (a) C₁₋₆ alkyl, (b) C₄₋₁₈ aryl, and (c) C₄₋₁₈ aryl-C₁₋₆ alkyl (e.g., -L-R, in which L is C₁₋₆ alkyl and R is C₄₋₁₈ aryl); (25) —SO₂NR¹R², where each of R¹ and R² is, independently, selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); and (26) —NR¹R², where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₁₈ aryl, (g) C₄₋₁₈ aryl-C₁₋₆ alkyl (e.g., -L-R, in which L is C₁₋₆ alkyl and R is C₄₋₁₈ aryl), (h) C₃₋₈ cycloalkyl, and (i) C₃₋₈ cycloalkyl-C₁₋₆ alkyl (e.g., -L-R, in which L is C₁₋₆ alkyl and R is C₃₋₈ cycloalkyl), wherein in one embodiment no two groups are bound to the nitrogen atom through a carbonyl group or a sulfonyl group. The alkyl group can be a primary, secondary, or tertiary alkyl group substituted with one or more substituents (e.g., one or more halo or alkoxy). In some embodiments, the unsubstituted alkyl group is a C₁₋₃, C₁₋₆, C₁₋₁₂, C₁₋₁₆, C₁₋₁₈, C₁₋₂₀, or C₁₋₂₄ alkyl group.

By “alkylene,” “alkenylene,” or “alkynylene” is meant a multivalent (e.g., bivalent) form of an alkyl, alkenyl, or alkynyl group, respectively, as described herein. Exemplary alkylene groups include methylene, ethylene, propylene, butylene, etc. In some embodiments, the alkylene group is a C₁₋₃, C₁₋₆, C₁₋₁₂, C₁₋₁₆, C₁₋₁₈, C₁₋₂₀, C₁₋₂₄, C₂₋₃, C₂₋₆, C₂₋₁₂, C₂₋₁₆, C₂₋₁₈, C₂₋₂₀, or C₂₋₂₄ alkylene group. In other embodiments, the alkylene group is a C₂₋₃, C₂₋₆, C₂₋₁₂, C₂₋₁₆, C₂₋₁₈, C₂₋₂₀, or C₂₋₂₄ alkenylene or alkynylene group. The alkylene, alkenylene, or alkynylene group can be branched or unbranched. The alkylene, alkenylene, or alkynylene group can also be substituted or unsubstituted. For example, the alkylene, alkenylene, or alkynylene group can be substituted with one or more substitution groups, as described herein for alkyl.

By “alkylsulfinyl” is meant an alkyl group, as defined herein, attached to the parent molecular group through an —S(O)— group. In some embodiments, the unsubstituted alkylsulfinyl group is a C₁₋₆ or C₁₋₁₂ alkylsulfinyl group. In other embodiments, the alkylsulfinyl group is —S(O)—R, in which R is an alkyl group, as defined herein.

By “alkylsulfinylalkyl” is meant an alkyl group, as defined herein, substituted by an alkylsulfinyl group. In some embodiments, the unsubstituted alkylsulfinylalkyl group is a C₂₋₁₂ or C₂₋₂₄ alkylsulfinylalkyl group (e.g., C₁₋₆ alkylsulfinyl-C₁₋₆ alkyl or C₁₋₁₂ alkylsulfinyl-C₁₋₁₂ alkyl). In other embodiments, the alkylsulfinylalkyl group is -L-S(O)—R, in which each of L and R is, independently, an alkyl group, as defined herein.

By “alkylsulfonyl” is meant an alkyl group, as defined herein, attached to the parent molecular group through an —SO₂— group. In some embodiments, the unsubstituted alkylsulfonyl group is a C₁₋₆ or C₁₋₁₂ alkylsulfonyl group. In other embodiments, the alkylsulfonyl group is —SO₂—R, where R is an optionally substituted alkyl (e.g., as described herein, including optionally substituted C₁₋₁₂ alkyl, haloalkyl, or perfluoroalkyl).

By “alkylsulfonylalkyl” is meant an alkyl group, as defined herein, substituted by an alkylsulfonyl group. In some embodiments, the unsubstituted alkylsulfonylalkyl group is a C₂₋₁₂ or C₂₋₂₄ alkylsulfonylalkyl group (e.g., C₁₋₆ alkylsulfonyl-C₁₋₆ alkyl or C₁₋₁₂ alkylsulfonyl-C₁₋₁₂ alkyl). In other embodiments, the alkylsulfonylalkyl group is -L-SO₂—R, in which each of L and R is, independently, an alkyl group, as defined herein.

By “alkynyl” is meant an unsaturated monovalent hydrocarbon having at least two carbon atom to 50 carbon atoms (C₂₋₅₀), such as two to 25 carbon atoms (C₂₋₂₅), or two to ten carbon atoms (C₂₋₁₀), and at least one carbon-carbon triple bond, wherein the unsaturated monovalent hydrocarbon can be derived from removing one hydrogen atom from one carbon atom of a parent alkyne. An alkynyl group can be branched, straight-chain, or cyclic (e.g., cycloalkynyl). An exemplary alkynyl includes an optionally substituted C₂₋₂₄ alkyl group having one or more triple bonds. The alkynyl group can be cyclic or acyclic and is exemplified by ethynyl, 1-propynyl, and the like. The alkynyl group can be monovalent or multivalent (e.g., bivalent) by removing one or more hydrogens to form appropriate attachment to the parent molecular group or appropriate attachment between the parent molecular group and another substitution. The alkynyl group can also be substituted or unsubstituted. For example, the alkynyl group can be substituted with one or more substitution groups, as described herein for alkyl.

By “ambient temperature” is meant a temperature ranging from 16° C. to 26° C., such as from 19° C. to 25° C. or from 20° C. to 25° C.

By “amide” is mean —C(O)NR¹R² or —NHCOR¹, where each of R¹ and R² is, independently, selected from hydrogen, aliphatic, heteroaliphatic, aromatic, as defined herein, or any combination thereof, or where R¹ and R², taken together with the nitrogen atom to which each are attached, can form a heterocyclyl group, as defined herein.

By “amino” is meant —NR¹R², where each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof, or where R¹ and R², taken together with the nitrogen atom to which each are attached, can form a heterocyclyl group, as defined herein. In particular embodiments, each of R¹ and R² is, independently, H, optionally substituted alkyl, optionally substituted alkoxy, optionally substituted aryl, optionally substituted aryloxy, optionally substituted alkyl-aryl, optionally substituted aryl-alkyl, optionally substituted silyl, or optionally substituted silyloxy. In particular embodiments, R¹ and R² can be taken together, with the nitrogen atom to which each is attached, to form an optionally substituted heterocyclyl.

By “aminoalkyl” is meant an alkyl group, as defined herein, substituted by an amino group, as defined herein. In some embodiments, the aminoalkyl group is -L-NR¹R², in which L is an alkyl group, as defined herein, and each of R¹ and R² is, independently, selected from hydrogen, aliphatic, heteroaliphatic, or aromatic, as defined herein, or any combination thereof; or R¹ and R², taken together with the nitrogen atom to which each are attached, can form a heterocyclyl group, as defined herein. In other embodiments, the aminoalkyl group is -L-C(NR¹R²)(R³)—R⁴, in which L is a covalent bond or an alkyl group, as defined herein; each of R¹ and R² is, independently, selected from hydrogen, aliphatic, heteroaliphatic, or aromatic, as defined herein, or any combination thereof, or R¹ and R², taken together with the nitrogen atom to which each are attached, can form a heterocyclyl group, as defined herein; and each of R³ and R⁴ is, independently, H or alkyl, as defined herein.

By “aminooxy” is meant an oxy group, as defined herein, substituted by an amino group, as defined herein. In some embodiments, the aminooxy group is —O—NR¹R², in which each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof, or R¹ and R², taken together with the nitrogen atom to which each are attached, can form a heterocyclyl group, as defined herein. In particular embodiments, each of R¹ and R² is, independently, H, optionally substituted alkyl, optionally substituted alkoxy, optionally substituted aryl, optionally substituted aryloxy, optionally substituted alkyl-aryl, optionally substituted aryl-alkyl, optionally substituted silyl, or optionally substituted silyloxy.

By “aromatic” is meant a cyclic, conjugated group or moiety of, unless specified otherwise, from 5 to 15 ring atoms having a single ring (e.g., phenyl) or multiple condensed rings in which at least one ring is aromatic (e.g., naphthyl, indolyl, or pyrazolopyridinyl); that is, at least one ring, and optionally multiple condensed rings, have a continuous, delocalized π-electron system. Typically, the number of out of plane π-electrons corresponds to the Huckel rule (4n+2). The point of attachment to the parent structure typically is through an aromatic portion of the condensed ring system. An aromatic group is unsubstituted or substituted, e.g., by a functional group described herein. For example, the aromatic group can be substituted with one or more substitution groups, as described herein for alkyl and/or aryl.

By “aromatic-carbonyl” is meant an aromatic group that is or can be coupled to a compound disclosed herein, wherein the aromatic group is or becomes coupled through a carbonyl group (—C(O)—). In some embodiments, the aromatic-carbonyl group is —C(O)—R, in which R is an optionally substituted aromatic group, as defined herein.

By “aromatic-carbonyloxy” is meant an aromatic group that is or can be coupled to a compound disclosed herein, wherein the aromatic group is or becomes coupled through a carbonyloxy group (—OC(O)—). In some embodiments, the aromatic-carbonyloxy group is —OC(O)—R, in which R is an optionally substituted aromatic group, as defined herein.

By “aromatic-oxy” is meant an aromatic group that is or can be coupled to a compound disclosed herein, wherein the aromatic group is or becomes coupled through an oxy group (—O—). In some embodiments, the aromatic-oxy group is —O—R, in which R is an optionally substituted aromatic group, as defined herein.

By “aromatic-oxycarbonyl” is meant an aromatic group that is or can be coupled to a compound disclosed herein, wherein the aromatic group is or becomes coupled through an oxycarbonyl group (—C(O)O—). In some embodiments, the aromatic-carbonyl group is —C(O)O—R, in which R is an optionally substituted aromatic group, as defined herein.

By “aryl” is meant an aromatic carbocyclic group comprising at least five carbon atoms to 15 carbon atoms (C₅₋₁₅), such as five to ten carbon atoms (C₅₋₁₀), having a single ring or multiple condensed rings, which condensed rings can or may not be aromatic provided that the point of attachment to a remaining position of the compounds disclosed herein is through an atom of the aromatic carbocyclic group. Aryl groups may be substituted with one or more groups other than hydrogen, such as aliphatic, heteroaliphatic, aromatic, other functional groups, or any combination thereof. Exemplary aryl groups include, but are not limited to, benzyl, naphthalene, phenyl, biphenyl, phenoxybenzene, and the like. The term aryl also includes heteroaryl, which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term non-heteroaryl, which is also included in the term aryl, defines a group that contains an aromatic group that does not contain a heteroatom. The aryl group can be substituted or unsubstituted. The aryl group can be substituted with one, two, three, four, or five substituents independently selected from the group consisting of: (1) C₁₋₆ alkanoyl (e.g., —C(O)—R, in which R is C₁₋₆ alkyl); (2) C₁₋₆ alkyl; (3) C₁₋₆ alkoxy (e.g., —O—R, in which R is C₁₋₆ alkyl); (4) C₁₋₆ alkoxy-C₁₋₆ alkyl (e.g., -L-O—R, in which each of L and R is, independently, C₁₋₆ alkyl); (5) C₁₋₆ alkylsulfinyl (e.g., —S(O)—R, in which R is C₁₋₆ alkyl); (6) C₁₋₆ alkylsulfinyl-C₁₋₆ alkyl (e.g., -L-S(O)—R, in which each of L and R is, independently, C₁₋₆ alkyl); (7) C₁₋₆ alkylsulfonyl (e.g., —SO₂—R, in which R is C₁₋₆ alkyl); (8) C₁₋₆ alkylsulfonyl-C₁₋₆ alkyl (e.g., -L-SO₂—R, in which each of L and R is, independently, C₁₋₆ alkyl); (9) aryl; (10) amino (e.g., —NR¹R², where each of R¹ and R² is, independently, selected from hydrogen, aliphatic, heteroaliphatic, haloaliphatic, haloheteroaliphatic, aromatic, as defined herein, or any combination thereof; or R¹ and R², taken together with the nitrogen atom to which each are attached, can form a heterocyclyl group, as defined herein); (11) C₁₋₆ aminoalkyl (e.g., -L¹-NR¹R² or -L²-C(NR¹R²)(R³)—R⁴, in which L¹ is C₁₋₆ alkyl; L² is a covalent bond or C₁₋₆ alkyl; each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, can form a heterocyclyl group, as defined herein; and each of R³ and R⁴ is, independently, H or C₁₋₆ alkyl); (12) heteroaryl; (13) C₄₋₁₈ aryl-C₁₋₆ alkyl (e.g., -L-R, in which L is C₁₋₆ alkyl and R is C₄₋₁₈ aryl); (14) aryloyl (e.g., —C(O)—R, in which R is aryl); (15) azido (e.g., —N₃); (16) cyano (e.g., —CN); (17) C₁₋₆ azidoalkyl (e.g., -L-N₃, in which L is C₁₋₆ alkyl); (18) aldehyde (e.g., —C(O)H); (19) aldehyde-C₁₋₆ alkyl (e.g., -L-C(O)H, in which L is C₁₋₆ alkyl); (20) C₃₋₈ cycloalkyl; (21) C₃₋₈ cycloalkyl-C₁₋₆ alkyl (e.g., -L-R, in which L is C₁₋₆ alkyl and R is C₃₋₈ cycloalkyl); (22) halo; (23) C₁₋₆ haloalkyl (e.g., -L¹-X or -L²-C(X)(R¹)—R², in which L¹ is C₁₋₆ alkyl; L² is a covalent bond or C₁₋₆ alkyl; X is fluoro, bromo, chloro, or iodo; and each of R¹ and R² is, independently, H or C₁₋₆ alkyl); (24) heterocyclyl (e.g., as defined herein, such as a 5-, 6- or 7-membered ring containing one, two, three, or four non-carbon heteroatoms); (25) heterocyclyloxy (e.g., —O—R, in which R is heterocyclyl, as defined herein); (26) heterocyclyloyl (e.g., —C(O)—R, in which R is heterocyclyl, as defined herein); (27) hydroxyl (—OH); (28) C₁₋₆ hydroxyalkyl (e.g., -L¹-OH or -L²-C(OH)(R¹)—R², in which L¹ is C₁₋₆ alkyl; L² is a covalent bond or alkyl; and each of R¹ and R² is, independently, H or C₁₋₆ alkyl, as defined herein); (29) nitro; (30) C₁₋₆ nitroalkyl (e.g., -L¹-NO or -L²-C(NO)(R¹)—R², in which L¹ is C₁₋₆ alkyl; L² is a covalent bond or alkyl; and each of R¹ and R² is, independently, H or C₁₋₆ alkyl, as defined herein); (31) N-protected amino; (32) N-protected amino-C₁₋₆ alkyl; (33) oxo (e.g., ═O); (34) C₁₋₆ thioalkyl (e.g., —S—R, in which R is C₁₋₆ alkyl); (35) thio-C₁₋₆ alkoxy-C₁₋₆ alkyl (e.g., -L-S—R, in which each of L and R is, independently, C₁₋₆ alkyl); (36) —(CH₂)ᵣCO₂R¹, where r is an integer of from zero to four, and R¹ is selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (37) —(CH₂)ᵣCONR¹R², where r is an integer of from zero to four and where each R¹ and R² is independently selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (38) —(CH₂)ᵣSO₂R¹, where r is an integer of from zero to four and where R¹ is selected from the group consisting of (a) C₁₋₆ alkyl, (b) C₄₋₁₈ aryl, and (c) C₄₋₁₈ aryl-C₁₋₆ alkyl (e.g., -L-R, in which L is C₁₋₆ alkyl and R is C₄₋₁₈ aryl); (39) —(CH₂)ᵣSO₂NR¹R², where r is an integer of from zero to four and where each of R¹ and R² is, independently, selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (40) —(CH₂)ᵣNR¹R², where r is an integer of from zero to four and where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₁₈ aryl, (g) C₄₋₁₈ aryl-C₁₋₆ alkyl (e.g., -L-R, in which L is C₁₋₆ alkyl and R is C₄₋₁₈ aryl), (h) C₃₋₈ cycloalkyl, and (i) C₃₋₈ cycloalkyl-C₁₋₆ alkyl (e.g., -L-R, in which L is C₁₋₆ alkyl and R is C₃₋₈ cycloalkyl), wherein in one embodiment no two groups are bound to the nitrogen atom through a carbonyl group or a sulfonyl group; (41) thiol (e.g., —SH); (42) perfluoroalkyl (e.g., —(CF₂)ₙCF₃, in which n is an integer from 0 to 10); (43) perfluoroalkoxy (e.g., —O—(CF₂)ₙCF₃, in which n is an integer from 0 to 10); (44) aryloxy (e.g., —O—R, in which R is aryl); (45) cycloalkoxy (e.g., —O—R, in which R is cycloalkyl); (46) cycloalkylalkoxy (e.g., —O-L-R, in which L is alkyl and R is cycloalkyl); and (47) arylalkoxy (e.g., —O-L-R, in which L is alkyl and R is aryl). In particular embodiments, an unsubstituted aryl group is a C₄₋₁₈, C₄₋₁₄, C₄₋₁₂, C₄₋₁₀, C₆₋₁₈, C₆₋₁₄, C₆₋₁₂, or C₆₋₁₀ aryl group.

By “aryl-alkyl,” “aryl-alkenyl,” and “aryl-alkynyl” is meant an aryl group, as defined herein, that is or can be coupled (or attached) to the parent molecular group through an alkyl, alkenyl, or alkynyl group, respectively, as defined herein. The aryl-alkyl, aryl-alkenyl, and/or aryl-alkynyl group can be substituted or unsubstituted. For example, the aryl-alkyl, aryl-alkenyl, and/or aryl-alkynyl group can be substituted with one or more substitution groups, as described herein for aryl and/or alkyl. Exemplary unsubstituted aryl-alkyl groups are of from 7 to 16 carbons (C₇₋₁₆ aryl-alkyl), as well as those having an aryl group with 4 to 18 carbons and an alkyl group with 1 to 6 carbons (i.e., C₄₋₁₈ aryl-C₁₋₆ alkyl). Exemplary unsubstituted aryl-alkenyl groups are of from 7 to 16 carbons (C₇₋₁₆ aryl-alkenyl), as well as those having an aryl group with 4 to 18 carbons and an alkenyl group with 2 to 6 carbons (i.e., C₄₋₁₈ aryl-C₂₋₆ alkenyl). Exemplary unsubstituted aryl-alkynyl groups are of from 7 to 16 carbons (C₇₋₁₆ aryl-alkynyl), as well as those having an aryl group with 4 to 18 carbons and an alkynyl group with 2 to 6 carbons (i.e., C₄₋₈ aryl-C₂₋₆ alkynyl). In some embodiments, the aryl-alkyl group is -L-R, in which L is an alkyl group or an alkylene group, as defined herein, and R is an aryl group, as defined herein. In some embodiments, the aryl-alkenyl group is -L-R, in which L is an alkenyl group or an alkenylene group, as defined herein, and R is an aryl group, as defined herein. In some embodiments, the aryl-alkynyl group is -L-R, in which L is an alkynyl group or an alkynylene group, as defined herein, and R is an aryl group, as defined herein.

By “arylene” is meant a multivalent (e.g., bivalent) form of an aryl group, as described herein. Exemplary arylene groups include phenylene, naphthylene, biphenylene, triphenylene, diphenyl ether, acenaphthenylene, anthrylene, or phenanthrylene. In some embodiments, the arylene group is a C₄₋₁₈, C₄₋₁₄, C₄₋₁₂, C₄₋₁₀, C₆₋₁₈, C₆₋₁₄, C₆₋₁₂, or C₆₋₁₀ arylene group. The arylene group can be branched or unbranched. The arylene group can also be substituted or unsubstituted. For example, the arylene group can be substituted with one or more substitution groups, as described herein for aryl.

By “arylalkoxy” is meant an aryl-alkyl group, as defined herein, attached to the parent molecular group through an oxygen atom. In some embodiments, the arylalkoxy group is —O-L-R, in which L is an alkyl group, as defined herein, and R is an aryl group, as defined herein.

By “aryloxy” is meant —OR, where R is an optionally substituted aryl group, as described herein. In some embodiments, an unsubstituted aryloxy group is a C₄₋₁₈ or C₆₋₁₈ aryloxy group. In other embodiments, R is an aryl group that is optionally substituted with alkyl, alkanoyl, amino, hydroxyl, and the like.

By “aryloxycarbonyl” is meant an aryloxy group, as defined herein, that is attached to the parent molecular group through a carbonyl group. In some embodiments, an unsubstituted aryloxycarbonyl group is a C₅₋₁₉ aryloxycarbonyl group. In other embodiments, the aryloxycarbonyl group is —C(O)O—R, in which R is an aryl group, as defined herein.

By “aryloyl” is meant an aryl group that is attached to the parent molecular group through a carbonyl group. In some embodiments, an unsubstituted aryloyl group is a C₇₋₁₁ aryloyl or C₅₋₁₉ aryloyl group. In other embodiments, the aryloyl group is —C(O)—R, in which R is an aryl group, as defined herein.

By “aryloyloxy” is meant an aryloyl group, as defined herein, that is attached to the parent molecular group through an oxy group. In some embodiments, an unsubstituted aryloyloxy group is a C₅₋₁₉ aryloyloxy group. In other embodiments, the aryloyloxy group is —OC(O)—R, in which R is an aryl group, as defined herein.

By “azido” is meant an —N₃ group.

By “azidoalkyl” is meant an azido group attached to the parent molecular group through an alkyl group, as defined herein. In some embodiments, the azidoalkyl group is -L-N₃, in which L is an alkyl group, as defined herein.

By “azo” is meant an —N═N— group.

By “carbamoyl” is meant an amino group attached to the parent molecular group through a carbonyl group, as defined herein. In some embodiments, the carbamoyl is —C(O)NR¹R² group, where each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof, or where R¹ and R², taken together with the nitrogen atom to which each are attached, can form a heterocyclyl group, as defined herein.

By “carbamoyloxy” is meant a carbamoyl group, as defined herein, attached to the parent molecular group through n oxy group, as defined herein. In some embodiments, the carbamoyl is —OC(O)NR¹R² group, where each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof, or where R¹ and R², taken together with the nitrogen atom to which each are attached, can form a heterocyclyl group, as defined herein.

By “carbonimidoyl” is meant a —C(NR)— group. In some embodiments, R is selected from hydrogen, optionally substituted aliphatic, optionally substituted heteroaliphatic, optionally substituted aromatic, optionally substituted heteroaromatic, optionally substituted silyl, optionally substituted alkyl, optionally substituted aryl, optionally substituted alkyl-aryl, or optionally substituted aryl-alkyl, optionally substituted silyloxy, as defined herein, or any combination thereof.

By “carbonyl” is meant a —C(O)— group, which can also be represented as >C═O.

By “carboxyl” is meant a —CO₂H group or an anion thereof.

By “catalyst” is meant a compound, usually present in small amounts relative to reactants, capable of catalyzing a synthetic reaction, as would be readily understood by a person of ordinary skill in the art. In some embodiments, catalysts may include transition metal coordination complex.

By “cyanato” is meant a —OCN group.

By “cyano” is meant a —CN group.

By “cycloaliphatic” is meant an aliphatic group, as defined herein, that is cyclic.

By “cycloalkoxy” is meant a cycloalkyl group, as defined herein, attached to the parent molecular group through an oxygen atom. In some embodiments, the cycloalkoxy group is —O—R, in which R is a cycloalkyl group, as defined herein.

By “cycloalkylalkoxy” is meant a —O-L-R group, in which L is an alkyl group or an alkylene group, as defined herein, and R is a cycloalkyl group, as defined herein.

By “cycloalkyl” is meant a monovalent saturated or unsaturated non-aromatic cyclic hydrocarbon group of from three to eight carbons, unless otherwise specified, and is exemplified by cyclopropyl, cyclobutyl, cyclopentyl, cyclohexyl, cycloheptyl, bicyclo[2.2.1.heptyl], and the like. The cycloalkyl group can also be substituted or unsubstituted. For example, the cycloalkyl group can be substituted with one or more groups including those described herein for alkyl. Further, cycloalkyl may include one or more double bonds and/or triple bonds.

By “cycloheteroaliphatic” is meant a heteroaliphatic group, as defined herein, that is cyclic.

By “disilanyl” is meant a group containing an Si—Si bond. In some embodiments, the disilanyl group is a —SiR^{S1}R^{S2}—SiR^{S3}R^{S4}R^{S5} or —SiR^{S1}R^{S2}—SiR^{S3}R^{S4}— group, in which each of R^{S1}, R^{S2}, R^{S3}, R^{S4}, and R^{S5} is, independently, H, optionally substituted aliphatic, optionally substituted heteroaliphatic, optionally substituted aromatic, optionally substituted heteroaromatic, or optionally substituted amino.

By “disulfide” is meant —SSR, where R is selected from hydrogen, aliphatic, heteroaliphatic, haloaliphatic, haloheteroaliphatic, aromatic, as defined herein, or any combination thereof.

By “electron-donating group” is meant a functional group capable of donating at least a portion of its electron density into the ring to which it is directly attached, such as by resonance.

By “electron-withdrawing group” is meant a functional group capable of accepting electron density from the ring to which it is directly attached, such as by inductive electron withdrawal.

By “halo” is meant F, Cl, Br, or I.

By “haloaliphatic” is meant an aliphatic group, as defined herein, in which one or more hydrogen atoms, such as one to 10 hydrogen atoms, independently is replaced with a halogen atom, such as fluoro, bromo, chloro, or iodo.

By “haloalkyl” is meant an alkyl group, as defined herein, where one or more hydrogen atoms, such as one to 10 hydrogen atoms, independently is replaced with a halogen atom, such as fluoro, bromo, chloro, or iodo. In an independent embodiment, haloalkyl can be a —CX₃ group, wherein each X independently can be selected from fluoro, bromo, chloro, or iodo. In some embodiments, the haloalkyl group is -L-X, in which L is an alkyl group, as defined herein, and X is fluoro, bromo, chloro, or iodo. In other embodiments, the haloalkyl group is -L-C(X)(R¹)—R², in which L is a covalent bond or an alkyl group, as defined herein; X is fluoro, bromo, chloro, or iodo; and each of R¹ and R² is, independently, H or alkyl, as defined herein.

By “haloheteroaliphatic” is meant a heteroaliphatic, as defined herein, in which one or more hydrogen atoms, such as one to 10 hydrogen atoms, independently is replaced with a halogen atom, such as fluoro, bromo, chloro, or iodo.

By “heteroaliphatic” is meant an aliphatic group, as defined herein, including at least one heteroatom to 20 heteroatoms, such as one to 15 heteroatoms, or one to 5 heteroatoms, which can be selected from, but not limited to oxygen, nitrogen, sulfur, silicon, boron, selenium, phosphorous, and oxidized forms thereof within the group. A heteroaliphatic group is unsubstituted or substituted, e.g., by a functional group described herein. For example, the heteroaliphatic group can be substituted with one or more substitution groups, as described herein for alkyl.

By “heteroaliphatic-carbonyl” is meant a heteroaliphatic group that is or can be coupled to a compound disclosed herein, wherein the heteroaliphatic group is or becomes coupled through a carbonyl group (—C(O)—). In some embodiments, the heteroaliphatic-carbonyl group is —C(O)—R, in which R is an optionally substituted heteroaliphatic group, as defined herein.

By “heteroaliphatic-carbonyloxy” is meant a heteroaliphatic group that is or can be coupled to a compound disclosed herein, wherein the heteroaliphatic group is or becomes coupled through a carbonyloxy group (—OC(O)—). In some embodiments, the heteroaliphatic-carbonyloxy group is —OC(O)—R, in which R is an optionally substituted heteroaliphatic group, as defined herein.

By “heteroaliphatic-oxy” is meant a heteroaliphatic group that is or can be coupled to a compound disclosed herein, wherein the heteroaliphatic group is or becomes coupled through an oxy group (—C(O)—). In some embodiments, the heteroaliphatic-oxy group is —O—R, in which R is an optionally substituted heteroaliphatic group, as defined herein.

By “heteroaliphatic-oxycarbonyl” is meant a heteroaliphatic group that is or can be coupled to a compound disclosed herein, wherein the heteroaliphatic group is or becomes coupled through an oxycarbonyl group (—C(O)O—). In some embodiments, the heteroaliphatic-oxycarbonyl group is —C(O)O—R, in which R is an optionally substituted heteroaliphatic group, as defined herein.

By “heteroalkyl,” “heteroalkenyl,” and “heteroalkynyl” is meant an alkyl, alkenyl, or alkynyl group (which can be branched, straight-chain, or cyclic), respectively, as defined herein, including at least one heteroatom to 20 heteroatoms, such as one to 15 heteroatoms, or one to 5 heteroatoms, which can be selected from, but not limited to, oxygen, nitrogen, sulfur, silicon, boron, selenium, phosphorous, and oxidized forms thereof within the group.

By “heteroalkylene,” “heteroalkenylene,” and “heteroalkynylene” is meant a multivalent (e.g., bivalent) form of a heteroalkyl, heteroalkenyl, or heteroalkynyl group, respectively, as described herein.

By “heteroaromatic” is meant an aromatic group, as defined herein, including at least one heteroatom to 20 heteroatoms, such as one to 15 heteroatoms, or one to 5 heteroatoms, which can be selected from, but not limited to oxygen, nitrogen, sulfur, silicon, boron, selenium, phosphorous, and oxidized forms thereof within the group. A heteroaromatic group is unsubstituted or substituted, e.g., by a functional group described herein. For example, the heteroaromatic group can be substituted with one or more substitution groups, as described herein for alkyl and/or aryl.

By “heteroaromatic-carbonyl” is meant a heteroaromatic group that is or can be coupled to a compound disclosed herein, wherein the heteroaromatic group is or becomes coupled through a carbonyl group (—C(O)—). In some embodiments, the heteroaromatic-carbonyl group is —C(O)—R, in which R is an optionally substituted heteroaromatic group, as defined herein.

By “heteroaromatic-carbonyloxy” is meant a heteroaromatic group that is or can be coupled to a compound disclosed herein, wherein the heteroaromatic group is or becomes coupled through a carbonyloxy group (—OC(O)—). In some embodiments, the heteroaromatic-carbonyloxy group is —OC(O)—R, in which R is an optionally substituted heteroaromatic group, as defined herein.

By “heteroaromatic-oxy” is meant a heteroaromatic group that is or can be coupled to a compound disclosed herein, wherein the heteroaromatic group is or becomes coupled through an oxy group (—O—). In some embodiments, the heteroaromatic-oxy group is —O—R, in which R is an optionally substituted heteroaromatic group, as defined herein.

By “heteroaromatic-oxycarbonyl” is meant a heteroaromatic group that is or can be coupled to a compound disclosed herein, wherein the heteroaromatic group is or becomes coupled through an oxycarbonyl group (—C(O)O—). In some embodiments, the heteroaromatic-carbonyl group is —C(O)O—R, in which R is an optionally substituted heteroaromatic group, as defined herein.

By “heteroaryl” is meant an aryl group including at least one heteroatom to six heteroatoms, such as one to four heteroatoms, which can be selected from, but not limited to, oxygen, nitrogen, sulfur, silicon, boron, selenium, phosphorous, and oxidized forms thereof within the ring. Such heteroaryl groups can have a single ring or multiple condensed rings, where the condensed rings may or may not be aromatic and/or contain a heteroatom, provided that the point of attachment is through an atom of the aromatic heteroaryl group. Heteroaryl groups may be substituted with one or more groups other than hydrogen, such as aliphatic, heteroaliphatic, aromatic, other functional groups, or any combination thereof. An exemplary heteroaryl includes a subset of heterocyclyl groups, as defined herein, which are aromatic, i.e., they contain 4n+2 pi electrons within the mono- or multicyclic ring system.

By “heteroarylene” is meant a multivalent (e.g., bivalent) form of a heteroaryl group, as described herein.

By “heteroatom” is meant an atom other than carbon, such as oxygen, nitrogen, sulfur, silicon, boron, selenium, or phosphorous. In particular disclosed embodiments, such as when valency constraints do not permit, a heteroatom does not include a halogen atom.

By “heterocyclyl” is meant a 5-, 6- or 7-membered ring, unless otherwise specified, containing one, two, three, or four non-carbon heteroatoms (e.g., independently selected from the group consisting of nitrogen, oxygen, phosphorous, sulfur, or halo). The 5-membered ring has zero to two double bonds and the 6- and 7-membered rings have zero to three double bonds. The term “heterocyclyl” also includes bicyclic, tricyclic and tetracyclic groups in which any of the above heterocyclic rings is fused to one, two, or three rings independently selected from the group consisting of an aryl ring, a cyclohexane ring, a cyclohexene ring, a cyclopentane ring, a cyclopentene ring, and another monocyclic heterocyclic ring, such as indolyl, quinolyl, isoquinolyl, tetrahydroquinolyl, benzofuryl, benzothienyl and the like. Heterocyclics include thiiranyl, thietanyl, tetrahydrothienyl, thianyl, thiepanyl, aziridinyl, azetidinyl, pyrrolidinyl, piperidinyl, azepanyl, pyrrolyl, pyrrolinyl, pyrazolyl, pyrazolinyl, pyrazolidinyl, imidazolyl, imidazolinyl, imidazolidinyl, pyridyl, homopiperidinyl, pyrazinyl, piperazinyl, pyrimidinyl, pyridazinyl, oxazolyl, oxazolidinyl, oxazolidonyl, isoxazolyl, isoxazolidiniyl, morpholinyl, thiomorpholinyl, thiazolyl, thiazolidinyl, isothiazolyl, isothiazolidinyl, indolyl, quinolinyl, isoquinolinyl, benzimidazolyl, benzothiazolyl, benzoxazolyl, furyl, thienyl, thiazolidinyl, isothiazolyl, isoindazoyl, triazolyl, tetrazolyl, oxadiazolyl, uricyl, thiadiazolyl, pyrimidyl, tetrahydrofuranyl, dihydrofuranyl, dihydrothienyl, dihydroindolyl, tetrahydroquinolyl, tetrahydroisoquinolyl, pyranyl, dihydropyranyl, tetrahydropyranyl, dithiazolyl, dioxanyl, dioxinyl, dithianyl, trithianyl, oxazinyl, thiazinyl, oxothiolanyl, triazinyl, benzofuranyl, benzothienyl, and the like.

By “heterocyclyloxy” is meant a heterocyclyl group, as defined herein, attached to the parent molecular group through an oxygen atom. In some embodiments, the heterocyclyloxy group is —O—R, in which R is a heterocyclyl group, as defined herein.

By “heterocyclyloyl” is meant a heterocyclyl group, as defined herein, attached to the parent molecular group through a carbonyl group. In some embodiments, the heterocyclyloyl group is —C(O)—R, in which R is a heterocyclyl group, as defined herein.

By “hydrazino” is meant —NR¹—NR²R³, where each of R¹, R², and R³ is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where a combination of R¹ and R² or a combination of R² and R³, taken together with the nitrogen atom to which each are attached, can form a heterocyclyl group, as defined herein. In some embodiments, each of R¹, R², or R³ is, independently, H, optionally substituted alkyl, optionally substituted aryl, optionally substituted alkyl-aryl, or optionally substituted aryl-alkyl. In particular embodiments, R² and R³ can be taken together, with the nitrogen atom to which each is attached, to form an optionally substituted heterocyclyl.

By “hydroxyl” is meant —OH.

By “hydroxyalkyl” is meant an alkyl group, as defined herein, substituted by one to three hydroxyl groups, with the proviso that no more than one hydroxyl group may be attached to a single carbon atom of the alkyl group and is exemplified by hydroxymethyl, dihydroxypropyl, and the like. In some embodiments, the hydroxyalkyl group is -L-OH, in which L is an alkyl group, as defined herein. In other embodiments, the hydroxyalkyl group is -L-C(OH)(R¹)—R², in which L is a covalent bond or an alkyl group, as defined herein, and each of R¹ and R² is, independently, H or alkyl, as defined herein.

By “imidoyl” is meant a moiety including a carbonimidoyl group. In some embodiments, the imidoyl group is C(NR¹)R², in which each of R¹ and R² is, independently, selected from hydrogen, optionally substituted aliphatic, optionally substituted heteroaliphatic, optionally substituted aromatic, optionally substituted heteroaromatic, optionally substituted silyl, optionally substituted alkyl, optionally substituted aryl, optionally substituted alkyl-aryl, or optionally substituted aryl-alkyl, optionally substituted silyloxy, as defined herein, or any combination thereof. In other embodiments, the imidoyl group is —C(NR)H, —C(NR¹)R^{Ak}, or —C(NN¹)R^{Ar}, in which R¹ is hydrogen, optionally substituted aliphatic, optionally substituted heteroaliphatic, optionally substituted aromatic, optionally substituted heteroaromatic, optionally substituted silyl, optionally substituted alkyl, optionally substituted aryl, optionally substituted alkyl-aryl, or optionally substituted aryl-alkyl, or optionally substituted silyloxy; R^{Ak} is an optionally substituted alkyl or an optionally substituted aliphatic; and R^{Ar} is an optionally substituted aryl or an optionally substituted aromatic.

By “imino” is meant a —NR— group. In some embodiments, R is selected from hydrogen, optionally substituted aliphatic, optionally substituted heteroaliphatic, optionally substituted aromatic, or optionally substituted heteroaromatic. In particular embodiments, R is H, optionally substituted alkyl, optionally substituted alkoxy, optionally substituted aryl, optionally substituted aryloxy, optionally substituted alkyl-aryl, or optionally substituted aryl-alkyl.

By “isocyanato” is meant a —NCO group.

By “isocyano” is meant a —NC group.

By “ketone” is meant —C(O)R or a compound including such a group, where R is selected from aliphatic, heteroaliphatic, aromatic, as defined herein, or any combination thereof. An example of a ketone can include R¹C(O)R, in which each of R and R¹ is, independently, selected from aliphatic, haloaliphatic, haloheteroaliphatic, heteroaliphatic, aromatic, aliphatic-aromatic, heteroaliphatic-aromatic, as defined herein, or any combination thereof.

By “nitro” is meant an —NO₂ group.

By “nitroalkyl” is meant an alkyl group, as defined herein, substituted by one to three nitro groups. In some embodiments, the nitroalkyl group is -L-NO, in which L is an alkyl group, as defined herein. In other embodiments, the nitroalkyl group is -L-C(NO)(R¹)—R², in which L is a covalent bond or an alkyl group, as defined herein, and each of R¹ and R² is, independently, H or alkyl, as defined herein.

By “oxo” is meant an ═O group.

By “oxy” is meant —O—.

By “perfluoroalkyl” is meant an alkyl group, as defined herein, having each hydrogen atom substituted with a fluorine atom. Exemplary perfluoroalkyl groups include trifluoromethyl, pentafluoroethyl, etc. In some embodiments, the perfluoroalkyl group is —(CF₂)ₙCF₃, in which n is an integer from 0 to 10.

By “perfluoroalkoxy” is meant an alkoxy group, as defined herein, having each hydrogen atom substituted with a fluorine atom. In some embodiments, the perfluoroalkoxy group is —O—R, in which R is a perfluoroalkyl group, as defined herein.

By “salt” is meant an ionic form of a compound or structure (e.g., any formulas, compounds, or compositions described herein), which includes a cation or anion compound to form an electrically neutral compound or structure. Salts are well known in the art. For example, non-toxic salts are described in Berge S. M. et al., “Pharmaceutical salts,” J. Pharm. Sci. 1977 January; 66(1):1-19; and in “Handbook of Pharmaceutical Salts: Properties, Selection, and Use,” Wiley-VCH, April 2011 (2nd rev. ed., eds. P. H. Stahl and C. G. Wermuth. The salts can be prepared in situ during the final isolation and purification of the compounds of the invention or separately by reacting the free base group with a suitable organic acid (thereby producing an anionic salt) or by reacting the acid group with a suitable metal or organic salt (thereby producing a cationic salt). Representative anionic salts include acetate, adipate, alginate, ascorbate, aspartate, benzenesulfonate, benzoate, bicarbonate, bisulfate, bitartrate, borate, bromide, butyrate, camphorate, camphorsulfonate, chloride, citrate, cyclopentanepropionate, digluconate, dihydrochloride, diphosphate, dodecylsulfate, edetate, ethanesulfonate, fumarate, glucoheptonate, gluconate, glutamate, glycerophosphate, hemisulfate, heptonate, hexanoate, hydrobromide, hydrochloride, hydroiodide, hydroxyethanesulfonate, hydroxynaphthoate, iodide, lactate, lactobionate, laurate, lauryl sulfate, malate, maleate, malonate, mandelate, mesylate, methanesulfonate, methylbromide, methylnitrate, methylsulfate, mucate, 2-naphthalenesulfonate, nicotinate, nitrate, oleate, oxalate, palmitate, pamoate, pectinate, persulfate, 3-phenylpropionate, phosphate, picrate, pivalate, polygalacturonate, propionate, salicylate, stearate, subacetate, succinate, sulfate, tannate, tartrate, theophyllinate, thiocyanate, triethiodide, toluenesulfonate, undecanoate, valerate salts, and the like. Representative cationic salts include metal salts, such as alkali or alkaline earth salts, e.g., barium, calcium (e.g., calcium edetate), lithium, magnesium, potassium, sodium, and the like; other metal salts, such as aluminum, bismuth, iron, and zinc; as well as nontoxic ammonium, quaternary ammonium, and amino cations, including, but not limited to ammonium, tetramethylammonium, tetraethylammonium, methylamine, dimethylamine, trimethylamine, triethylamine, ethylamine, pyridinium, and the like. Other cationic salts include organic salts, such as chloroprocaine, choline, dibenzylethylenediamine, diethanolamine, ethylenediamine, methylglucamine, and procaine. Yet other salts include ammonium, sulfonium, sulfoxonium, phosphonium, iminium, imidazolium, benzimidazolium, amidinium, guanidinium, phosphazinium, phosphazenium, pyridinium, etc., as well as other cationic groups described herein (e.g., optionally substituted isoxazolium, optionally substituted oxazolium, optionally substituted thiazolium, optionally substituted pyrrolium, optionally substituted furanium, optionally substituted thiophenium, optionally substituted imidazolium, optionally substituted pyrazolium, optionally substituted isothiazolium, optionally substituted triazolium, optionally substituted tetrazolium, optionally substituted furazanium, optionally substituted pyridinium, optionally substituted pyrimidinium, optionally substituted pyrazinium, optionally substituted triazinium, optionally substituted tetrazinium, optionally substituted pyridazinium, optionally substituted oxazinium, optionally substituted pyrrolidinium, optionally substituted pyrazolidinium, optionally substituted imidazolinium, optionally substituted isoxazolidinium, optionally substituted oxazolidinium, optionally substituted piperazinium, optionally substituted piperidinium, optionally substituted morpholinium, optionally substituted azepanium, optionally substituted azepinium, optionally substituted indolium, optionally substituted isoindolium, optionally substituted indolizinium, optionally substituted indazolium, optionally substituted benzimidazolium, optionally substituted isoquinolinum, optionally substituted quinolizinium, optionally substituted dehydroquinolizinium, optionally substituted quinolinium, optionally substituted isoindolinium, optionally substituted benzimidazolinium, and optionally substituted purinium).

By “silyl” is meant a —SiR¹R²R³ or —SiR¹R²— group. In some embodiments, each of R¹, R², and R³ is, independently, H, optionally substituted aliphatic, optionally substituted heteroaliphatic, optionally substituted aromatic, optionally substituted heteroaromatic, or optionally substituted amino. In particular embodiments, each of R¹, R², and R³ is, independently, H, optionally substituted alkyl, optionally substituted alkoxy, optionally substituted aryl, optionally substituted aryloxy, optionally substituted alkyl-aryl, optionally substituted aryl-alkyl, or optionally substituted amino. In other embodiments, the silyl group is —Si(R)ₐ(OR)_{b}(NR₂)_{c}, in which each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl.

By “silyloxy” is meant —OR, where R is an optionally substituted silyl group, as described herein. In some embodiments, the silyloxy group is —O—SiR¹R²R³, in which each of R¹, R², and R³ is, independently, H, optionally substituted aliphatic, optionally substituted heteroaliphatic, optionally substituted aromatic, optionally substituted heteroaromatic, or optionally substituted amino. In particular embodiments, each of R¹, R², and R³ is, independently, H, optionally substituted alkyl, optionally substituted alkoxy, optionally substituted aryl, optionally substituted aryloxy, optionally substituted alkyl-aryl, optionally substituted aryl-alkyl, or optionally substituted amino. In other embodiments, the silyloxy group is —O—Si(R)ₐ(OR)_{b}(NR₂)_{c}, in which each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl

By “sulfinyl” is meant an —S(O)— group.

By “sulfo” is meant an —S(O)₂OH group.

By “sulfonyl” or “sulfonate” is meant an —S(O)₂— group or a —SO₂R, where R is selected from hydrogen, aliphatic, heteroaliphatic, haloaliphatic, haloheteroaliphatic, aromatic, as defined herein, or any combination thereof.

By “thioalkyl” is meant an alkyl group, as defined herein, attached to the parent molecular group through a sulfur atom. Exemplary unsubstituted thioalkyl groups include C₁₋₆ thioalkyl. In some embodiments, the thioalkyl group is —S—R, in which R is an alkyl group, as defined herein.

By “thiol” is meant an —SH group.

A person of ordinary skill in the art would recognize that the definitions provided above are not intended to include impermissible substitution patterns (e.g., methyl substituted with 5 different groups, and the like). Such impermissible substitution patterns are easily recognized by a person of ordinary skill in the art. Any functional group disclosed herein and/or defined above can be substituted or unsubstituted, unless otherwise indicated therein.

As used herein, the term “about” means +/−10% of any recited value. As used herein, this term modifies any recited value, range of values, or endpoints of one or more ranges.

As used herein, the terms “top,” “bottom,” “upper,” “lower,” “above,” and “below” are used to provide a relative relationship between structures. The use of these terms does not indicate or require that a particular structure must be located at a particular location in the apparatus.

Other features and advantages of the invention will be apparent from the following description and the claims.

### BRIEF DESCRIPTION OF THE DRAWINGS

FIG. 1A-1D shows process flow diagram depicting operations for a method in accordance with certain disclosed embodiments.

FIG. 2A-2B shows timing sequence diagrams for examples of cycles in a method in accordance with certain disclosed embodiments.

FIG. 3A-3C shows non-limiting characterization of deposited films using a first process 301 including plasma treatment and a second process 302 including thermal conversion within plasma treatment.

FIG. 4 is a schematic diagram of an example process chamber 400 for performing certain disclosed embodiments.

FIG. 5 is a schematic diagram of an example process tool 500 for performing certain disclosed embodiments.

### DETAILED DESCRIPTION

Semiconductor fabrication processes often involve deposition of silicon nitride material. In one example, silicon nitride may be used in semiconductor device fabrication as diffusion barriers, gate insulators, sidewall spacers, liners, strained films in transistors, etch stop layers, and encapsulation layers. Conformal silicon nitride layers may also be used in other applications. For example, silicon nitride may be used during fabrication of memory structures.

The presence disclosure relates to methods for depositing a silicon nitride film. In particular embodiments, the film is deposited by way of a hybrid ALD process, which includes thermal conversion of a deposited layer and then plasma treatment thereafter. The deposited layer can include both carbon and silicon atoms, and thermal conversion can be conducted in the presences of a nitrogen-containing reactant. Plasma treatment can be conducted in the presence of a source gas, in which nitrogen-containing energetic species are delivered to the substrate.

In particular, the combination of thermal conversion and plasma treatment provides a conformal film. Furthermore, the thermal conversion and plasma treatment operations can be conducted in cycles, until the desired thickness of the film is obtained. In one embodiment, thermal conversion and plasma treatment is conducted in every cycle (e.g., in every ALD cycle).

Without wishing to be limited be mechanism, the use of plasma can generate an energetic species (e.g., a radical, an ion, a neutral, a metastable, and the like) that can modify a surface, which can allow for conformal film deposition at a lower temperature than a deposition process lacking plasma treatment. In particular embodiments, use of a nitrogen-containing reactant during thermal conversion can act as a catalyst during plasma treatment.

In one embodiment, thermal conversion provides a conformal film, and plasma treatment allows the carbon content within the film to be tuned. In another embodiment, carbon content can be tuned by not using plasma treatment, but by altering the process temperature to tune the carbon content.

Thermal conversion can include an ALD technique, in which thin layers of material are deposited using sequential self-limiting reactions. Typically, an ALD cycle includes operations to deliver and adsorb at least one reactant to the substrate surface, and then react the adsorbed reactant with one or more reactants to form the partial layer of film. As an example, a silicon nitride deposition cycle may include the following operations: (i) delivery/adsorption of a silicon-containing precursor, (ii) purging of the silicon precursor from the chamber, (iii) delivery of a nitrogen-containing reactant or nitrogen-containing gas, and (iv) purging of the nitrogen-containing reactant from the chamber.

When thermal conversion is employed with plasma treatment, each cycle can include both operations in a hybrid ALD process. As an example, a silicon nitride deposition cycle may include the following operations: (i) delivery/adsorption of a silicon-containing precursor, (ii) purging of the silicon precursor from the chamber, (iii) delivery of a nitrogen-containing reactant or nitrogen-containing gas, (iv) purging of the nitrogen-containing reactant from the chamber, (v) delivery of an energetic species (e.g., a radical species); and (vi) purging of the energetic species from the chamber.

Any energetic species can be employed during deposition or plasma treatment. As used herein, an “energetic species” can include any species that is reactive with one or more components provided during a deposition process. Such components can include a precursor, a deposited layer, and the like. Non-limiting examples of energetic species include radicals, metastables, ions, neutral species, plasma, photons, radiation, excited molecules, excited atoms, a reactive species, or others described herein. In one non-limiting embodiment, the metastable has an energy of about 0.01-1 eV. In another non-limiting embodiment, the ion has an energy of about 100-1000 eV. In yet another non-limiting embodiment, the energetic species has an energy of about 0.01-1000 eV. Any description herein related to radicals and metastables may, in some non-limiting instances, encompass any energetic species described herein.

Unlike a chemical vapor deposition (CVD) technique, ALD processes use surface-mediated deposition reactions to deposit films on a layer-by-layer basis. In one example of an ALD process, a substrate surface that includes a population of surface active sites is exposed to a gas phase distribution of a first precursor, such as a silicon-containing precursor, in a dose provided to a chamber configured to house a substrate. Molecules of this first precursor are adsorbed onto the substrate surface, including chemisorbed species and/or physisorbed molecules of the first precursor. It should be understood that when the compound is adsorbed onto the substrate surface as described herein, the adsorbed layer may include the compound as well as derivatives of the compound. For example, an adsorbed layer of a silicon-containing precursor may include the silicon-containing precursor as well as derivatives of the silicon-containing precursor. After a first precursor dose, the chamber is then evacuated to remove most or all of first precursor remaining in gas phase so that mostly or only the adsorbed species remain. In some implementations, the chamber may not be fully evacuated. For example, the chamber may be evacuated such that the partial pressure of the first precursor in gas phase is sufficiently low to mitigate a reaction. A second reactant, such as a nitrogen-containing reactant, is introduced to the chamber so that some of these molecules react with the first precursor adsorbed on the surface. In some processes, the second reactant reacts immediately with the adsorbed first precursor. The chamber may then be evacuated again to remove unbound second reactant molecules. As described above, in some embodiments the chamber may not be completely evacuated. Within a single cycle, a further operation can include introducing a radical species to the chamber. The chamber may then be evacuated again to remove unbound radical species. Additional ALD cycles may be used to build film thickness.

In certain embodiments, an ALD first precursor dose partially saturates the substrate surface. In some embodiments, the dose phase of an ALD cycle concludes before the precursor contacts the substrate to evenly saturate the surface. Typically, the precursor flow is turned off or diverted at this point, and only purge gas flows. By operating in this sub-saturation regime, the ALD process reduces the cycle time and increases throughput. However, because precursor adsorption is not saturation limited, the adsorbed precursor concentration may vary slightly across the substrate surface. Examples of ALD processes operating in the sub-saturation regime are provided in U.S. patent application Ser. No. 14/061,587 (now U.S. Pat. No. 9,355,839), filed Oct. 23, 2013, titled “SUB-SATURATED ATOMIC LAYER DEPOSITION AND CONFORMAL FILM DEPOSITION,” which is incorporated herein by reference in its entirety.

As described, in some implementations, the ALD methods include plasma activation. As described herein, the ALD methods and apparatuses described herein may be conformal film deposition (CFD) methods, which are described generally in U.S. patent application Ser. No. 13/084,399 (now U.S. Pat. No. 8,728,956), filed Apr. 11, 2011, and titled “PLASMA ACTIVATED CONFORMAL FILM DEPOSITION,” and in U.S. patent application Ser. No. 13/084,305 (U.S. Patent Pub. No. 2011/0256734), filed Apr. 11, 2011, and titled “SILICON NITRIDE FILMS AND METHODS,” which are herein incorporated by reference in their entireties.

The concept of an ALD “cycle” is relevant to the discussion of various embodiments herein. Generally, a cycle is the minimum set of operations used to perform a surface deposition reaction one time. The result of one cycle is production of at least a partial silicon nitride film layer on a substrate surface. Typically, an ALD cycle includes operations to deliver and adsorb at least one reactant to the substrate surface, and then react the adsorbed reactant with one or more reactants to form the partial layer of film. The cycle may include certain ancillary operations such as sweeping one of the reactants or byproducts and/or treating the partial film as deposited. Generally, a cycle contains one instance of a unique sequence of operations. ALD cycles may be used to build film thickness.

Reference is made herein in detail to specific embodiments of the disclosure. Examples of the specific embodiments are illustrated in the accompanying drawings. While the disclosure will be described in conjunction with these specific embodiments, it will be understood that it is not intended to limit the disclosure to such specific embodiments. On the contrary, it is intended to cover alternatives, modifications, and equivalents as may be included within the spirit and scope of the disclosure. In the following description, numerous specific details are set forth in order to provide a thorough understanding of the present disclosure. The present disclosure may be practiced without some or all of these specific details. In other instances, well known process operations have not been described in detail so as to not unnecessarily obscure the present disclosure.

### Hybrid ALD

The methods herein generally related to a hybrid ALD process to provide a silicon nitride (SiN) film, a doped SiN film (e.g., a carbon-doped SiN film), or silicon carbonitride (SiCN). In particular embodiments, the film is conformal.

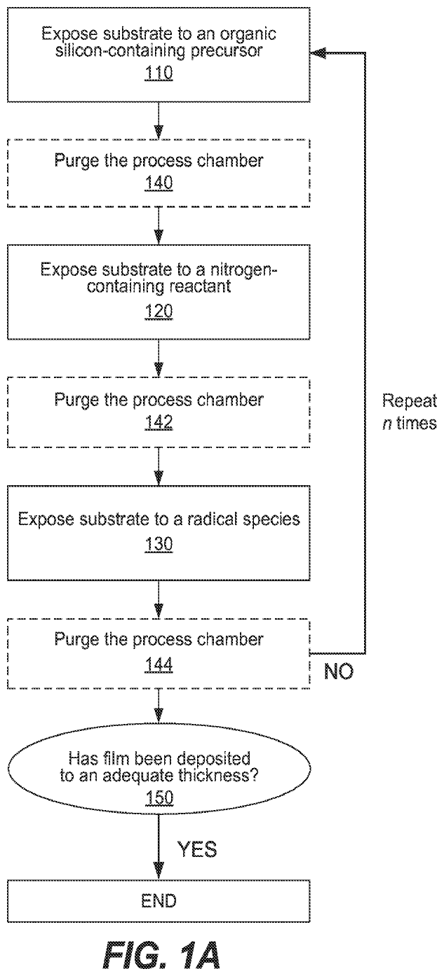

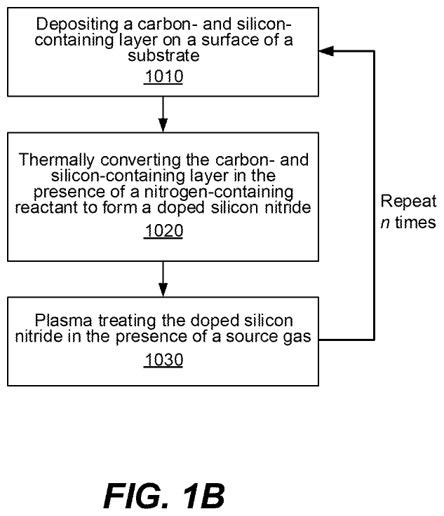

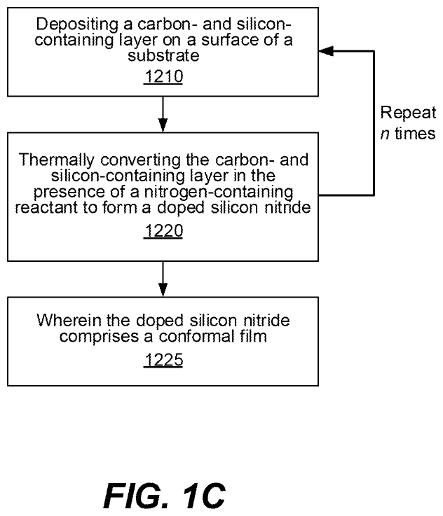

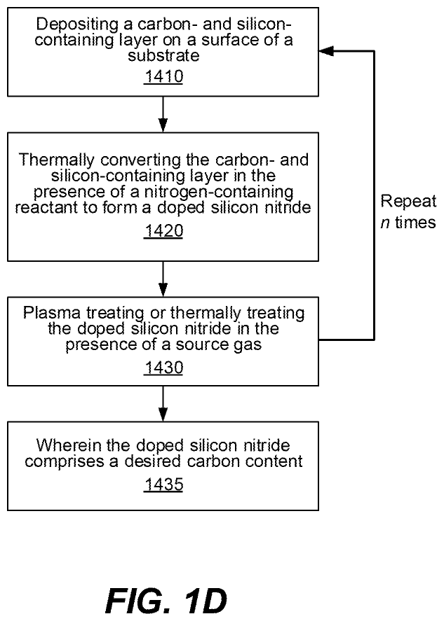

FIG. 1A provides a non-limiting method having various exposure operations, which can be repeated an n number of times to provide a film of adequate thickness. The film can be provided on any useful substrate. The substrate may be a silicon wafer, e.g., a 200-mm wafer, a 300-mm wafer, or a 450-mm wafer, including wafers having one or more layers of material, such as dielectric, conducting, or semi-conducting material deposited thereon. The substrate can include structures, such as high aspect ratio (HAR) structures, as described herein.

Substrates may have “features” such as via or contact holes, which may be characterized by one or more of narrow and/or re-entrant openings, constrictions within the feature, and high aspect ratios. The feature may be formed in one or more of the above described layers. One example of a feature is a hole or via in a semiconductor substrate or a layer on the substrate. In some embodiments, the feature may have an aspect ratio of at least about 2:1, at least about 4:1, at least about 6:1, at least about 10:1, or higher. The feature may also have a dimension near the opening, e.g., an opening diameter or line width of between about 10 nm to 500 nm, for example between about 25 nm and about 300 nm. Disclosed methods may be performed on substrates with features having an opening less than about 150 nm. A feature via or trench may be referred to as an unfilled feature or a feature. A feature that may have a re-entrant profile that narrows from the bottom, closed end, or interior of the feature to the feature opening.

In any method herein, an initial operation can include providing a substrate to a process chamber. The process chamber may be set to a chamber pressure between about 10 mTorr and about 30 Torr, or between about 1 to 3 Torr or between about 0.5 to 22 Torr. Such chamber pressures may be used throughout operations 110-144 as described herein.

The substrate may be heated to a substrate temperature between about 25° C. and about 900° C., or between about 500° C. and about 700° C. It will be understood that substrate temperature as used herein refers to the temperature that the pedestal holding the substrate is set at and that in some embodiments, the substrate when provided to the process chamber on the pedestal may be heated to the desired substrate temperature prior to processing the substrate. The substrate temperature may be the same throughout operations 110-144 as described herein. Alternatively, the substrate temperature may be modified (e.g., increased or decreased) to obtain a desired carbon content.

Returning FIG. 1A, in operation 110, the substrate is exposed to an organic silicon-containing precursor. The organic silicon-containing precursor adsorbs onto a surface of the substrate. Operations 110-144 may constitute an atomic layer deposition cycle. Embodiments described herein involve thermal atomic layer deposition performed in cycles such that plasma is not ignited during either exposure to an organic silicon-containing precursor or exposure to a nitrogen-containing reactant, and then a plasma can be optionally ignited after such exposure steps.

The organic silicon-containing precursor used during operation 110 may be an amino silane, an isocyanato silane, an azido silane, a hydrazino silane, a siloxane or a derivative thereof, a mixed silane, a silyl amine, a silazane or a derivative thereof, a mixed amine, a cyclic silazane, a cyclic siloxane, an amino siloxane or a derivative thereof, a silanol, or a carbonyloxy silane, as described herein. In particular embodiments, the organic silicon-containing precursor has a structure of formula (I) or (II), as also described herein. In various embodiments, subsequent purge operations as described below may remove adsorbed organic silicon-containing precursor from the surface of the substrate.

In some embodiments, adsorption on the surface of the substrate may be form a thin, carbon- and silicon-containing layer on the surface of the substrate. The thin layer may be less than a monolayer, and may have a thickness between about 0.2 Å and about 3 Å (e.g., about 0.2 to 0.4 Å).

In some embodiments, the organic silicon-containing precursor is flowed to a chamber housing the substrate at a flow rate between about 100 sccm and about 5000 sccm (e.g., about 100 to 2000 sccm). The precursor can be flowed for any useful period (e.g., about 0.1 to 10 seconds) and any useful pressure (e.g., about 1 to 25 Torr).

During operation 110, a push gas may be flowed. The push gas may be any inert gas, such as nitrogen (N₂), argon (Ar), or any other listed herein. The push gas may be provided to assist with pressure and/or temperature control of the process chamber, evaporation of a liquid reactant, more rapid delivery of the reactant, and/or as a sweep gas for removing process gases from the process chamber and/or process chamber plumbing. In some embodiments, the push gas is flowed to a chamber housing the substrate at a flow rate between about 100 sccm and about 5000 sccm (e.g., about 500 to 2000 sccm). Flow of the push gas with the organic silicon-containing precursor can allow for dilution of the precursor, as well as pressure stability during operation.

In operation 140, the process chamber is optionally purged to remove organic silicon-containing precursor molecules that did not adsorb onto the substrate surface.

Purging the chamber may involve flowing a purge gas or a sweep gas, which may be a carrier gas used in other operations or may be a different gas. In some embodiments, purging may involve evacuating the chamber. Examples of purge gases include argon (Ar), nitrogen (N₂), hydrogen (H₂), helium (He), oxygen (O₂), krypton (Kr), xenon (Xe), neon (Ne), and combinations thereof. In various embodiments, the purge gas is an inert gas. The purge gas may include one or more gases. In some embodiments, operation 140 may include one or more evacuation subphases for evacuating the process chamber. Alternatively, it will be appreciated that operation 140 may be omitted in some embodiments. Operation 140 may have any suitable duration, such as between about 0 seconds and about 60 seconds, for example about 0.01 seconds. In some embodiments, increasing a flow rate of one or more purge gases may decrease the duration of operation 140. For example, a purge gas flow rate may be adjusted according to various reactant thermodynamic characteristics and/or geometric characteristics of the process chamber and/or process chamber plumbing for modifying the duration of operation 140. In one non-limiting example, the duration of a purge phase may be adjusted by modulating purge gas flow rate. This may reduce deposition cycle time, which may improve substrate throughput. After a purge, the organic silicon-containing precursor molecules remain adsorbed onto the substrate surface.

The purge gas can be flowed to a chamber housing the substrate at a flow rate between about 1000 sccm and about 40000 sccm (e.g., about 100 to 2000 sccm). The purge gas can be flowed for any useful period (e.g., about 0.1 to 10 seconds) and any useful pressure (e.g., about 0.5 to 25 Torr).

In operation 120, the substrate is exposed to a nitrogen-containing reactant gas without a plasma to form silicon nitride on the surface. In various embodiments, the nitrogen-containing reactant is nitrogen gas (N₂). In some embodiments, the nitrogen-containing reactant is ammonia (NH₃) or a deuterated form thereof, such as singly deuterated ammonia (NH₂D), doubly deuterated ammonia (NHD₂), or triply deuterated ammonia (ND₃). In various embodiments, the nitrogen-containing reactant is a hydrazine-based compound, e.g., R¹R²N—NR³R⁴, in which each of R¹, R², R³, and R⁴ is, independently, H, optionally substituted aliphatic, or optionally substituted aromatic. In other embodiments, the nitrogen-containing reactant is an amine-based compound, e.g., NR¹R²R³, in which each of R¹, R², and R³ is, independently, H, optionally substituted aliphatic, or optionally substituted aromatic. In some embodiments, the hydrazine-based compound is hydrazine (H₂NNH₂), t-butylhydrazine (H₂NNHtBu), or tetramethyl hydrazine (Me₂NNMe₂). Combinations of these nitrogen-containing reactants can also be employed.

The nitrogen-containing reactant can be flowed to a chamber housing the substrate at a flow rate between about 1000 sccm and about 40000 sccm (e.g., about 2000 to 10000 sccm). The nitrogen-containing reactant can be flowed for any useful period (e.g., about 0.5 to 40 seconds) and any useful pressure (e.g., about 1 to 25 Torr).

The nitrogen-containing reactant gas can be used with a push gas or a carrier gas. The push gas or the carrier gas be an inert gas, such as those described herein. The push gas or carrier gas can be flowed to a chamber housing the substrate at a flow rate between about 100 sccm and about 5000 sccm (e.g., about 500 to 2000 sccm). The push gas or carrier gas can be flowed for any useful period (e.g., about 0.5 to 40 seconds) and any useful pressure (e.g., about 1 to 25 Torr).

In yet other embodiments, the nitrogen-containing reactant can further include co-flow with a reducing gas. Non-limiting reducing gases can include hydrogen (H₂). In one non-limiting instance, operation 120 includes a nitrogen-containing reactant (e.g., NH₃ or N₂), a reducing gas (e.g., H₂), and optionally an inert gas (e.g., N₂). The reducing gas can be flowed to a chamber housing the substrate at a flow rate between about 0 and about 10000 sccm (e.g., about 0 to 5000 sccm). The reducing gas can be flowed for any useful period (e.g., about 0.5 to 40 seconds) and any useful pressure (e.g., about 1 to 25 Torr).

During operation 110 and/or 120, the semiconductor substrate may reside on a pedestal set to a temperature between about 300° C. and about 700° C. In some embodiments, the semiconductor substrate resides in a chamber set to a chamber pressure between about 10 mTorr and about 30 Torr. In various embodiments, each thermal atomic layer deposition cycle also includes purging a chamber housing the semiconductor substrate between exposing the semiconductor substrate to the silicon-containing precursor and exposing the semiconductor substrate to the nitrogen-containing reactant.

For example, in optional operation 142, the chamber is optionally purged to remove any residual byproducts. Operation 142 may be performed using any of the conditions described above with respect to operation 140. For example, in some embodiments, the chamber is purged by flowing an inert gas, such as nitrogen or argon, to pump excess molecules and/or residual byproducts from the chamber.

In operation 130, the substrate is exposed to an energetic species (e.g., a radical species). In various embodiments, a radical species is generated from a source gas, in which the source gas includes a nitrogen atom. In certain embodiments, the source gas is a nitrogen gas (N₂), ammonia (NH₃), a hydrazine-based compound, e.g., R¹R²N—NR³R⁴, and/or an amino-based compound, e.g., NR¹R²R³, as described herein, as well as deuterated forms of any of these (e.g., singly deuterated ammonia (NH₂D), doubly deuterated ammonia (NHD₂), or triply deuterated ammonia (ND₃)). In yet other embodiments, the source gas can further include co-flow with a reducing gas. In particular embodiments, the radical species is a NH* radical species or a NR* radical species, in which R is H, aliphatic, aromatic, heteroaliphatic, or heteroaromatic. The NH* radical species can be generated in any useful manner, such as by NH₃, N₂/NH₃, or N₂/H₂ plasma. During plasma generation, any useful process conditions can be modified, in which conditions can include pressure, gas ratio mixture, and plasma power (e.g., in which higher power can provide a higher radical flux).

Other radical species can include elemental nitrogen radicals, ammonia radicals, and amine radicals. Examples of amine radicals include but are not limited to radicals of methylamine, dimethylamine, and aniline. In some embodiments, all or substantially all the radicals can be in the ground state, e.g., at least about 90% or 95% of the radicals adjacent the substrate are in the ground state. In some embodiments, as discussed in further detail below, the radical species can be produced by a remote plasma source.

In particular embodiments, the radical species is formed with a plasma formed from a combination of N₂ with NH₃ or a combination of N₂ with H₂. As can be seen, a plasma can be formed by employing only a nitrogen-containing reactant or a combination of a nitrogen-containing reactant with a reducing gas (e.g., such as hydrogen or H₂). Furthermore, an inert gas can be employed with the nitrogen-containing reactant. The plasma can be delivered to a chamber housing the substrate at a flow rate between about 0 and about 10000 sccm (e.g., about 0 to 5000 sccm). The reducing gas can be flowed for any useful period (e.g., about 0.5 to 40 seconds) and any useful pressure (e.g., about 0.5 to 25 Torr).

In one embodiment, plasma is formed in the presence of a first nitrogen-containing reactant (e.g., having a flow rate of about 20 to 500 sccm), an inert gas (e.g., having a flow rate of about 1000 to 40000 sccm), and a reducing gas (e.g., having a flow rate of about 0 to 200 sccm). In particular embodiments, the plasma is formed in the presence of a first nitrogen-containing reactant including NH₃ (e.g., having a flow rate of about 50 to 250 sccm), an inert gas including N₂ (e.g., having a flow rate of about 5000 to 25000 sccm), and a reducing gas including H₂ (e.g., having a flow rate of about 0 to 100 sccm).

The plasma power may be between about 75 W and about 12000 W per 300 mm wafer surface area. The plasma may be generated remotely (such as in a remote plasma generator) or directly in a chamber housing the substrate (i.e., in situ). The in situ plasma may be ignited at a power per substrate area between about 0.2122 W/cm² and about 2.122 W/cm². For example, the power may range from about 600 W to about 6000 W for a chamber processing four 300 mm wafers. Plasmas for ALD processes may be generated by applying a radio frequency (RF) field to a gas using two capacitively coupled plates. Ionization of the gas between plates by the RF field ignites the plasma, creating free electrons in the plasma discharge region. These electrons are accelerated by the RF field and may collide with gas phase reactant molecules. Collision of these electrons with reactant molecules may form radical species that participate in the deposition process.

During operation 130, it will be appreciated that the RF field may be coupled via any suitable electrodes. Non-limiting examples of electrodes include process gas distribution showerheads and substrate support pedestals. It will be appreciated that plasmas for ALD processes may be formed by one or more suitable methods other than capacitive coupling of an RF field to a gas. In some embodiments, the plasma is a remote plasma, such that a nitrogen-containing reactant or a source gas is ignited in a remote plasma generator upstream of the station, then delivered to the station where the substrate is housed.

In operation 144, the chamber is optionally purged to remove any residual byproducts. Operation 144 may be performed using any of the conditions described above with respect to operation 140. For example, in some embodiments, the chamber is purged by flowing an inert gas, such as nitrogen or argon, to pump excess molecules and/or residual byproducts from the chamber.

In operation 150, it is determined whether the desired thickness of silicon nitride film has been deposited. If not, operations 110-144 are repeated in sufficient cycles to deposit a desired thickness of silicon nitride. Any suitable number of deposition cycles may be included in an ALD process to deposit a desired film thickness of silicon nitride. For example, about 20 to about 40 deposition cycles may be performed to deposit a silicon nitride film on the substrate using disclosed embodiments. In some embodiments, 20 to 40 depositions are performed.

FIG. 1B provides a non-limiting method having various exposure operations, which can be repeated an n number of times to provide a film of desired thickness. In operation 1010, a carbon- and silicon-containing layer is deposited on a surface of substrate. Deposition can include delivering an organic silicon-containing precursor to the substrate and optionally purging to remove adsorbed organic silicon-containing precursor from the surface of the substrate.

In operation 1020, the carbon- and silicon-containing layer can be thermally converted in the presence of a nitrogen-containing reactant to form a doped silicon nitride. The nitrogen-containing reactant can be any described herein. Thermal conversion can include delivering a nitrogen-containing reactant to the substrate and optionally purging to remove adsorbed nitrogen-containing reactant from the surface of the substrate.

In operation 1030, the doped silicon nitride can be plasma treated in the presence of a source gas. The source gas can include a nitrogen-containing reactant, e.g., any described herein; and the plasma can include a radical species formed in the presence of the source gas. Plasma treatment can include delivering a radical species to the substrate and optionally purging to remove adsorbed radical species from the surface of the substrate.

Some methods do not include a plasma treatment operation. For instance, while plasma treatment may be useful to tune the carbon content of a deposited film, thermal conversion may be used solely to obtain a conformal film. FIG. 1C provides a non-limiting method having various exposure operations, which can be repeated an n number of times to provide a conformal film of desired thickness.

In operation 1210, a carbon- and silicon-containing layer is deposited on a surface of substrate. Deposition can include delivering an organic silicon-containing precursor to the substrate and optionally purging to remove adsorbed organic silicon-containing precursor from the surface of the substrate.

In operation 1220, the carbon- and silicon-containing layer can be thermally converted in the presence of a nitrogen-containing reactant to form a doped silicon nitride. The nitrogen-containing reactant can be any described herein. Thermal conversion can include delivering a nitrogen-containing reactant to the substrate and optionally purging to remove adsorbed nitrogen-containing reactant from the surface of the substrate. Repeating operations 1210 and 1220 can provide a doped silicon film comprising a conformal film 1225.

Other methods include a plasma treatment operation or a thermal treatment operation to provide a film having a desired carbon content. FIG. 1D provides a non-limiting method having various exposure operations, which can be repeated an n number of times to provide a doped silicon nitride film of desired thickness and desired carbon content.

In operation 1410, a carbon- and silicon-containing layer is deposited on a surface of substrate. Deposition can include delivering an organic silicon-containing precursor to the substrate and optionally purging to remove adsorbed organic silicon-containing precursor from the surface of the substrate.

In operation 1420, the carbon- and silicon-containing layer can be thermally converted in the presence of a nitrogen-containing reactant to form a doped silicon nitride. The nitrogen-containing reactant can be any described herein. Thermal conversion can include delivering a nitrogen-containing reactant to the substrate and optionally purging to remove adsorbed nitrogen-containing reactant from the surface of the substrate.

In operation 1430, the doped silicon nitride can be plasma treated or thermally treated in the presence of a source gas. In one embodiment, the source gas can include a nitrogen-containing reactant, e.g., any described herein; and the plasma can include a radical species formed in the presence of the source gas. Plasma treatment can include delivering an energetic species (e.g., a radical species) to the substrate and optionally purging to remove adsorbed radical species from the surface of the substrate. In another embodiment, the thermal treatment includes a source gas to provide a tuned carbon content. Non-limiting source gases can include an inert gas (e.g., nitrogen (N₂), argon (Ar), and the like), which may include or not include hydrogen gas (H₂).

Carbon content can be tuned by modifying the RF power and/or RF time during plasma treatment. In one instance, high carbon doping can be provided with a plasma treatment having a low RF power and/or a short RF strike (e.g., a plasma exposure time of about 10 ms to 2 s or from about 50 ms to 1 s). In another instance, low carbon doping can be provided with a plasma treatment having a higher RF power and/or a longer RF strike (e.g., a plasma exposure time of about 1 s to 5 s). In particular embodiments, the substrate is maintained at a temperature of about 650° C. (e.g., by way of maintaining the pedestal at temperature of about 650° C.). Repeating operations 1410-1430 can provide a doped silicon film comprising a desired carbon content 1435.

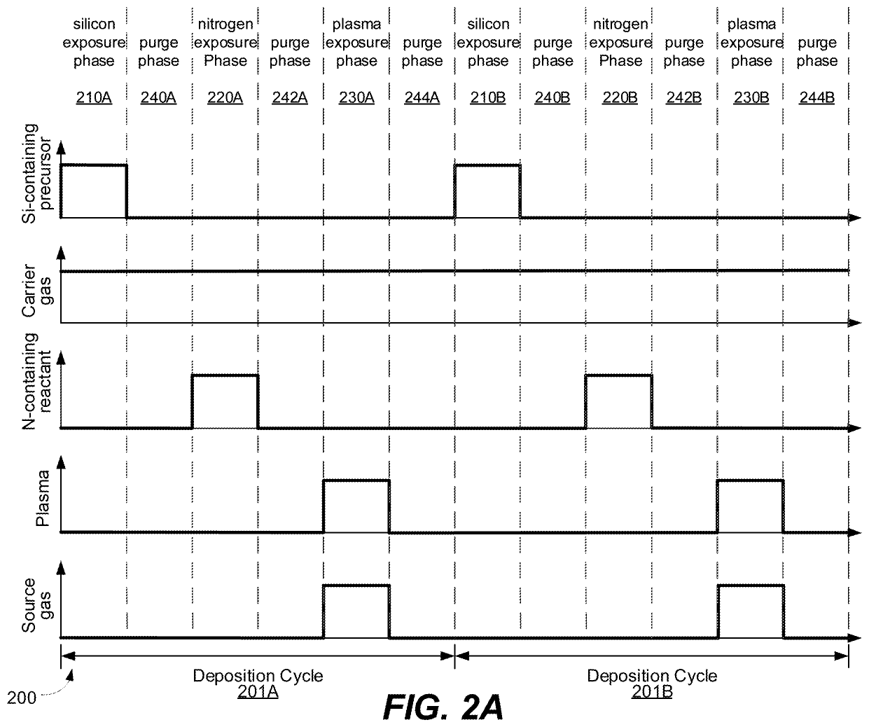

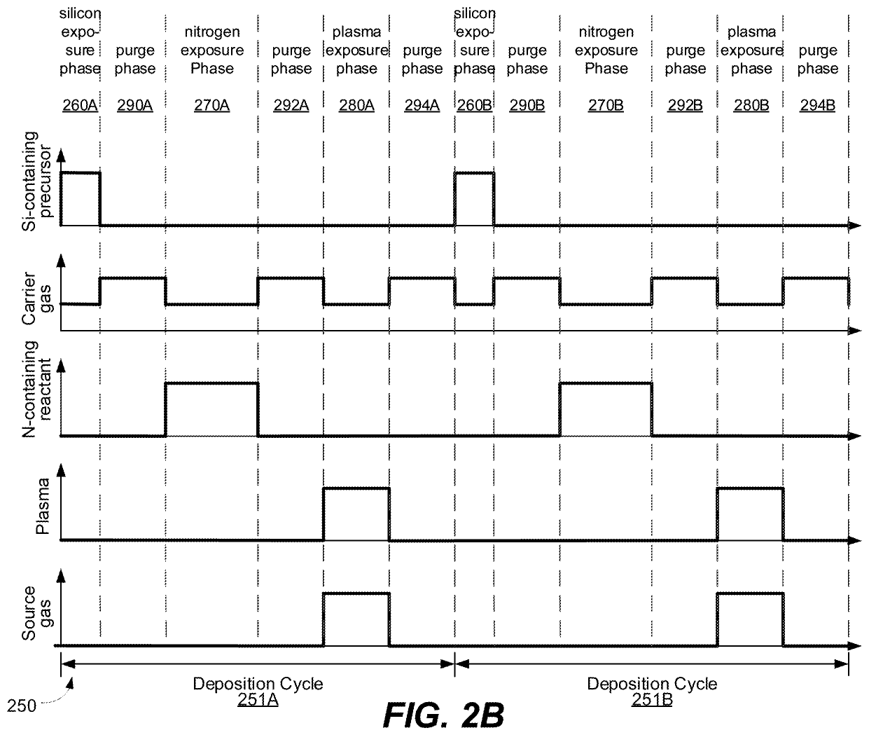

FIG. 2A provides a timing sequence diagram showing an example of cycles in a method in accordance with certain disclosed embodiments. The timing sequence diagram shows the on or off phase for flows of organic silicon-containing precursor gas, carrier gas, nitrogen-containing reactant gas, plasma, and source gas. FIG. 2A includes a process 200 having two deposition cycles—deposition cycle 201A and deposition cycle 201B. Note that although only two deposition cycles are depicted, more deposition cycles may be performed.

Deposition cycle 201A includes a silicon exposure phase 210A, a purge phase 240A, a nitrogen exposure phase 220A, a purge phase 242A, a plasma exposure phase 230A, and a purge phase 244A. During the silicon exposure phase 210A, the carrier gas flow (e.g., inert gas flow) may continue to be on while the silicon-containing precursor gas flow is turned on. Nitrogen-containing reactant gas flow remains off, and source gas flow is turned off. This may correspond to operation 110 of FIG. 1A. During purge phase 240A, the carrier gas may continue to flow to help remove excess molecules from the chamber. During this phase, the silicon-containing precursor gas flow is turned off, the nitrogen-containing reactant gas flow is off, and the source gas flow is also turned off. This may correspond to operation 140 of FIG. 1A.

During nitrogen exposure phase 220A, a carrier gas may continue to flow. In some embodiments, the carrier gas is used to help deliver a nitrogen-containing reactant gas to the chamber and may be diverted or flowed into the chamber. During this phase, silicon-containing precursor gas flow is turned off, and source gas flow is turned off while nitrogen-containing reactant gas flow is turned on. This may correspond to operation 120 of FIG. 1A. During purge phase 242A, the carrier gas flow may continue to be on and the carrier gas may act as a purge gas to remove excess molecules and/or byproducts from the chamber. Silicon-containing precursor gas flow, nitrogen-containing reactant gas flow, and source gas flow are turned off.

During plasma exposure phase 230A, a carrier gas may continue to flow. In some embodiments, the carrier gas is used to help deliver a radical species obtained from a source gas. During this phase, silicon-containing precursor gas flow and nitrogen-containing reactant gas flow are turned off, and source gas flow is turned on. This may correspond to operation 130 of FIG. 1A. During purge phase 244A, the carrier gas flow may continue to be on and the carrier gas may act as a purge gas to remove excess radical species, molecules, and/or byproducts from the chamber. Silicon-containing precursor gas flow and nitrogen-containing reactant gas flow are turned off.

In this example of FIG. 2A, it is determined that the silicon nitride film deposited is of insufficient thickness and another deposition cycle 201B is performed. Deposition cycle 201B includes silicon-containing precursor exposure phase 210B, purge phase 240B, nitrogen-containing reactant exposure phase 220B, purge phase 242B, plasma exposure phase 230B, and purge phase 244B. During silicon-containing precursor exposure phase 210B, a carrier gas may be flowed and a silicon-containing precursor gas flow is turned on, while nitrogen-containing reactant gas flow and source gas flow are turned off. This may correspond to a repeated operation of operation 110 of FIG. 1A after determining in operation 150 that the film is not deposited to an adequate thickness. During purge phase 240B, the carrier gas flow remains on while silicon-containing precursor gas flow is turned off and both nitrogen-containing reactant gas flow and source gas flow remain off. This may correspond to a repeated operation of operation 140 of FIG. 1A. During nitrogen exposure phase 220B, the carrier gas flow may remain on while the nitrogen-containing reactant gas flow is turned on and silicon-containing precursor gas flow and source gas flow are turned off. This may correspond to a repeated operation of operation 120 of FIG. 1A. During purge phase 242B, the carrier gas flow may remain on while the silicon-containing precursor gas flow, nitrogen-containing reactant gas flow, and source gas flows are turned off.

During plasma exposure phase 230B, a carrier gas flow and source gas flow may remain on while silicon-containing precursor gas flow and nitrogen-containing reactant gas flow are turned off. This may correspond to operation 130 of FIG. 1A. During purge phase 244B, the carrier gas flow and source gas flow may remain on while the silicon-containing precursor gas flow and nitrogen-containing reactant gas flow are turned off. Although two deposition cycles are depicted in FIG. 2A, it will be understood that additional deposition cycles may also be performed.

The timing and flow rate of the gases can be modified to provide beneficial deposition conditions, such as thickness of deposited layers and desired carbon content within the film. FIG. 2B provides a timing sequence diagram showing an example of cycles in a method in accordance with certain disclosed embodiments. The timing sequence diagram shows the on or off phase for flows of organic silicon-containing precursor gas, carrier gas, nitrogen-containing reactant gas, plasma, and source gas. FIG. 2B includes a process 250 having two deposition cycles—deposition cycle 251A and deposition cycle 251B. Note that although only two deposition cycles are depicted, more deposition cycles may be performed.

Deposition cycle 251A includes a silicon exposure phase 260A, a purge phase 290A, a nitrogen exposure phase 270A, a purge phase 292A, a plasma exposure phase 280A, and a purge phase 294A. During the silicon exposure phase 260A, the carrier gas flow (e.g., inert gas flow) may continue to be on while the silicon-containing precursor gas flow is turned on. Nitrogen-containing reactant gas flow remains off, and source gas flow is turned off. As can be seen, the period of the silicon exposure phase 260A can be shortened, as compared to the same phase 210A in FIG. 2A.

During purge phase 290A, the carrier gas may continue to flow to help remove excess molecules from the chamber. In particular embodiments, the flow rate of the carrier gas can be increased to further enhance removal of excess molecules, as seen in purge phase 290A. During this phase, the silicon-containing precursor gas flow is turned off, the nitrogen-containing reactant gas flow is off, and the source gas flow is also turned off. This may correspond to operation 140 of FIG. 1A.

During nitrogen exposure phase 270A, a carrier gas may continue to flow. In particular embodiments, the flow rate of the carrier gas can be decreased, as compared to that in the purge phase 290A, to reduce consumption of the nitrogen-containing reactant within the nitrogen exposure phase 270A. In some embodiments, the carrier gas is used to help deliver a nitrogen-containing reactant gas to the chamber and may be diverted or flowed into the chamber. During this phase, silicon-containing precursor gas flow is turned off, and source gas flow is turned off while nitrogen-containing reactant gas flow is turned on. This may correspond to operation 120 of FIG. 1A. During purge phase 292A, the carrier gas flow may continue to be on and the carrier gas may act as a purge gas to remove excess molecules and/or byproducts from the chamber. In particular embodiments, the flow rate of the carrier gas can be increased to further enhance removal of excess molecules, as seen in purge phase 292A. Silicon-containing precursor gas flow, nitrogen-containing reactant gas flow, and source gas flow are turned off.

During plasma exposure phase 280A, a carrier gas may continue to flow. In particular embodiments, the flow rate of the carrier gas can be decreased, as compared to that in the purge phase 292A, to reduce consumption of the source gas within the plasma exposure phase 280A. In some embodiments, the carrier gas is used to help deliver a radical species obtained from a source gas. During this phase, silicon-containing precursor gas flow and nitrogen-containing reactant gas flow are turned off, and source gas flow is turned on. This may correspond to operation 130 of FIG. 1A. During purge phase 294A, the carrier gas flow may continue to be on and the carrier gas may act as a purge gas to remove excess radical species, molecules, and/or byproducts from the chamber. In particular embodiments, the flow rate of the carrier gas can be increased to further enhance removal of excess molecules, as seen in purge phase 294A. Silicon-containing precursor gas flow and nitrogen-containing reactant gas flow are turned off.

In this example of FIG. 2B, it is determined that the silicon nitride film deposited is of insufficient thickness and another deposition cycle 251B is performed. Deposition cycle 251B includes silicon-containing precursor exposure phase 260B, purge phase 290B, nitrogen-containing reactant exposure phase 270B, purge phase 292B, plasma exposure phase 280B, and purge phase 294B. During silicon-containing precursor exposure phase 260B, a carrier gas may be flowed and a silicon-containing precursor gas flow is turned on, while nitrogen-containing reactant gas flow and source gas flow are turned off. This may correspond to a repeated operation of operation 110 of FIG. 1A after determining in operation 150 that the film is not deposited to an adequate thickness. During purge phase 290B, the carrier gas flow remains on while silicon-containing precursor gas flow is turned off and both nitrogen-containing reactant gas flow and source gas flow remain off. This may correspond to a repeated operation of operation 140 of FIG. 1A. During nitrogen exposure phase 270B, the carrier gas flow may remain on while the nitrogen-containing reactant gas flow is turned on and silicon-containing precursor gas flow and source gas flow are turned off. This may correspond to a repeated operation of operation 120 of FIG. 1A. During purge phase 292B, the carrier gas flow may remain on while the silicon-containing precursor gas flow, nitrogen-containing reactant gas flow, and source gas flows are turned off.

During plasma exposure phase 280B, a carrier gas flow and source gas flow may remain on while silicon-containing precursor gas flow and nitrogen-containing reactant gas flow are turned off. This may correspond to operation 130 of FIG. 1A. During purge phase 294B, the carrier gas flow and source gas flow may remain on while the silicon-containing precursor gas flow and nitrogen-containing reactant gas flow are turned off. Although two deposition cycles are depicted in FIG. 2A, it will be understood that additional deposition cycles may also be performed.

In one instance, the methods can provide a conformal SiN film, which in turn is deposited on a high aspect ratio (HAR) structure. In one embodiment, the aspect ratio (of depth to width) is about 180:1 or greater. One non-limiting method can include a hybrid ALD process, which includes deposition of an organosilane precursor, thermal conversion using NH₃ gas, and then plasma treatment using N₂/NH₃ plasma, which produced predominantly NH* radicals. In particular embodiments, the organosilane precursor includes an aminosilane precursor. After the hybrid ALD process, the obtained film can be a conformal film (e.g., having 100% step coverage).

The process conditions described herein can provide a film structure that is highly conformal. In certain embodiments, for an aspect ratio of about 6:1, the silicon carbide film can be deposited with a conformality of between about 25% and about 100%, and typically between about 50% to 80% or between about 50% to 100%.

In particular embodiments, the methods herein provide enhanced growth rate of a film that is deposited on a side wall. In one embodiment, the growth rate using the hybrid ALD process is improved by more than five times, ten times, or more, as compared to a process that lacks the thermal conversion operation but includes a plasma treatment operation.

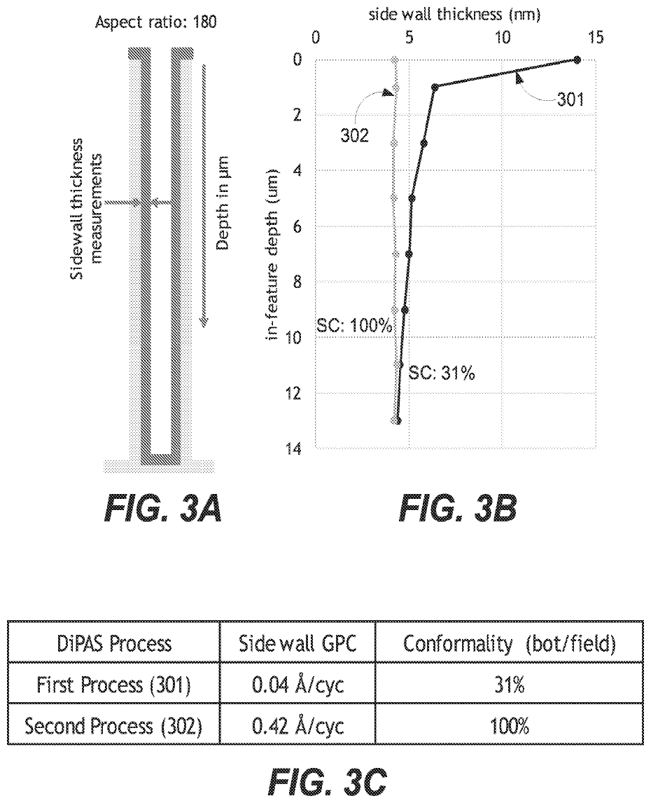

As seen in FIG. 3A, a film can be deposited in a feature having a depth and a width, in which the aspect ratio of the depth to width is about 180:1. The deposited film can be characterized by its deposited thickness on the sidewall, and the deposited thickness at the top of the feature and at the bottom of the feature can be compared to provide a measurement of conformality.

FIG. 3B shows a film deposited by using DIPAS (di-iso-propylaminosilane or SiH₃[NiPr₂]) as the organic silicon-containing precursor. Hybrid ALD conditions are provided in Table 1, below. The hybrid ALD process was performed at 650° C.

TABLE 1
Non-limiting hybrid ALD process

| | Precursor, reactant, | Flow rate | Time | Pressure |
|---|---|---|---|---|
| Operation | or source gas | [sccm] | [sec] | [Torr] |
| Deposition | DIPAS (SiH₃[NiPr₂]) | 200 | 2 | 22 |
| | Nitrogen (N₂) | 300 | | |
| First purge | Nitrogen (N₂) | 10000 | 10 | 22 |
| Thermal | Ammonia (NH₃) | 4500 | 15 | 22 |
| Conversion | | | | |
| Second purge | Nitrogen (N₂) | 10000 | 10 | 22 |
| Plasma | Ammonia (NH₃) | 125 | 10 | 6 |
| Treatment | Nitrogen (N₂) | 12000 | | |
| Third purge | Nitrogen (N₂) | 10000 | 10 | 22 |

A non-limiting hybrid ALD process was compared to a plasma-only process. The plasma-only process was performed at 650° C. and did not include a thermal conversion operation. Rather, the plasma-only process included a deposition operation, a first purge operation, a plasma treatment operation, and a second purge operation.

FIG. 3C shows characterization of non-limiting films formed by using a first process 301 (including plasma-only conversion) and a second process 302 (a hybrid ALD process including thermal conversion and plasma treatment). As can be seen, the growth rate per cycle (GPC) of the side wall was increased by about 10 times upon employing a hybrid ALD process (0.42 Å/cycle for the second process 302), as compared to a plasma-only conversion process 301 (0.04 Å/cycle). Enhanced conformality (or increase step coverage) was also observed upon employing a hybrid ALD process (100% step coverage for the second process 302), as compared to a plasma-only conversion process 301 (30% step coverage).

Carbon content within the film can also be controlled. For instance, carbon percentage (atomic %) can be controlled to be from about 2 atomic % to about 25 atomic %. Without wishing to be limited by mechanism, the carbon (C) atoms within the film can be bonded with the silicon (Si) atoms within the film by way of a Si—C bond. Such carbon impurities can act like defect centers in the SiN film, thereby providing charged trap states for electron and holes. Electron trap states are expected to be distributed from about 0.6 to 1.3 eV (see, e.g., Al Ahmed SR & Kobayashi K, “Extraction of Energy Distribution of Electrons Trapped in Silicon Carbonitride (SiCN) Charge Trapping Films,” IEICE Transactions, 2017; E100-C(7): 662-668; and Kobayashi K & Mino H, “Hole trapping capability of silicon carbonitride charge trap layers,” Eur. Phys. J. Appl. Phys., 2020; 91: 10101, 7 pp., each of which is incorporated herein by reference in its entirety). In use, these high energy trap states can require a lower carrier density, as compared non-doped SiN layers, which in turn could result in low power consumption and higher speed (programming/erasing). Hole trap density can also be expected to be higher for a carbon-doped SiN film, as compared to a non-doped SiN film.

The carbon content within the film can be varied by employing thermal conversion and/or plasma treatment. Carbon content can be from about 2 atomic % to about 25 atomic %, which can be determined in any useful manner (e.g., x-ray photoelectron spectroscopy (XPS)). In this way, the carbon content within the film can be tuned. Furthermore, by controlling the amount of carbon percentage in the film, one can expect that film properties (e.g., charged trap states, electrical film properties, leakage current, breakdown voltage, density, wet etch rate, and the like) are expected to change significantly, thus giving a wide range of tuneability for the memory applications.

The film can be employed in any useful manner. In one instance, the film has beneficial Si—C defects, which can act as high energy electron traps. Such traps can be useful, for example, within a trapping layer in memory cells. In other embodiments, the film can be used in a device (e.g., a solar cell). The presence of carbon can provide a film having a decreased wet etch rate. In one embodiment, the film can be employed as an etch stop layer, in which carbon-doped silicon nitride can have a decreased wet etch rate, as compared to silicon nitride alone. In certain instances, the carbon-doped silicon nitride (e.g., having 25 at. % carbon) can be configured to be selectively etched. In one embodiments, selective etching can include an etch rate in diluted HF (100:1) of less than about 0.05/min.

### Precursors, Including Si-Containing Precursors

The film can be deposited using any useful silicon-containing precursor (Si-containing precursor). In some embodiments, the precursor includes a structure of formula (I):

Si(R′)₄ (I),

wherein at least one R′ includes a carbon atom. In other embodiments, at least one R′ includes a heteroatom (e.g., nitrogen, oxygen, and/or silicon). In yet other embodiments, at least one R′ includes a carbon atom and a heteroatom (e.g., nitrogen, oxygen, and/or silicon). In particular embodiments, R′ does not include a halogen atom.

In other embodiments, the precursor includes a structure of formula (II):

(R′)₃Si-[L-Si(R′)₂]—R′ (II),

wherein at least one R′ includes a carbon atom and L is a linker. In some embodiments, at least one R′ includes a heteroatom (e.g., nitrogen, oxygen, and/or silicon). In yet other embodiments, at least one R′ includes a carbon atom and a heteroatom (e.g., nitrogen, oxygen, and/or silicon). In particular embodiments, R′ does not include a halogen atom.

For formula (II), non-limiting linkers for L include a covalent bond, oxy (—O—), carbonyl (—C(O)—), optionally substituted carbonimidoyl (e.g., —C(NR)—), optionally substituted imino (e.g., —NR—), an optionally substituted alkylene, optionally substituted heteroalkylene, optionally substituted arylene, and the like.

For any formula herein (e.g., for formula (I) or (II)), R′ can be H, aliphatic, heteroaliphatic, aromatic, heteroaromatic, amino, hydrazino, azido, hydroxyl, silyl (e.g., aminosilyl, alkoxysilyl, and the like), silyloxy (e.g., aminosilyloxy, alkoxysilyloxy, and the like), cyanato (—OCN), isocyanato (—NCO), cyano (—CN), or isocyano (—NC), in which any of these may be optionally substituted.

In particular embodiments, at least one, two, three, four, or more R′ in any formula herein (e.g., for formula (I) or (II)) includes an optionally substituted aliphatic. Non-limiting aliphatic groups include alkyl, alkenyl, or alkynyl, including linear, branched, cyclic, saturated, or unsaturated forms thereof. Such groups can be unsubstituted or substituted, such as with one or more substituents described herein for alkyl. Further examples of aliphatic groups include methyl (Me), ethyl (Et), propyl (Pr), iso-propyl (iPr), cyclopropyl (cPr), butyl (Bu), sec-butyl (sBu), iso-butyl (iBu), tert-butyl (tBu), pentyl (Pe), tert-pentyl (tPe), allyl (All), vinyl (Vi), ethynyl, and the like.

In some embodiments, at least one, two, three, four, or more R′ in any formula herein (e.g., for formula (I) or (II)) includes an optionally substituted heteroaliphatic. A heteroaliphatic group can include any including one or more carbon atoms and one or more heteroatoms (e.g., oxygen, nitrogen, and the like).

Non-limiting heteroaliphatic groups includes aliphatic-carbonyl (e.g., alkanoyl or —C(O)R^{Ak}), aliphatic-carbonyloxy (e.g., alkanoyloxy or —OC(O)R^{Ak}), aliphatic-oxy (e.g., alkoxy or —OR^{Ak}), aliphatic-oxycarbonyl (e.g., alkoxycarbonyl or —C(O)OR^{Ak}), amino (e.g., —NR^{N1}R^{N2}), aromatic-carbonyl (e.g., aryloyl or —C(O)R^{Ar}), aromatic-carbonyloxy (e.g., aryloyloxy or —OC(O)R^{Ar}), aromatic-oxy (e.g., aryloxy or —OR^{Ar}), aromatic-oxycarbonyl (e.g., aryloxycarbonyl or —C(O)OR^{Ar}), imidoyl (e.g., —C(NR^{N1})H, —C(NR^{N1})R^{Ak}, or —C(NR^{N1})R^{Ar} carbamoyl (e.g., —C(O)NR^{N1}R^{N2}), carbamoyloxy (e.g., —OC(O)NR^{N1}R^{N2}), carboxyl (—CO₂H), formyl (—C(O)H), heteroaromatic, heterocyclyl (e.g., optionally substituted furanyl, tetrahydrofuranyl, pyrrolidinyl, pyrrolyl, imidazolyl, pyrazolyl, triazolyl, piperidinyl, pyridinyl, pyrimidinyl, pyridazinyl, pyrazinyl, oxazolyl, morpholinyl, and the like), hydrazino (e.g., —NR^{N1}—NR^{N2}R^{N3}) silyl (e.g., —SiR^{S1}R^{S2}R^{S3}), and silyloxy (e.g., —O—SiR^{S1}R^{S2}R^{S3}). Each of these groups can be optionally substituted with any substituent described herein (e.g., as described herein for alkyl). Heteroaliphatic groups can include linear, branched, cyclic (e.g., heterocyclyl), saturated, or unsaturated forms thereof.

Heteroaliphatic groups can include R^{Ak} and/or R^{Ar} moieties. In some embodiments, R^{Ak} is optionally substituted aliphatic, optionally substituted heteroaliphatic, optionally substituted alkyl, optionally substituted alkenyl, optionally substituted alkynyl, optionally substituted cycloalkyl, optionally substituted heteroalkyl, optionally substituted heteroalkenyl, optionally substituted heteroalkynyl, or optionally substituted heterocyclyl. In other embodiments, R^{Ar} is optionally substituted aromatic, optionally substituted heteroaromatic, optionally substituted aryl, or optionally substituted heteroaryl.

Nitrogen-containing groups (e.g., amino, imidoyl, etc.) can include R^{N1}, R^{N2}, and/or R^{N3} moieties attached to a nitrogen atom. In some embodiments, each of R^{N1}, R^{N2}, and R^{N3} is, independently, H, optionally substituted aliphatic, optionally substituted heteroaliphatic, optionally substituted aromatic, optionally substituted heteroaromatic, optionally substituted silyl, or optionally substituted silyloxy. In particular embodiments, R^{N1} and R^{N2} or R^{N2} and R^{N3} can be taken together, with the nitrogen atom to which each is attached, to form an optionally substituted heterocyclyl. Such nitrogen-containing groups can be included within other moieties, such as within silyl or silyloxy groups.

Silicon-containing groups (e.g., silyl, etc.) can include R^{S1}, R^{S2}, and/or R^{S3} attached to a silicon atom. In some embodiments, each of R^{S1}, R^{S2}, and R^{S3} is, independently, H, optionally substituted aliphatic, optionally substituted heteroaliphatic, optionally substituted aromatic, optionally substituted heteroaromatic, or optionally substituted amino. Such silicon-containing groups can be included within other moieties, such as within amino groups.

In some embodiments, the silyl group is an alkylsilyl group having one or more aliphatic groups attached to the silicon atom. In one instance, the alkylsilyl group is —Si(R)ₐ(R^{Ak})_{b}, in which R is, independently, H, aromatic, heteroaromatic, amino, hydrazino, azido, hydroxyl, silyl (e.g., aminosilyl, alkoxysilyl, and the like), silyloxy (e.g., aminosilyloxy, alkoxysilyloxy, and the like), cyanato, isocyanato, cyano, or isocyano, in which any of these may be optionally substituted; R^{Ak} is optionally substituted aliphatic, optionally substituted heteroaliphatic, optionally substituted alkyl, optionally substituted alkenyl, optionally substituted alkynyl, optionally substituted cycloalkyl, optionally substituted heteroalkyl, optionally substituted heteroalkenyl, optionally substituted heteroalkynyl, or optionally substituted heterocyclyl; a≥0; b≥1; and a+b=3. Yet other non-limiting alkylsilyl groups include —SiH₂R^{Ak}, —SiH[R^{Ak}]₂, or —Si[R^{Ak}]₃, in which R^{Ak} is any provided herein.

In some embodiments, the silyl group is an alkoxysilyl group having one or more aliphatic groups attached to the silicon atom by way of an oxy (—O—) group. In one instance, the alkoxylsilyl group is —Si(R)ₐ(OR^{Ak})_{b}, in which R is, independently, H, aromatic, heteroaromatic, amino, hydrazino, azido, hydroxyl, silyl (e.g., aminosilyl, alkoxysilyl, and the like), silyloxy (e.g., aminosilyloxy, alkoxysilyloxy, and the like), cyanato, isocyanato, cyano, or isocyano, in which any of these may be optionally substituted; R^{Ak} is optionally substituted aliphatic, optionally substituted heteroaliphatic, optionally substituted alkyl, optionally substituted alkenyl, optionally substituted alkynyl, optionally substituted cycloalkyl, optionally substituted heteroalkyl, optionally substituted heteroalkenyl, optionally substituted heteroalkynyl, or optionally substituted heterocyclyl; a≥0; b≥1; and a+b=3. Yet other non-limiting alkoxysilyl groups include —SiH₂[OR^{Ak}], —SiH[OR^{Ak}]₂, or —Si[OR^{Ak}]₃, in which R^{Ak} is any described herein.

In other embodiments, the silyl group is an arylsilyl group having one or more aromatic groups attached to the silicon atom. In one instance, the arylsilyl group is —Si(R)ₐ(RAb, in which R is, independently, H, aliphatic, heteroaliphatic, amino, hydrazino, azido, hydroxyl, silyl (e.g., aminosilyl, alkoxysilyl, and the like), silyloxy (e.g., aminosilyloxy, alkoxysilyloxy, and the like), cyanato, isocyanato, cyano, or isocyano, in which any of these may be optionally substituted; R^{Ar} is optionally substituted aromatic, optionally substituted heteroaromatic, optionally substituted aryl, or optionally substituted heteroaryl; a≥0; b≥1; and a+b=3. Yet other non-limiting arylsilyl groups include —SiH₂R^{Ar}, —SiH[R^{Ar}]₂, or —Si[R^{Ar}]₃, in which R^{Ar} is any described herein.

In yet other embodiments, the silyl group is an aryloxysilyl group having one or more aromatic groups attached to the silicon atom by way of an oxy (—O—) group. In one instance, the arylsilyl group is —Si(R)ₐ(OR^{Ar})_{b}, in which R is, independently, H, aliphatic, heteroaliphatic, amino, hydrazino, azido, hydroxyl, silyl (e.g., aminosilyl, alkoxysilyl, and the like), silyloxy (e.g., aminosilyloxy, alkoxysilyloxy, and the like), cyanato, isocyanato, cyano, or isocyano, in which any of these may be optionally substituted; R^{Ar} is optionally substituted aromatic, optionally substituted heteroaromatic, optionally substituted aryl, or optionally substituted heteroaryl; a≥0; b≥1; and a+b=3. Yet other non-limiting aryloxysilyl groups include —SiH₂[OR^{Ar}], —SiH[OR^{Ar}]₂, or —Si[OR^{Ar}]₃, in which R^{Ar} is any described herein.

A silyl group can also include an aminosilyl having one or more optionally substituted amino groups attached to the silicon atom. In one instance, the aminosilyl group is —Si(R)ₐ(NR^{N1}R^{N2})_{b}, in which R is, independently, H, aliphatic, heteroaliphatic, aromatic, heteroaromatic, hydrazino, azido, hydroxyl, silyl (e.g., aminosilyl, alkoxysilyl, and the like), silyloxy (e.g., aminosilyloxy, alkoxysilyloxy, and the like), cyanato, isocyanato, cyano, or isocyano, in which any of these may be optionally substituted; each of RN and R^{N2} is, independently, H, optionally substituted aliphatic, optionally substituted heteroaliphatic, optionally substituted aromatic, optionally substituted heteroaromatic, optionally substituted silyl, or optionally substituted silyloxy, in which R^{N1} and R^{N2} can be taken together, with the nitrogen atom to which each is attached, to form an optionally substituted heterocyclyl; a≥0; b≥1; and a+b=3. Yet other non-limiting embodiments of aminosilyl groups include —SiH₂[NR^{N1}R^{N2}], —SiH[R^{Ak}][NR^{N1}R^{N2}], —Si[R^{Ak}]₂[NR^{N1}R^{N2}], —SiH[NR^{N1}R^{N2}]₂, —Si[R^{Ak}][NR^{N1}R^{N2}]₂, or —Si[NR^{N1}R^{N2}]₃), such as —SiH₂[NH₂], —SiHR^{Ak}[NH₂], —Si[R^{Ak}]₂[NH₂], —SiH₂[NH(R^{Ak})], —SiHR^{Ak}[NH(R^{Ak})], —Si[R^{Ak}]₂[NH(R^{Ak})], —SiH₂[N(R^{Ak})₂], —SiHR^{Ak}[N(R^{Ak})₂], —Si[R^{Ak}]₂[N(R^{Ak})₂], —SiH[NH₂]₂, —SiR^{Ak}[NH₂]₂, —SiH[NH(R^{Ak})]₂, —SiR^{Ak}[NH(R^{Ak})]₂, —SiH[NH(R^{Ak})][NH₂], —SiR^{Ak}[NH(R^{Ak})][NH₂], —SiH[N(R^{Ak})₂]₂, —SiR^{Ak}[N(R^{Ak})₂]₂, —SiH[N(R^{Ak})₂][NH₂], —SiR^{Ak}[N(R^{Ak})₂][NH₂], —Si[NH₂]₃, —Si[N(R^{Ak})₂][NH₂]₂, —Si[N(R^{Ak})₂]₂[NH₂], —Si[N(R^{Ak})₂]₃, —Si[NH(R^{Ak})][NH₂]₂, —Si[NH(R^{Ak})₂]₂[NH₂], —Si[NH(R^{Ak})]₃, —Si[NH(R^{Ak})][N(R^{Ak})₂]₂, —Si[NH(R^{Ak})]2[N(R^{Ak})₂], and the like, in which R^{A} is optionally substituted aliphatic, heteroaliphatic, alkyl, alkenyl, alkynyl, or alkoxy; and each of RN and R^{N2} is any described herein.

In some embodiments, the silyl group is —Si(R′)ₐ(OR)_{b}(NR₂)_{c}, in which each R′ is, independently, H, aliphatic, heteroaliphatic, aromatic, heteroaromatic, amino, hydrazino, azido, hydroxyl, silyl, silyloxy, cyanato, isocyanato, cyano, or isocyano, in which any of these may be optionally substituted; each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl.

In other embodiments, any of the silyl groups herein can be attached to the parent compound through an oxy bond. In some embodiments, the silyloxy group is —O—Si(R′)ₐ(OR)_{b}(NR₂)_{c}, in which each R′ is, independently, H, aliphatic, heteroaliphatic, aromatic, heteroaromatic, amino, hydrazino, azido, hydroxyl, silyl, silyloxy, cyanato, isocyanato, cyano, or isocyano, in which any of these may be optionally substituted; each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl. Yet other non-limiting silyloxy groups include —O—Si(R)ₐ(R^{Ak})_{b}, —O—Si(R)ₐ(OR^{Ak})_{b}, —O—Si(R)ₐ(R^{Ar})_{b}, —O—Si(R)ₐ(OR^{Ar})_{b}, —O—Si(R)ₐ(NR^{NL}R^{N2})_{b}, in which R is, independently, H, aromatic, heteroaromatic, amino, hydrazino, azido, hydroxyl, silyl (e.g., aminosilyl, alkoxysilyl, and the like), silyloxy (e.g., aminosilyloxy, alkoxysilyloxy, and the like), cyanato, isocyanato, cyano, or isocyano, in which any of these may be optionally substituted; R^{Ak} is optionally substituted aliphatic, optionally substituted heteroaliphatic, optionally substituted alkyl, optionally substituted alkenyl, optionally substituted alkynyl, optionally substituted cycloalkyl, optionally substituted heteroalkyl, optionally substituted heteroalkenyl, optionally substituted heteroalkynyl, or optionally substituted heterocyclyl; R^{Ar} is optionally substituted aromatic, optionally substituted heteroaromatic, optionally substituted aryl, or optionally substituted heteroaryl; each of RN and R^{N2} is, independently, H, optionally substituted aliphatic, optionally substituted heteroaliphatic, optionally substituted aromatic, optionally substituted heteroaromatic, optionally substituted silyl, or optionally substituted silyloxy, in which R^{N1} and R^{N2} can be taken together, with the nitrogen atom to which each is attached, to form an optionally substituted heterocyclyl; a≥0; b≥1; and a+b=3. Yet other non-limiting silyloxy groups include alkylsilyloxy (e.g., —O—SiH₂R^{Ak}, —O—SiH[R^{Ak}]₂, or —O—Si[R^{Ak}]₃); alkoxysilyloxy (e.g., —O—SiH₂[OR^{Ak}], —O—SiH[OR^{Ak}]₂, or —O—Si[OR^{Ak}]₃); arylsilyloxy (e.g., —O—SiH₂R^{Ar}, —O—SiH[R^{Ar}]₂, or —O—Si[R^{Ar}]₃); or aryloxysilyloxy (e.g., —O—SiH₂[OR^{Ar}], —O—SiH[OR^{Ar}]₂, or —O—Si[OR^{Ar}]₃). In some embodiments, the silyl group is aminosilyloxy (e.g., —O—SiH₂[NR^{N1}R^{N2}], —O—SiH[R^{Ak}][NR^{N1}R^{N2}]—O—Si[R^{Ak}]₂[NR^{N1}R^{N2}], —O—SiH[NR^{N1}R^{N2}]₂, —O—Si[R^{Ak}][NR^{N1}R^{N2}]₂, or —O—Si[NR^{N1}R^{N2}]₃).

Silyl and silyloxy group can have a mixed combination of aliphatic and aromatic groups. In one instance, the silyl group is —Si(R)ₐ(R^{Ak})_{b}(R^{Ar})_{c}, or —Si(R)ₐ(OR^{Ak})_{b}(OR^{Ar})_{c}, in which R is, independently, H, aromatic, heteroaromatic, amino, hydrazino, azido, hydroxyl, silyl (e.g., aminosilyl, alkoxysilyl, and the like), silyloxy (e.g., aminosilyloxy, alkoxysilyloxy, and the like), cyanato, isocyanato, cyano, or isocyano, in which any of these may be optionally substituted; R^{Ak} is optionally substituted aliphatic (e.g., optionally substituted alkyl) or optionally substituted heteroaliphatic (e.g., optionally substituted alkoxy or optionally substituted amino); R^{Ar} is optionally substituted aromatic or optionally substituted heteroaromatic; each of a, b, and c≥0; and a+b+c=3.

In another instance, the silyl group is —Si(R)ₐ(NR^{Ak}₂)_{b}, —Si(R)ₐ(NR^{Ak}R^{Ar})_{b}, or —Si(R)ₐ(NR^{Ar}₂)_{b}, in which R is, independently, H, aromatic, heteroaromatic, amino, hydrazino, azido, hydroxyl, silyl (e.g., aminosilyl, alkoxysilyl, and the like), silyloxy (e.g., aminosilyloxy, alkoxysilyloxy, and the like), cyanato, isocyanato, cyano, or isocyano, in which any of these may be optionally substituted; each of R^{N1} and R^{N2} is, independently, H, optionally substituted aliphatic, optionally substituted heteroaliphatic, optionally substituted aromatic, optionally substituted heteroaromatic, optionally substituted silyl, or optionally substituted silyloxy, in which R^{N1} and R^{N2} can be taken together, with the nitrogen atom to which each is attached, to form an optionally substituted heterocyclyl; each of a and b≥0; and a+b=3.

In yet another instance, the silyloxy group is —O—Si(R)ₐ(R^{Ak})_{b}(R^{Ak})_{c}, —O—Si(R)ₐ(OR^{Ak})_{b}(OR^{Ar})_{c}, —O—Si(R)ₐ(NR^{Ak}₂)_{b}, —O—Si(R)ₐ(NR^{Ak}R^{Ak})_{b}, or —O—Si(R)ₐ(NR^{Ar}₂)_{b}, in which R, R^{Ak}, and R^{Ar} are any described herein; and a, b, and c are any described herein.

In some embodiments, at least one, two, three, four, or more R′ in any formula herein (e.g., for formula (I) or (II)) includes an optionally substituted aliphatic-oxy, heteroaliphatic-oxy, aromatic-oxy, or heteroaromatic-oxy. For instance, R′ can be —O—R, in which R is optionally substituted aliphatic (e.g., alkyl, alkenyl, alkynyl, cycloalkyl, cycloalkenyl, or cycloalkynyl), optionally substituted heteroaliphatic (e.g., heteroalkyl, heteroalkenyl, heteroalkynyl, or heterocyclyl), optionally substituted aromatic (e.g., aryl), optionally substituted heteroaromatic (e.g., heteroaryl), optionally substituted aliphatic-carbonyl (e.g., alkanoyl or —C(O)R^{Ak}, in which R^{Ak} is optionally substituted aliphatic or any described herein), optionally substituted silyl (e.g., —SiR^{S1}R^{S2}R^{S3} or —Si(R′)ₐ(OR)_{b}(NR₂)_{c}, including any described herein), or optionally substituted amino (e.g., —NR^{N1}R^{N2}, including any described herein).

In particular embodiments, at least one, two, three, four, or more R′ in any formula herein (e.g., for formula (I) or (II)) includes an optionally substituted aromatic or optionally substituted heteroaromatic. Non-limiting aromatic and heteroaromatic groups include phenyl, benzyl, naphthyl, furanyl, pyrrolyl, imidazolyl, pyrazolyl, triazolyl, pyridinyl, pyrimidinyl, pyridazinyl, pyrazinyl, oxazolyl, and the like.

In particular embodiments, at least one, two, three, four, or more R′ in any formula herein (e.g., for formula (I) or (II)) includes an optionally substituted amino (e.g., —NH₂, —NR^{N1}H, or —NR^{N1}R^{N2}). In particular embodiments, each of R^{N1} and R^{N2} is, independently, H, optionally substituted aliphatic, optionally substituted heteroaliphatic, optionally substituted aromatic, optionally substituted heteroaromatic, optionally substituted amino, hydroxyl, optionally substituted alkyl, optionally substituted alkoxy, optionally substituted aryl, optionally substituted aryloxy, optionally substituted alkyl-aryl, optionally substituted aryl-alkyl, optionally substituted silyl, or optionally substituted silyloxy. In particular embodiments, R^{N1} and R^{N2} can be taken together, with the nitrogen atom to which each is attached, to form an optionally substituted heterocyclyl.

Non-limiting instances of R^{N1} and R^{N2} can include H, aliphatic, alkyl (e.g., —R^{Ak}), alkenyl, alkynyl, aliphatic carbonyl (e.g., alkanoyl or —C(O)R^{Ak}), aliphatic-carbonyloxy (e.g., alkanoyloxy or —OC(O)R^{Ak}), aliphatic-oxy (e.g., alkoxy or —OR^{Ak}), aliphatic-oxycarbonyl (e.g., alkoxycarbonyl or —C(O)OR^{Ak}), amino (e.g., —NR₂, in which each R is, e.g., H, optionally substituted aliphatic, optionally substituted heteroaliphatic, optionally substituted aromatic, or optionally substituted heteroaromatic), aromatic (e.g., aryl or —R^{Ar}), aromatic-carbonyl (e.g., aryloyl or —C(O)R^{Ar}), aromatic-carbonyloxy (e.g., aryloyloxy or —OC(O)R^{Ar}), aromatic-oxy (e.g., aryloxy or —OR^{Ar}), aromatic-oxycarbonyl (e.g., aryloxycarbonyl or —C(O)OR^{Ar}), imidoyl (e.g., —C(NR)H, —C(NR)R^{Ak}, or —C(NR)R^{Ar}, in which each R is, e.g., H, optionally substituted aliphatic, optionally substituted heteroaliphatic, optionally substituted aromatic, or optionally substituted heteroaromatic), carbamoyl (e.g., —C(O)NR₂, in which each R is, e.g., H, optionally substituted aliphatic, optionally substituted heteroaliphatic, optionally substituted aromatic, or optionally substituted heteroaromatic), carbamoyloxy (e.g., —OC(O)NR₂, in which each R is, e.g., H, optionally substituted aliphatic, optionally substituted heteroaliphatic, optionally substituted aromatic, or optionally substituted heteroaromatic), carboxyl (—CO₂H), formyl (—C(O)H), heteroaromatic, heterocyclyl (e.g., optionally substituted furanyl, tetrahydrofuranyl, pyrrolidinyl, pyrrolyl, imidazolyl, pyrazolyl, triazolyl, piperidinyl, pyridinyl, pyrimidinyl, pyridazinyl, pyrazinyl, oxazolyl, morpholinyl, and the like), hydroxyl (—OH), silyl (e.g., —SiR^{S1}R^{S2}R^{S3} or —Si(R′)ₐ(OR)_{b}(NR₂)_{c}), and silyloxy (e.g., —O—SiR^{S1}R^{S2}R^{S3} or —O—Si(R′)ₐ(OR)_{b}(NR₂)_{c}). For any of these groups, where indicated, R^{Ak}, R^{Ar}, R′, R, R^{S1}, R^{S2}, R^{S3}, a, b, and c can be any described herein.

Yet other non-limiting amino groups include —NH₂, —NHMe, —NMe₂, —NHEt, —NMeEt, —NEt, —NHnPr, —NMenPr, —NnPr₂, —NHiPr, —NMeiPr, —NiPr₂, —NHsBu, —NMesBu, —NsBu₂, —NHtBu, —NMetBu, —NtBu₂, —N[SiH₃]₂, —N[Si(Me)₃]₂, —N[Si(Et)₃]₂, —NH[SiH₃], —NH[Si(Me)₃], —NH[Si(Et)₃], —NMe[SiH₃], —NMe[Si(Me)₃], —NMe[Si(Et)₃], —N[SiH₂Me]₂, —N[SiHMe₂]₂, —N[SiH₂Et]₂, —N[SiHEt₂]₂, —N[SiHMeEt]₂, —NH[SiH₂Me], —NH[SiHMe₂], —NH[SiH₂Et], —NH[SiHEt₂]₂, —NH[SiHMeEt], —NMe[SiH₂Me], —NMe[SiHMe₂], —NMe[SiH₂Et], —NMe[SiHEt₂]₂, —NMe[SiHMeEt], and the like.

In particular embodiments, at least one, two, three, four, or more R′ in any formula herein (e.g., for formula (I) or (II)) includes an optionally substituted hydrazino (e.g., —NH—NH₂ or —NR^{N1}—NR^{N2}R^{N3}) In particular embodiments, each of R^{N1}, R^{N2}, and R^{N3} is, independently, H, optionally substituted aliphatic, optionally substituted heteroaliphatic, optionally substituted aromatic, optionally substituted heteroaromatic, optionally substituted amino, hydroxyl, optionally substituted alkyl, optionally substituted alkoxy, optionally substituted aryl, optionally substituted aryloxy, optionally substituted alkyl-aryl, optionally substituted aryl-alkyl, optionally substituted silyl, or optionally substituted silyloxy. In particular embodiments, R^{N1} and R^{N2} or R^{N2} and R^{N3} can be taken together, with the nitrogen atom to which each is attached, to form an optionally substituted heterocyclyl. Yet other non-limiting hydrazino groups include —NH—NH₂, —NMe-NH₂, —NH—NHMe, —NH—NMe₂, —NMe-NMe₂, —NEt-NH₂, —NH—NHEt, —NH-NEt₂, —NMe-NEt₂, and the like.

In some embodiments, at least one, two, three, four, or more R′ in any formula herein (e.g., for formula (I) or (II)) includes an optionally substituted silyl. In one embodiment, silyl is —SiR^{S1}R^{S2}R^{S3}, in which each of R^{S1}, R^{S2}, and R^{S3} is, independently, H, optionally substituted aliphatic, optionally substituted heteroaliphatic, optionally substituted aromatic, optionally substituted heteroaromatic, optionally substituted amino, optionally substituted hydrazino, azido, hydroxyl, optionally substituted silyl, optionally substituted silyloxy, optionally substituted alkyl, optionally substituted alkenyl, optionally substituted alkynyl, optionally substituted alkoxy, optionally substituted heteroalkyl, optionally substituted heteroalkenyl, optionally substituted heteroalkynyl, optionally substituted heterocyclyl, optionally substituted aryl, optionally substituted aryloxy, cyanato, isocyanato, cyano, isocyano, and the like. Non-limiting silyl groups include any described herein, such as —Si(R)ₐ(R^{Ak})_{b}, —Si(R)ₐ(OR^{Ak})_{b}, —Si(R)ₐ(R^{Ak})_{b}, —Si(R)ₐ(OR^{Ak})_{b}, —Si(R)ₐ(NR^{N1}R^{N2})_{b}, —Si(R′)ₐ(OR)_{b}(NR₂)_{c}, and the like. Yet other non-limiting silyl groups include —SiH₃, —SiH₂Me, —SiHMe₂, —SiMe₃, —Si(OH)₃, —SiH₂(OMe), —SiH(OMe)₂, —Si(OMe)₃, —SiH₂(NH₂), —SiHMe(NH₂), —SiMe₂(NH₂), —SiH(NH₂)₂, —SiMe(NH₂)₂, —Si(NH₂)₃, —SiH₂(NMe₂), —SiH₂(NMe₂), —SiHMe(NMe₂), —Si(Me)₂(NMe₂)₂, —SiMe(NMe₂)₂, —Si(NMe₂)₃, —SiH₂(NHMe), —SiHMe(NHMe), —SiH(NHMe)₂, —SiMe(NHMe)₂, —Si(NHMe)₃, and the like.

In other embodiments, at least one, two, three, four, or more R′ in any formula herein (e.g., for formula (I) or (II)) includes an optionally substituted silyloxy. Non-limiting silyloxy groups include any described herein, such as —O—Si(R)ₐ(R^{Ak})_{b}, —O—Si(R)ₐ(OR^{Ak})_{b}, —O—Si(R)ₐ(R^{Ar})_{b}, —O—Si(R)ₐ(OR^{Ar})_{b}, —O—Si(R)ₐ(NR^{N1}R^{N2})_{b}, —O—Si(R′)ₐ(OR)_{b}(NR₂)_{c}, and the like. Yet other non-limiting silyloxy groups include —O—SiH₃, —O—SiH₂Me, —O—SiHMe₂, —O—SiMe₃, —O—Si(OH)₃, —O—SiH₂(OMe), —O—SiH(OMe)₂, —O—Si(OMe)₃, —O—SiH₂(NH₂), —O—SiHMe(NH₂), —O—SiMe₂(NH₂), —O—SiH(NH₂)₂, —O—SiMe(NH₂)₂, —O—Si(NH₂)₃, —O—SiH₂(NMe₂), —O—SiH₂(NMe₂), —O—SiHMe(NMe₂), —O—Si(Me)₂(NMe₂)₂, —O—SiMe(NMe₂)₂, —O—Si(NMe₂)₃, —O—SiH₂(NHMe), —O—SiHMe(NHMe), —O—SiH(NHMe)₂, —O—SiMe(NHMe)₂, —O—Si(NHMe)₃, and the like.

In yet other embodiments, at least one, two, three, four, or more R′ in any formula herein (e.g., for formula (I) or (II)) includes azido (—N₃), hydroxyl (—OH), cyanato (—OCN), isocyanato (—NCO), cyano (—CN), and/or isocyano (—NC).

The organic silicon-containing precursor may be selected from the group consisting of silane, disilane, trisilane, tetrasilane, amine-substituted versions of any of the foregoing silanes, and trisilylamine.

Examples of organic silicon-containing precursors include, but are not limited to, silanes, polysilanes, halosilanes, and aminosilanes. A silane contains hydrogen and/or carbon groups, but does not contain a halogen. A polysilane may have the formula (H₃Si—(SiH₂)ₙ—SiH₃), where n≥1. Examples of silanes include silane (SiH₄), disilane (Si₂H₆), trisilane, tetrasilane and organo silanes such as methylsilane, ethylsilane, isopropylsilane, t-butylsilane, dimethylsilane, diethylsilane, di-t-butylsilane, allylsilane, sec-butylsilane, thexylsilane, isoamylsilane, t-butyldisilane, di-t-butyldisilane, tetra-ethyl-ortho-silicate (also known as tetra-ethoxy-silane or TEOS) and the like.

An aminosilane includes at least one nitrogen atom bonded to a silicon atom, but may also contain hydrogens, oxygens, halogens and carbons. Examples of aminosilanes are mono-, di-, tri- and tetra-aminosilane (H₃Si(NH₂)₄, H₂Si(NH₂)₂, HSi(NH₂)₃ and Si(NH₂)₄, respectively), as well as substituted mono-, di-, tri- and tetra-aminosilanes, for example, t-butylaminosilane, methylaminosilane, tert-butylsilanamine, bis(tertiarybutylamino)silane (SiH₂(NHC(CH₃)₃)₂ (BTBAS), tert-butyl silylcarbamate, SiH(CH₃)—(N(CH₃)₂)₂, SiHCl—(N(CH₃)₂)₂, (Si(CH₃)₂NH)₃, di(sec-butylamino)silane (DSBAS), di(isopropylamido)silane (DIPAS), bis(diethylamino)silane (BDEAS), and the like. A further example of an aminosilane is trisilylamine (N(SiH₃)₃).

Examples of silicon-containing precursors for depositing silicon carbide include siloxanes, alkyl silane or hydrocarbon-substituted silane, or a nitrogen-containing carbon-containing reactant. Examples of siloxanes include 2,4,6,8-tetramethyl cyclotetrasiloxane (TMCTS), heptamethylcyclotetrasiloxane (HMCTS), silsesquioxane, disiloxanes, such as pentamethyldisiloxane (PMDSO) or tetramethyldisiloxane (TMDSO), and trisiloxanes such as hexamethyltrisiloxane or heptamethyltrisiloxane. Alkyl silanes include a central silicon atom with one or more alkyl groups bonded to it as well as one or more hydrogen atoms bonded to it. In some embodiments, any one or more of the alkyl groups contain 1-5 carbon atoms. The hydrocarbon groups may be saturated or unsaturated (e.g., alkene (e.g., vinyl), alkyne, and aromatic groups). Examples include but are not limited to trimethylsilane (3MS), triethylsilane, pentamethyl disilamethane ((CH₃)₂Si—CH₂—Si(CH₃)₃), and dimethylsilane (2MS). Additionally, disilanes, trisilanes, or other higher silanes may be used in place of monosilanes. In some embodiments, one of the silicon atoms can have a carbon-containing or hydrocarbon group attached to it, and one of the silicon atoms can have a hydrogen atom attached to it. Example carbon-containing reactants including a nitrogen include methyl-substituted disilazanes and trisilazanes, such as tetramethyldisilazane and hexamethyl trisilazane.

Yet other examples of organic silicon-containing precursors can include siloxanes such as cyclotetrasiloxanes such as heptamethylcyclotetrasiloxane (HMCTS) and tetramethyl cyclotetrasiloxane. Other cyclic siloxanes can also include but are not limited to cyclotrisiloxanes and cyclopentasiloxanes. Other examples of suitable precursors include linear siloxanes such as, but not limited to, disiloxanes, such as pentamethyldisiloxane (PMDSO), tetramethyldisiloxane (TMDSO), hexamethyl trisiloxane, and heptamethyl trisiloxane. For undoped silicon carbide, examples of suitable precursors include monosilanes substituted with one or more alkyl, alkene, and/or alkyne groups containing, e.g., 1-5 carbon atoms. Examples include but are not limited to trimethylsilane (3MS), dimethylsilane (2MS), triethylsilane (TES), and pentamethyldisilamethane. Additionally, disilanes, trisilanes, or other higher silanes may be used in place of monosilanes. An example of one such disilane from the alkyl silane class is hexamethyldisilane (HMDS). Another example of a disilane from the alkyl silane class can include pentamethyldisilane (PMDS). Other types of alkyl silanes can include alkylcarbosilanes, which can have a branched polymeric structure with a carbon bonded to a silicon atom as well as alkyl groups bonded to a silicon atom. Examples include dimethyl trimethylsilyl methane (DTMSM) and bis-dimethylsilyl ethane (BDMSE). Examples of other suitable precursors include, e.g., alkyldisilazanes and possibly compounds including amino (—NH₂) and alkyl groups separately bonded to one or more silicon atoms. Alkyldisilazanes include silizanes and alkyl groups bonded to two silicon atoms. An example includes 1,1,3,3-tetramethyldisilazane (TMDSN).

In the Si-containing precursors described herein, different kinds of R′ can be attached to the silicon atom. Further Si-containing precursors are described herein.

### Amino Silanes

A silicon-containing precursor can include one or more optionally substituted amino groups, thereby providing a non-limiting amino silane. In one embodiment, the precursor has a formula of (R′)₄₋ₓSi(NR″₂)ₓ, wherein:
x is 1, 2, 3, or 4;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl.

In another embodiment, the precursor has a formula of (R″₂N)ₓ(R′)₃₋ₓSi-L-Si(R′)₃₋ₓ(NR″₂)ₓ, wherein:
each x is, independently, 0, 1, 2, or 3;
L is a linker, such as a covalent bond, optionally substituted aliphatic, optionally substituted heteroaliphatic, optionally substituted aromatic, optionally substituted heteroaromatic, oxy (—O—), imino, or silyl;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl.

In particular embodiments, L is optionally substituted imino, such as —NR—, in which R is H, optionally substituted aliphatic, optionally substituted alkyl, optionally substituted alkenyl, optionally substituted alkynyl, or optionally substituted aromatic. In other embodiments, L is optionally substituted silyl, such as —SiR₂—, in which each R is, independently, H, optionally substituted aliphatic, optionally substituted alkyl, optionally substituted alkenyl, optionally substituted alkynyl, or optionally substituted aromatic.

In one instance, at least one x is not 0. In another embodiment, x can be 0 (e.g., if L includes a carbon atom or a heteroatom). In yet another embodiment, x is 0; and/or L includes optionally substituted aliphatic, optionally substituted alkylene, optionally substituted alkenylene, optionally substituted alkynylene, optionally substituted heteroaliphatic, optionally substituted heteroalkylene, optionally substituted heteroalkenylene, optionally substituted heteroalkynylene, optionally substituted aromatic, optionally substituted arylene, optionally substituted heteroaromatic, optionally substituted heteroarylene, oxy (—O—), imino, or silyl.

In particular embodiments, at least one R′ or R″ is not H. The precursor can have any useful combination of R′ groups and amino groups (NR″₂) attached to one or more silicon atoms.

In some embodiments, R′ is H, optionally substituted amino (e.g., —NR₂), aliphatic-oxy (e.g., alkoxy or —OR), aliphatic-carbonyl (e.g., alkanoyl or —C(O)R), aliphatic-carbonyloxy (e.g., alkanoyloxy or —OC(O)R), aliphatic-oxycarbonyl (e.g., alkoxycarbonyl or —C(O)OR), silyl (e.g., —SiR₃), aliphatic-oxy-silyl (e.g., alkoxysilyl or —Si(R)ₐ(OR)_{b}), aminosilyl (e.g., —Si(R)ₐ(NR₂)_{b}), silyloxy (e.g., —O—SiR₃), aliphatic-oxy-silyloxy (e.g., alkoxysilyloxy or —O—Si(R)ₐ(OR)_{b}), aminosilyloxy (e.g., —O—Si(R)ₐ(NR₂)_{b}), aromatic (e.g., aryl), aromatic-oxy (e.g., aryloxy or —OR), hydroxyl (—OH), formyl (—C(O)H), and the like. In particular embodiments, each R is, independently, H, optionally substituted aliphatic, optionally substituted alkyl, optionally substituted alkenyl, optionally substituted alkynyl, optionally substituted heteroaliphatic, optionally substituted aromatic, optionally substituted aryl, and optionally substituted heteroaromatic; a≥0; b≥1; and a+b=3. In some embodiments, two R groups can be taken together, with the nitrogen atom to which each is attached, to form an optionally substituted heterocyclyl. In other embodiments, each R is, independently, H, optionally substituted alkyl, optionally substituted alkenyl, optionally substituted alkynyl, or optionally substituted aryl.

In other embodiments, R″ is H, optionally substituted aliphatic, optionally substituted heteroaliphatic, optionally substituted alkyl, optionally substituted silyl, or optionally substituted silyloxy. In some embodiments, R″ is optionally substituted alkyl (e.g., Me, Et, nPr, iPr, sBu, or tBu). In other embodiments, R″ is —SiR′₃, —SiR₃, —Si(R′)ₐ(OR)_{b}, —Si(R)ₐ(OR)_{b}, —Si(R′)ₐ(NR₂)_{b}, —Si(R)ₐ(NR₂)_{b}, —Si(R′)ₐ(OR)_{b}(NR₂)_{c}, —Si(R)ₐ(OR)_{b}(NR₂)_{c}, —O—SiR′₃, —O—SiR₃, —O—Si(R′)ₐ(OR)_{b}, —O—Si(R)ₐ(OR)_{b}, —O—Si(R′)ₐ(NR₂)_{b}, —O—Si(R)ₐ(NR₂)_{b}, —O—Si(R′)ₐ(OR)_{b}(NR₂)_{c}, or —O—Si(R)ₐ(OR)_{b}(NR₂)_{c} in which each R′ is, independently, H, aliphatic, heteroaliphatic, aromatic, heteroaromatic, amino, hydrazino, azido, hydroxyl, silyl, silyloxy, cyanato, isocyanato, cyano, or isocyano, in which any of these may be optionally substituted; each R is, independently, H, optionally substituted aliphatic, optionally substituted heteroaliphatic, optionally substituted aromatic, or optionally substituted heteroaromatic; each of a, b, and c≥0; and a+b+c=3 or a+b=3 (if c is not present). In particular embodiments, R is H, optionally substituted alkyl, optionally substituted alkenyl, or optionally substituted alkynyl.

The precursor can include at least one R′ group attached to the silicon atom. In one embodiment, the precursor has a formula of (R′)(H)₃₋ₓSi(NR″₂)ₓ, wherein R′ and R″ can be any described herein, and wherein x is 1, 2, or 3. In another embodiment, the precursor has a formula of (R′)(H)₂Si(NR″₂), wherein R′ and R″ can be any described herein. In one embodiment, the precursor has a formula of (R′)(H)Si(NR″₂)₂, wherein R′ and R″ can be any described herein. In another embodiment, the precursor has a formula of (R′)₂(H)Si(NR″₂), wherein R′ and R″ can be any described herein. In yet another embodiment, the precursor has a formula of (R′)₂Si(NR″₂)₂, wherein R′ and R″ can be any described herein. In one embodiment, the precursor has a formula of (R′)₃Si(NR″₂), wherein R′ and R″ can be any described herein.

The precursor can lack an R′ group attached to the silicon atom. In one embodiment, the precursor has a formula of (H)₄₋ₓSi(NR″₂)ₓ, wherein each R″ can independently be any described herein, and wherein x is 1, 2, 3, or 4. In another embodiment, the precursor has a formula of Si(NR″₂)ₓ, wherein each R″ can independently be any described herein. In particular embodiments, each R″ is, independently, aliphatic, heteroaliphatic, aromatic, or heteroaromatic.

The precursor can include one or more hydrogen atoms attached to the silicon atom. In one embodiment, the precursor has a formula of (H)₃Si(NR″₂) or (H)₂Si(NR″₂)₂ or (H)Si(NR″₂)₃, wherein each R″ can independently be any described herein. In particular embodiments, each R″ is, independently, aliphatic, heteroaliphatic, aromatic, heteroaromatic, or amino, in which any of these may be optionally substituted.

The precursor can include a heterocyclyl group having a nitrogen atom. In one embodiment, the formula has a formula of H₃Si-Het, in which Het is an optionally substituted heterocyclyl including at least one nitrogen atom. In particular embodiments, the precursor has a formula of

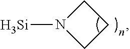

in which the heterocyclyl group can be optionally substituted (e.g., with any substituent described herein as a substitution for alkyl), and wherein n is 1, 2, 3, 4, or 5. In one embodiment, the formula has a formula of R′₃Si-Het, in which Het is an optionally substituted heterocyclyl including at least one nitrogen atom, and each R′ can independently be any described herein. In particular embodiments, the precursor has a formula of

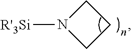

in which the heterocyclyl group can be optionally substituted (e.g., with any substituent described herein as a substitution for alkyl); each R′ can independently be any described herein; and wherein n is 1, 2, 3, 4, or 5.

In some instances, the precursor can have two or more silicon atoms, in which the precursor can include a Si—Si bond. In a particular embodiment, the precursor has a formula of (R″₂N)ₓ(R′)₃₋ₓSi—Si(R′)₃₋ₓ(NR″₂)ₓ, wherein R′ and R″ can be any described herein. In one embodiment, the precursor has a formula of (R″₂N)(R′)₂Si—Si(R′)₂(NR″₂), wherein R′ and R″ can be any described herein. In another embodiment, the precursor has a formula of (R″₂N)₂(R′)Si—Si(R′)(NR″₂)₂, wherein R′ and R″ can be any described herein. In yet another embodiment, the precursor has a formula of (R″₂N)₃Si—Si(NR″₂)₃, wherein each R″ can independently be any described herein.

The precursor can include differing groups attached to the silicon atoms. In one instance, the precursor has a formula of (R″₂N)ₓ(R′)₃₋ₓSi—SiH₃, wherein R′ and R″ can be any described herein.

A linker can be present between two silicon atoms. In one instance, the precursor has a formula of (R″₂N)ₓ(R′)₃₋ₓSi—NR—Si(R′)₃₋ₓ(NR″₂)ₓ, wherein R′ and R″ can be any described herein, and in which R is H, optionally substituted aliphatic, optionally substituted alkyl, optionally substituted alkenyl, optionally substituted alkynyl, or optionally substituted aromatic. In another instance, the precursor has a formula of (R″₂N)ₓ(H)₃₋ₓSi—NR—Si(H)₃₋ₓ(NR″₂)ₓ, wherein R, R′, and R″ can be any described herein.

The precursor can include a combination of R′ groups with a linker having a heteroatom. In one instance, the precursor has a formula of (R′)₃Si—NR—Si(R′)₃, wherein R and R′ can be any described herein. In another instance, the precursor has a formula of (R′)₃Si-L-Si(R′)₃, wherein L and R′ can be any described herein. In particular embodiments, L is oxy (—O—), optionally substituted imino (e.g., —NR—), or optionally substituted silyl (e.g., —SiR₂—).

The precursor can include any useful combination of R′ and NR″₂ groups in combination with two silicon atoms. In one instance, the precursor has a formula of (R″₂N)(R′)₂Si-L-Si(R′)₂(NR″₂)ₓ, wherein L, R′, and R″ can be any described herein.

The precursor can include heterocyclic groups including the silicon and nitrogen atoms. In one embodiment, the precursor has a formula of

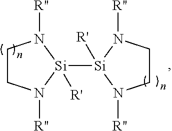

wherein R′ and R″ can be any described herein, and wherein n is 1, 2, 3, or 4.

In another embodiment, the precursor has a formula of

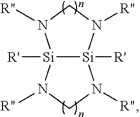

wherein R′ and R″ can be any described herein, and wherein n is 1, 2, 3, or 4. In yet another embodiment, the precursor has a formula of

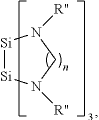

which each R″ can independently be any described herein; and wherein n is 1, 2, 3, or 4.
In another embodiment, the precursor has a formula of

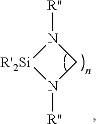

wherein R′ and R″ can be any described herein, and wherein n is 1, 2, 3, or 4. In yet another embodiment, the precursor has a formula of

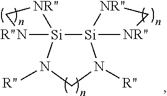

wherein R″ can independently be any described herein, and wherein n is 1, 2, 3, or 4.

In any precursor herein, two R″ can be taken together, with the nitrogen atom to which each is attached, to form an optionally substituted heterocyclyl.

Precursors can include any of the following, e.g., (R^{Ak})Si(NH₂)(NR^{Ak}₂)₂, (R^{Ak})Si(NR^{Ak}₂)₃, (R^{Ak})₂Si(NHR^{Ak}₂)₂, (R^{Ak})(H)Si(NHR^{Ak})₂, (R^{Ak})₃Si(NR^{Ak}₂), (R^{Ak})₃Si(NHR^{Ak}), H₂Si(NHR^{Ak}₂)₂, (R^{Ak})(H)Si(NR^{Ak}₂)₂, HSi(NH₂)(NR^{Ak}₂)₂, HSi(NR^{Ak}₂)₃, Si(NR^{Ak}₂)₄, (R′)(H)Si(NR″₂)₂, (R′)₂Si(NR^{Ak}₂)₂, (R′)₂Si(N[SiH₃]₂)₂, (R′)₂Si(N[SiR″₃]₂)₂, or (R′)₃Si(NHR^{Ak}). In some embodiments, each of R′ and R″, independently, can be any described herein (e.g., H, optionally substituted aliphatic, optionally substituted heteroaliphatic, optionally substituted alkyl, optionally substituted alkenyl, or optionally substituted alkynyl). In other embodiments, each R^{Ak} is, independently, H, optionally substituted aliphatic, optionally substituted heteroaliphatic, optionally substituted alkyl, optionally substituted alkenyl, or optionally substituted alkynyl. In particular embodiments, R^{Ak} is methyl (Me), ethyl (Et), n-propyl (nPr), iso-propyl (iPr), n-butyl (nBu), sec-butyl (sBu), iso-butyl (iBu), tert-butyl (tBu), and the like.

Non-limiting examples of precursor include any of the following: methylaminotrimethylsilane (SiMe₃[NHMe]); dimethylaminodimethylsilane (SiMe₂H[NMe₂]); dimethylaminotrimethylsilane (SiMe₃[NMe₂]); dimethylaminodiethylsilane (SiHEt₂[NMe₂]); dimethylaminotriethylsilane (SiEt₃[NMe₂]); ethylmethylaminodimethylsilane (SiHMe₂[NMeEt]); ethylmethylaminotrimethylsilane (SiMe₃[NMeEt]); ethylmethylaminodiethylsilane (SiHEt₂[NMeEt]); ethylmethylaminotriethylsilane (SiEt₃[NMeEt]); diethylaminomethylsilane (SiH₂Me[NEt₂]); diethylaminoethylsilane (SiH₂Et[NEt₂]); ethylaminotrimethylsilane (SiMe₃[NHEt]); diethylaminodimethylsilane (SiHMe₂[NEt₂]); diethylaminodiethylsilane (SiHEt₂[NEt₂]); diethylaminotrimethylsilane (SiMe₃[NEt₂]); diethylaminotriethylsilane (SiEt₃[NEt₂]); iso-propylaminodimethylsilane (SiHMe₂[NHiPr]); iso-propylaminotrimethylsilane (SiMe₃[NHiPr]); iso-propylamino diethylsilane (SiHEt₂[NHiPr]); iso-propylaminotriethylsilane (SiEt₃[NHiPr]); di-isopropyl aminotrimethylsilane (SiMe₃[NiPr₂]); di-iso-propylaminosilane (SiH₃[NiPr₂], C₆H₁₇NSi, or DIPAS); di-iso-propylaminomethylsilane (SiH₂Me[NiPr₂]); di-isopropylaminodimethylsilane (SiHMe₂[NiPr₂]); di-isopropylaminodiethylsilane (SiHEt₂[NiPr₂]); di-isopropylamino triethylsilane (SiEt₃[NiPr₂]); n-propylaminotrimethylsilane (SiMe₃[NHnPr]); di-sec-butylamino silane (SiH₃[NsBu₂] or DSBAS); di-sec-butylaminomethylsilane (SiH₂Me[NsBu₂]); iso-butylaminotrimethylsilane (SiMe₃[NHiBu]); n-butylaminotrimethylsilane (SiMe₃[NHnBu]); tert-butylaminodimethylsilane (SiHMe₂[NHtBu]); tert-butylaminotrimethylsilane (SiMe₃[NHtBu]); tert-butylaminodiethylsilane (SiHEt₂[NHtBu]); tert-butylaminotriethylsilane (SiEt₃[NHtBu]); dicyclohexylaminosilane (SiH₃[NCy₂], in which Cy is cyclohexyl); N-propylisopropyl aminosilane (SiH₃[NiPrnPr]); N-methylcyclohexylaminosilane (SiH₃[NMeCy]); N-ethyl cyclohexylaminosilane (SiH₃[NEtCy]); allylphenylaminosilane (SiH₃[NAllPh]); N-isopropyl cyclohexylaminosilane (SiH₃[NiPrCy]); allylcyclopentylaminosilane (SiH₃[NAllCp]); phenylcyclohexylaminosilane (SiH₃[NPhCy]); cyclohexylaminotrimethylsilane (SiMe₃[NHCy], in which Cy is cyclohexyl); pyrrolyltrimethylsilane (SiMe₃[NHPy], in which Py is pyrrolyl); pyrrolidinotrimethylsilane (SiMe₃[NHPyr], in which Pyr is pyrrolindyl); piperidino trimethylsilane (SiMe₃[NHPip], in which Pip is piperidinyl); piperazinotrimethylsilane (SiMe₃[NHPz], in which Pz is piperazinyl); imidazolyltrimethylsilane (SiMe₃[NHIm], in which Im is imidazolyl); bis(dimethylamino)silane (SiH₂[NMe₂]₂ or BDMAS); bis(dimethylamino)methylsilane (SiMeH[NMe₂]₂); bis(dimethylamino)dimethylsilane (SiMe₂[NMe₂]₂ or BDMADMS); bis(dimethylamino)diethylsilane (SiEt₂[NMe₂]₂); bis(dimethylamino)methylvinylsilane (SiMeVi[NMe₂]₂); bis(ethylamino)dimethylsilane (SiMe₂[NHEt]₂); bis(ethylmethylamino)silane (SiH₂[NMeEt]₂); bis(ethylmethylamino)dimethylsilane (SiMe₂[NMeEt]₂); bis(ethylmethylamino)diethylsilane (SiEt₂[NMeEt]₂); bis(ethylmethylamino)methylvinylsilane (SiMeVi[NMeEt]₂); bis(diethylamino)silane (SiH₂[NEt₂]₂, C₈H₂₂N₂Si, or BDEAS); bis(diethylamino)dimethylsilane (SiMe₂[NEt₂]₂); bis(diethylamino)methylvinylsilane (SiMeVi[NEt₂]₂); bis(diethylamino)diethylsilane (SiEt₂[NEt₂]₂); bis(iso-propylamino)dimethylsilane (SiMe₂[NHiPr]₂); bis(iso-propylamino)diethylsilane (SiEt₂[NHiPr]₂); bis(iso-propylamino)methylvinylsilane (SiMeVi[NHiPr]₂); bis(di-iso-propylamino)silane (SiH₂[NiPr₂]₂); bis(di-iso-propylamino)dimethylsilane (SiMe₂[NiPr₂]₂); bis(di-iso-propylamino) diethylsilane (SiEt₂[NiPr₂]₂); bis(di-iso-propylamino)methylvinylsilane (SiMeVi[NiPr₂]₂); bis(methylamino)silane (SiH₂[NHMe]₂); bis(sec-butylamino)silane (SiH₂[NHsBu]₂); bis(sec-butylamino)methylsilane (SiHMe[NHsBu]₂); bis(sec-butylamino)ethylsilane (SiHEt[NHsBu]₂); bis(tert-butylamino)silane (SiH₂[NHtBu]₂ or BTBAS); bis(tert-butylamino)dimethylsilane (SiMe₂[NHtBu]₂); bis(tert-butylamino)methylvinylsilane (SiMeVi[NHtBu]₂); bis(tert-butylamino)diethylsilane (SiEt₂[NHtBu]₂); bis(1-imidazolyl)dimethylsilane (SiMe₂[Im]₂, in which Im is imidazolyl); tris(dimethylamino)silane (SiH[NMe₂]3 or 3DMAS); tris(dimethylamino)phenylsilane (SiPh[NMe₂]₃); tris(dimethylamino)methylsilane (SiMe[NMe₂]₃); tris(dimethylamino)ethylsilane (SiEt[NMe₂]₃); tris(ethylmethylamino)silane (SiH[NEtMe]₃); tris(diethylamino)silane (SiH[NEt₂]₃); tris(iso-propylamino)silane (SiH[NHiPr]₃, C₉H₂₅N₃Si, or TIPAS); tris(dimethylamino)silylamide (Si[NMe₂]₃[NH₂]); tetrakis(dimethylamino)silane (Si[NMe₂]₄); tetrakis(ethylmethylamino)silane (Si[NEtMe]₄); tetrakis(diethylamino)silane (Si[NEt₂]₄); 1,2-diethyl-tetrakis(diethylamino)disilane ([Et₂N]2EtSi—SiEt[NEt₂]₂); 1,2-dimethyl-tetrakis(dimethylamino)disilane ([Me₂N]₂MeSi—SiMe[NMe₂]₂); 1,2-dimethyl-tetrakis(diethylamino)disilane ([Et₂N]₂MeSi—SiMe[NEt₂]₂); hexakis(methylamino)disilane ([MeHN]₃Si—Si[NHMe]₃); hexakis(ethylamino)disilane ([EtHN]₃Si—Si[NHEt]₃); hexakis(dimethylamino)disilazane (Me₂N—Si[NMe₂]₂—Si[NMe₂]₂—NMe₂), and the like.

### Isocyanato Silanes

A silicon-containing precursor can include one or more isocyanato groups, thereby providing a non-limiting isocyanato silane. In one embodiment, the precursor has a formula of (R′)₄₋ₓSi(NCO)ₓ, wherein:
x is 1, 2, 3, or 4; and
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted.

In another embodiment, the precursor has a formula of (R′)_{z}Si(NCO)ₓ(NR″₂)_{y}, wherein:
x is 1, 2, 3, or 4;
each of y and z is, independently, 0, 1, 2, or 3;
x+y+z=4;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl.

In yet another embodiment, the precursor has a formula of (NCO)ₓ(R′)₃₋ₓSi-L-Si(R′)₃₋ₓ(NCO)ₓ, wherein:
each x is, independently, 0, 1, 2, or 3;
L is a linker, such as a covalent bond, optionally substituted aliphatic, optionally substituted alkylene, optionally substituted alkenylene, optionally substituted alkynylene, optionally substituted heteroaliphatic, optionally substituted heteroalkylene, optionally substituted heteroalkenylene, optionally substituted heteroalkynylene, optionally substituted aromatic, optionally substituted arylene, optionally substituted heteroaromatic, optionally substituted heteroarylene, oxy (—O—), imino, or silyl; and
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted.

In some embodiments, R′ is H, optionally substituted amino (e.g., —NR₂), aliphatic-oxy (e.g., alkoxy or —OR), aliphatic-carbonyl (e.g., alkanoyl or —C(O)R), aliphatic-carbonyloxy (e.g., alkanoyloxy or —OC(O)R), aliphatic-oxycarbonyl (e.g., alkoxycarbonyl or —C(O)OR), silyl (e.g., —SiR₃), aliphatic-oxy-silyl (e.g., alkoxysilyl or —Si(R)ₐ(OR)_{b}), aminosilyl (e.g., —Si(R)ₐ(NR₂)_{b}), silyloxy (e.g., —O—SiR₃), aliphatic-oxy-silyloxy (e.g., alkoxysilyloxy or —O—Si(R)ₐ(OR)_{b}), aminosilyloxy (e.g., —O—Si(R)ₐ(NR₂)_{b}), aromatic (e.g., aryl), aromatic-oxy (e.g., aryloxy or —OR), hydroxyl (—OH), formyl (—C(O)H), and the like. In particular embodiments, each R is, independently, H, optionally substituted aliphatic, optionally substituted alkyl, optionally substituted alkenyl, optionally substituted alkynyl, optionally substituted heteroaliphatic, optionally substituted aromatic, optionally substituted aryl, and optionally substituted heteroaromatic; a≥0; b≥1; and a+b=3. In some embodiments, two R groups can be taken together, with the nitrogen atom to which each is attached, to form an optionally substituted heterocyclyl. In other embodiments, each R is, independently, H, optionally substituted alkyl, optionally substituted alkenyl, optionally substituted alkynyl, or optionally substituted aryl.

In other embodiments, R″ is H, optionally substituted aliphatic, optionally substituted heteroaliphatic, optionally substituted alkyl, optionally substituted silyl, or optionally substituted silyloxy. In some embodiments, R″ is optionally substituted alkyl (e.g., Me, Et, nPr, iPr, sBu, or tBu). In other embodiments, R″ is —SiR′₃, —SiR₃, —Si(R′)ₐ(OR)_{b}, —Si(R)ₐ(OR)_{b}, —Si(R′)ₐ(NR₂)_{b}, —Si(R)ₐ(NR₂)_{b}, —Si(R′)ₐ(OR)_{b}(NR₂)_{c}, —Si(R)ₐ(OR)_{b}(NR₂)_{c}, —O—SiR′₃, —O—SiR₃, —O—Si(R′)ₐ(OR)_{b}, —O—Si(R)ₐ(OR)_{b}, —O—Si(R′)ₐ(NR₂)_{b}, —O—Si(R)ₐ(NR₂)_{b}, —O—Si(R′)ₐ(OR)_{b}(NR₂)_{c}, or —O—Si(R)ₐ(OR)_{b}(NR₂)_{c} in which each R′ is, independently, H, aliphatic, heteroaliphatic, aromatic, heteroaromatic, amino, hydrazino, azido, hydroxyl, silyl, silyloxy, cyanato, isocyanato, cyano, or isocyano, in which any of these may be optionally substituted; each R is, independently, H, optionally substituted aliphatic, optionally substituted heteroaliphatic, optionally substituted aromatic, or optionally substituted heteroaromatic; each of a, b, and c≥0; and a+b+c=3 or a+b=3 (if c is not present). In particular embodiments, R is H, optionally substituted alkyl, optionally substituted alkenyl, or optionally substituted alkynyl.

Precursors can include any of the following, e.g., (R′)Si(NCO)(NR″₂)₂, (R′)₂Si(NCO)(NR″₂), (R′)₂Si(NCO)(N[SiR₃]₂), or tetraisocyanatosilane (Si[NCO]₄). In some embodiments, each of R′ and R″, independently, can be any described herein (e.g., H, optionally substituted aliphatic, optionally substituted heteroaliphatic, optionally substituted alkyl, optionally substituted alkenyl, or optionally substituted alkynyl). In other embodiments, each R is, independently, H, optionally substituted aliphatic, optionally substituted heteroaliphatic, optionally substituted alkyl, optionally substituted alkenyl, optionally substituted alkynyl, optionally substituted alkoxy, optionally substituted aromatic, optionally substituted heteroaromatic, optionally substituted aryl, or optionally substituted heteroaryl.

### Azido Silanes

A silicon-containing precursor can include one or more azido groups, thereby providing a non-limiting azido silane. In one embodiment, the precursor has a formula of (R′)₄₋ₓSi(N₃)ₓ, wherein:
x is 1, 2, 3, or 4; and
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted.

In another embodiment, the precursor has a formula of (R′)_{z}Si(N₃)ₓ(NR″₂)_{y}, wherein:
x is 1, 2, 3, or 4;
each of y and z is, independently, 0, 1, 2, or 3;
x+y+z=4;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl.

In yet another embodiment, the precursor has a formula of (N₃)ₓ(R′)₃₋ₓSi-L-Si(R′)₃₋ₓ(N₃)ₓ, wherein:
each x is, independently, 0, 1, 2, or 3;
L is a linker, such as a covalent bond, optionally substituted aliphatic, optionally substituted alkylene, optionally substituted alkenylene, optionally substituted alkynylene, optionally substituted heteroaliphatic, optionally substituted heteroalkylene, optionally substituted heteroalkenylene, optionally substituted heteroalkynylene, optionally substituted aromatic, optionally substituted arylene, optionally substituted heteroaromatic, optionally substituted heteroarylene, oxy (—O—), imino, or silyl; and
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted.

In some embodiments, R′ is H, optionally substituted amino (e.g., —NR₂), aliphatic-oxy (e.g., alkoxy or —OR), aliphatic-carbonyl (e.g., alkanoyl or —C(O)R), aliphatic-carbonyloxy (e.g., alkanoyloxy or —OC(O)R), aliphatic-oxycarbonyl (e.g., alkoxycarbonyl or —C(O)OR), silyl (e.g., —SiR₃), aliphatic-oxy-silyl (e.g., alkoxysilyl or —Si(R)ₐ(OR)_{b}), aminosilyl (e.g., —Si(R)ₐ(NR₂)_{b}), silyloxy (e.g., —O—SiR₃), aliphatic-oxy-silyloxy (e.g., alkoxysilyloxy or —O—Si(R)ₐ(OR)_{b}), aminosilyloxy (e.g., —O—Si(R)ₐ(NR₂)_{b}), aromatic (e.g., aryl), aromatic-oxy (e.g., aryloxy or —OR), hydroxyl (—OH), formyl (—C(O)H), and the like. In particular embodiments, each R is, independently, H, optionally substituted aliphatic, optionally substituted alkyl, optionally substituted alkenyl, optionally substituted alkynyl, optionally substituted heteroaliphatic, optionally substituted aromatic, optionally substituted aryl, and optionally substituted heteroaromatic; a≥0; b≥1; and a+b=3. In some embodiments, two R groups can be taken together, with the nitrogen atom to which each is attached, to form an optionally substituted heterocyclyl. In other embodiments, each R is, independently, H, optionally substituted alkyl, optionally substituted alkenyl, optionally substituted alkynyl, or optionally substituted aryl.

In other embodiments, R″ is H, optionally substituted aliphatic, optionally substituted heteroaliphatic, optionally substituted alkyl, optionally substituted silyl, or optionally substituted silyloxy. In some embodiments, R″ is optionally substituted alkyl (e.g., Me, Et, nPr, iPr, sBu, or tBu). In other embodiments, R″ is —SiR′₃, —SiR₃, —Si(R′)ₐ(OR)_{b}, —Si(R)ₐ(OR)_{b}, —Si(R′)ₐ(NR₂)_{b}, —Si(R)ₐ(NR₂)_{b}, —Si(R′)ₐ(OR)_{b}(NR₂)_{c}, —Si(R)ₐ(OR)_{b}(NR₂)_{c}, —O—SiR′₃, —O—SiR₃, —O—Si(R′)ₐ(OR)_{b}, —O—Si(R)ₐ(OR)_{b}, —O—Si(R′)ₐ(NR₂)_{b}, —O—Si(R)ₐ(NR₂)_{b}, —O—Si(R′)ₐ(OR)_{b}(NR₂)_{c}, or —O—Si(R)ₐ(OR)_{b}(NR₂)_{c} in which each R′ is, independently, H, aliphatic, heteroaliphatic, aromatic, heteroaromatic, amino, hydrazino, azido, hydroxyl, silyl, silyloxy, cyanato, isocyanato, cyano, or isocyano, in which any of these may be optionally substituted; each R is, independently, H, optionally substituted aliphatic, optionally substituted heteroaliphatic, optionally substituted aromatic, or optionally substituted heteroaromatic; each of a, b, and c≥0; and a+b+c=3 or a+b=3 (if c is not present). In particular embodiments, R is H, optionally substituted alkyl, optionally substituted alkenyl, or optionally substituted alkynyl.

Precursors can include any of the following, e.g., (R′)₃Si(N₃), (R′)₂Si(N₃)₂, (R′)Si(N₃)₃, or Si(N₃)(NR″₂)₃. In some embodiments, each of R′ and R″, independently, can be any described herein (e.g., H, optionally substituted aliphatic, optionally substituted heteroaliphatic, optionally substituted alkyl, optionally substituted alkenyl, or optionally substituted alkynyl). Non-limiting examples of precursors also include tris(dimethylamino)silylazide ([Me₂N]₃SiN₃); di-tert-butyl diazidosilane (tBu₂Si(N₃)₂); ethylsilicon triazide (EtSi(N₃)₃); and the like.

### Hydrazino Silanes

A silicon-containing precursor can include one or more optionally substituted hydrazino groups, thereby providing a non-limiting hydrazino silane. In one embodiment, the precursor has a formula of (R′)₄₋ₓSi(NR″—NR″₂)ₓ, wherein:
x is 1, 2, 3, or 4;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl.

In another embodiment, the precursor has a formula of (NR″₂—NR″)ₓ(R′)₃₋ₓSi-L-Si(R′)₃₋ₓ(NR″—NR″₂)ₓ, wherein:
each x is, independently, 0, 1, 2, or 3;
L is a linker, such as a covalent bond, optionally substituted aliphatic, optionally substituted heteroaliphatic, optionally substituted aromatic, optionally substituted heteroaromatic, oxy (—O—), imino, or silyl;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl.

In yet another embodiment, the precursor has a formula of (R′)₄₋ₓSi(NR″-L-NR″₂)ₓ, wherein: x is 1, 2, 3, or 4; and each L, R′, and R″ can be any described herein.

In particular embodiments, L is optionally substituted imino, such as —NR—, in which R is H, optionally substituted aliphatic, optionally substituted alkyl, optionally substituted alkenyl, optionally substituted alkynyl, or optionally substituted aromatic. In other embodiments, L is optionally substituted silyl, such as —SiR₂—, in which each R is, independently, H, optionally substituted aliphatic, optionally substituted alkyl, optionally substituted alkenyl, optionally substituted alkynyl, or optionally substituted aromatic. In yet other embodiments, L is —NR—NR—, in which R is any described herein (e.g., R is H, optionally substituted aliphatic, optionally substituted alkyl, optionally substituted alkenyl, optionally substituted alkynyl, or optionally substituted aromatic).

In one instance, at least one x is not 0. In another embodiment, x can be 0 (e.g., if L includes a carbon atom or a heteroatom). In yet another embodiment, x is 0; and/or L includes optionally substituted aliphatic, optionally substituted alkylene, optionally substituted alkenylene, optionally substituted alkynylene, optionally substituted heteroaliphatic, optionally substituted heteroalkylene, optionally substituted heteroalkenylene, optionally substituted heteroalkynylene, optionally substituted aromatic, optionally substituted arylene, optionally substituted heteroaromatic, optionally substituted heteroarylene, oxy (—O—), imino, or silyl.

The precursor can include any useful combination of R′ and hydrazino groups. In one embodiment, the precursor has a formula of (R′)₃Si(NR″-L-NR″₂) or (R′)₃Si(NR″—NR″₂), wherein L, R′, and R″ can be any described herein.

The precursor can include a plurality of hydrazino groups. In one embodiment, the precursor has a formula of (R′)₂Si(NR″-L-NR″₂)₂, (R′)₂Si(NR″—NR″₂)₂, or (R′)₂Si(NH—NHR″)₂, wherein L, R′, and R″ can be any described herein.

The precursor can include at least two silicon atoms. In one embodiment, the precursor has a formula of (NR″₂—NR″)(R′)₂Si—Si(R′)₂(NR″—NR″₂), wherein each R′ and R″ can be any described herein.

Non-limiting precursors can include bis(tert-butylhydrazino)diethylsilane (SiEt₂[NH—NHtBu]₂); tris(dimethylhydrazino)silane (SiH[NH—NMe₂]₃); and the like.

### Siloxanes and Derivatives Thereof

A silicon-containing precursor can include one or more aliphatic-oxy, aromatic-oxy groups, and/or oxy groups, thereby providing a siloxane or a derivative thereof having one or more Si—O, O—Si—O, or Si—O—Si bonds. In one embodiment, the precursor has a formula of (R′)₄₋ₓSi(OR″′)ₓ, wherein:
x is 1, 2, 3, or 4;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″′ is, independently, H, aliphatic, heteroaliphatic, aromatic, heteroaromatic, silyl, or silyloxy, in which any of these may be optionally substituted.

In another embodiment, the precursor has a formula of (R″′O)ₓ(R′)₃₋ₓSi-L-Si(R′)₃₋ₓ(OR″′)ₓ, wherein:
each x is, independently, 0, 1, 2, or 3;
L is a linker, such as a covalent bond, optionally substituted aliphatic, optionally substituted heteroaliphatic, optionally substituted aromatic, optionally substituted heteroaromatic, oxy (—O—), imino, or silyl;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″′ is, independently, H, aliphatic, heteroaliphatic, aromatic, heteroaromatic, silyl, or silyloxy, in which any of these may be optionally substituted.

In particular embodiments, L is optionally substituted imino, such as —NR—, in which R is H, optionally substituted aliphatic, optionally substituted alkyl, optionally substituted alkenyl, optionally substituted alkynyl, or optionally substituted aromatic. In other embodiments, L is optionally substituted silyl, such as —SiR₂—, in which each R is, independently, H, optionally substituted aliphatic, optionally substituted alkyl, optionally substituted alkenyl, optionally substituted alkynyl, or optionally substituted aromatic. In other embodiments, L is —O-L′-O—, in which L′ is optionally substituted aliphatic, optionally substituted heteroaliphatic, optionally substituted aromatic, optionally substituted heteroaromatic, optionally substituted silyl (e.g., —SiR₂—), optionally substituted alkylene (e.g., —(CH₂)ₙ—, in which n is 1 to 6), optionally substituted arylene, and the like. In yet other embodiments, L is oxy.

In one instance, at least one x is not 0. In another embodiment, x can be 0 (e.g., if L includes a carbon atom or a heteroatom). In yet another embodiment, x is 0; and/or L includes optionally substituted aliphatic, optionally substituted alkylene, optionally substituted alkenylene, optionally substituted alkynylene, optionally substituted heteroaliphatic, optionally substituted heteroalkylene, optionally substituted heteroalkenylene, optionally substituted heteroalkynylene, optionally substituted aromatic, optionally substituted arylene, optionally substituted heteroaromatic, optionally substituted heteroarylene, oxy (—O—), imino, or silyl.

In some embodiments, R′ is H, optionally substituted amino (e.g., —NR₂), aliphatic-oxy (e.g., alkoxy or —OR), aliphatic-carbonyl (e.g., alkanoyl or —C(O)R), aliphatic-carbonyloxy (e.g., alkanoyloxy or —OC(O)R), aliphatic-oxycarbonyl (e.g., alkoxycarbonyl or —C(O)OR), silyl (e.g., —SiR₃), aliphatic-oxy-silyl (e.g., alkoxysilyl or —Si(R)ₐ(OR)_{b}), aminosilyl (e.g., —Si(R)ₐ(NR₂)_{b}), silyloxy (e.g., —O—SiR₃), aliphatic-oxy-silyloxy (e.g., alkoxysilyloxy or —O—Si(R)ₐ(OR)_{b}), aminosilyloxy (e.g., —O—Si(R)ₐ(NR₂)_{b}), aromatic (e.g., aryl), aromatic-oxy (e.g., aryloxy or —OR), hydroxyl (—OH), formyl (—C(O)H), and the like. In particular embodiments, each R is, independently, H, optionally substituted aliphatic, optionally substituted alkyl, optionally substituted alkenyl, optionally substituted alkynyl, optionally substituted heteroaliphatic, optionally substituted aromatic, optionally substituted aryl, and optionally substituted heteroaromatic; a≥0; b≥1; and a+b=3. In some embodiments, two R groups can be taken together, with the nitrogen atom to which each is attached, to form an optionally substituted heterocyclyl. In other embodiments, each R is, independently, H, optionally substituted alkyl, optionally substituted alkenyl, optionally substituted alkynyl, or optionally substituted aryl.

In other embodiments, R″′ is H, optionally substituted aliphatic, optionally substituted heteroaliphatic, optionally substituted alkyl, optionally substituted silyl, or optionally substituted silyloxy. In some embodiments, R″′ is optionally substituted alkyl (e.g., Me, Et, nPr, iPr, sBu, or tBu). In other embodiments, R″′ is —SiR′₃, —SiR₃, —Si(R′)ₐ(OR)_{b}, —Si(R)ₐ(OR)_{b}, —Si(R′)ₐ(NR₂)_{b}, —Si(R)ₐ(NR₂)_{b}, —Si(R′)ₐ(OR)_{b}(NR₂)_{c}, —Si(R)ₐ(OR)_{b}(NR₂)_{c}, —O—SiR′₃, —O—SiR₃, —O—Si(R′)ₐ(OR)_{b}, —O—Si(R)ₐ(OR)_{b}, —O—Si(R′)ₐ(NR₂)_{b}, —O—Si(R)ₐ(NR₂)_{b}, —O—Si(R′)ₐ(OR)_{b}(NR₂)_{c}, or —O—Si(R)ₐ(OR)_{b} (NR₂)_{c} in which each R′ is, independently, H, aliphatic, heteroaliphatic, aromatic, heteroaromatic, amino, hydrazino, azido, hydroxyl, silyl, silyloxy, cyanato, isocyanato, cyano, or isocyano, in which any of these may be optionally substituted; each R is, independently, H, optionally substituted aliphatic, optionally substituted heteroaliphatic, optionally substituted aromatic, or optionally substituted heteroaromatic; each of a, b, and c≥0; and a+b+c=3 or a+b=3 (if c is not present). In particular embodiments, R is H, optionally substituted alkyl, optionally substituted alkenyl, or optionally substituted alkynyl.

The precursor can include one or more hydrogen atoms attached to the silicon atom. In one embodiment, the precursor has a formula of H₃Si(OR″′), H₂Si(OR″′)₂, or HSi(OR″′)₃, wherein each R″′ can independently be any described herein.

The precursor can include any combination of R′ and OR″′ groups within the precursor. In one embodiment, the precursor has a formula of (R′)₃Si(OR″′), (R′)₂Si(OR″′)₂, or (R′)Si(OR″′)₃, wherein each of R′ and R″′ can independently be any described herein. The precursor can include alkyl groups, such as in the precursor having a formula of (R^{Ak})₃Si(OR^{Ak}), (R^{Ak})₂Si(OR^{Ak})₂, or (R^{Ak})Si(OR^{Ak})₃, in which R^{Ak} is optionally substituted alkyl.

In some instances, the precursor can have two or more silicon atoms, in which the precursor can include a Si—Si bond. In a particular embodiment, the precursor has a formula of (R″′O)ₓ(R′)₃₋ₓSi—Si(R′)₃₋ₓ(OR″′)ₓ, wherein R′ and R″′ can be any described herein. In one embodiment, the precursor has a formula of (R″′O)(R′)₂Si—Si(R′)₂(OR″′), wherein R′ and R″′ can be any described herein.

The precursor can include a combination of R′ groups with a linker having a heteroatom. In one instance, the precursor has a formula of (R′)₃Si—O—Si(R′)₃, wherein R′ can be any described herein. In another instance, the precursor has a formula of (R′)₃Si—O-L′-O—Si(R′)₃, wherein L′ and R′ can be any described herein. In yet another instance, the precursor has a formula of (R′)₃Si—(OSiR′₂)_{z}—R′, wherein R′ can be any described herein; and in which z is 1, 2, 3, 4, or more. In another instance, the precursor has a formula of (R′)₄₋ₓSi—[(OSiR′₂)_{z}—R′]ₓ, wherein R′ can be any described herein; x is 1, 2, 3, or 4; and z is 1, 2, 3, 4, or more.

The precursor can include any useful combination of R′ and OR″′ groups in combination with two silicon atoms. In one instance, the precursor has a formula of (R″′O)ₓ(R′)₃₋ₓSi—O—Si(R′)₃₋ₓ(OR″′)ₓ, wherein R′ and R″′ can be any described herein. In another instance, the precursor has a formula of (R″′O)ₓ(R′)₃₋ₓSi—O-L′-O—Si(R′)₃₋ₓ(OR″′)ₓ, wherein L′, R′, and R″′ can be any described herein.

Non-limiting precursors can include methoxydimethylsilane (SiHMe₂[OMe]); ethoxydimethylsilane (SiHMe₂[OEt]); iso-propoxydimethylsilane (SiHMe₂[OiPr]); t-butoxydimethylsilane (SiHMe₂[OtBu]); t-pentoxydimethylsilane (SiHMe₂[OtPe]); phenoxy dimethylsilane (SiHMe₂[OPh]); acetoxydimethylsilane (SiHMe₂[OAc]); methoxytrimethylsilane (SiMe₃[OMe]); ethoxytrimethylsilane (SiMe₃[OEt]); iso-propoxytrimethylsilane (SiMe₃[OiPr]); t-butoxytrimethylsilane (SiMe₃[OtBu]); t-pentoxytrimethylsilane (SiMe₃[OtPe]); phenoxy trimethylsilane (SiMe₃[OPh]); acetoxytrimethylsilane (SiMe₃[OAc]); methoxytriethylsilane (SiEt₃[OMe]); ethoxytriethylsilane (SiEt₃[OEt]); iso-propoxytriethylsilane (SiEt₃[OiPr]); t-butoxytriethylsilane (SiEt₃[OtBu]); t-pentoxytriethylsilane (SiEt₃[OtPe]); phenoxytriethylsilane (SiEt₃[OPh]); acetoxytriethylsilane (SiEt₃[OAc]); dimethoxysilane (SiH₂[OMe]₂); diethoxysilane (SiH₂[OEt]₂); di-iso-propoxysilane (SiH₂[OPr]₂); di-tert-butoxysilane (SiH₂[OtBu]₂ or DTBOS); di-tert-pentoxysilane (SiH₂[OtPe]₂ or DTPOS); diacetoxysilane (SiH₂[OAc]₂); dimethoxy dimethylsilane (SiMe₂[OMe]₂); diethoxydimethylsilane (SiMe₂[OEt]₂); di-iso-propoxy dimethylsilane (SiMe₂[OPr]₂); di-tert-butoxydimethylsilane (SiMe₂[OtBu]₂); diacetoxy dimethylsilane (SiMe₂[OAc]₂); dimethoxydiethylsilane (SiEt₂[OMe]₂); diethoxydiethylsilane (SiEt₂[OEt]₂); di-iso-propoxydiethylsilane (SiEt₂[OiPr]₂); di-tert-butoxydiethylsilane (SiEt₂[OtBu]₂); diacetoxydiethylsilane (SiEt₂[OAc]₂); dimethoxydiphenylsilane (SiPh₂[OMe]₂); dimethoxydi-iso-propylsilane (Si[iPr]₂[OMe]₂); diethoxydi-iso-propylsilane (Si[iPr]₂[OEt]₂); di-iso-propoxydi-iso-propylsilane (Si[iPr]₂[OiPr]₂); di-tert-butoxydi-iso-propylsilane (Si[iPr]₂[OtBu]₂); diacetoxydi-iso-propylsilane (Si[iPr]₂[OAc]₂); dimethoxymethylvinylsilane (SiMeVi[OMe]₂); diethoxymethylvinylsilane (SiMeVi[OEt]₂); di-iso-propoxymethylvinylsilane (SiMeVi[OiPr]₂); di-tert-butoxymethylvinylsilane (SiMeVi[OtBu]₂); diacetoxymethylvinylsilane (SiMeVi[OAc]₂); triethoxysilane (SiH[OEt]₃ or TES); trimethoxyethylsilane (SiEt[OMe]₃); triethoxymethylsilane (SiMe[OEt]₃); triethoxyphenylsilane (SiPh[OEt]₃); tetramethoxysilane (Si[OMe]₄); tetraethoxysilane (Si[OEt]₄ or TEOS); tetra-n-propoxysilane (Si[OnPr]₄); tetra-iso-propoxysilane (Si[OiPr]₄); tetra-n-butoxysilane (Si[OnBu]₄); tetra-t-butoxysilane (Si[OtBu]₄); tetramethyldisiloxane (O[SiHMe₂]₂ or TMDO); hexamethyldisiloxane (O[SiMe₃]₂); hexaethyldisiloxane (O[SiEt₃]₂); hexapropyldisiloxane (O[SiPr₃]₂); hexaphenyldisiloxane (O[SiPh₃]₂); hexamethyltrisiloxane (Me₂SiH—O—SiMe₂-O—SiHMe₂); and the like.

### Mixed Silanes Including Oxygen and Nitrogen

A silicon-containing precursor can include one or more optionally substituted amino groups with either aliphatic-oxy or aromatic-oxy groups, thereby providing a non-limiting mixed silane. In one embodiment, the precursor has a formula of (R′)_{z}Si(OR″′)ₓ(NR″₂)_{y}, wherein:
each of x and y is, independently, 1, 2, 3, or 4;
z is 0, 1, or 2;
x+y+z=4;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted;
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl; and
each R″′ is, independently, H, aliphatic, heteroaliphatic, aromatic, heteroaromatic, silyl, or silyloxy, in which any of these may be optionally substituted.

In another embodiment, the precursor has a formula of (R″₂N)_{y}(R″′O)ₓ(R′)_{z}Si-L-Si(R′)_{z}(OR″′)ₓ(NR″₂)_{y}, wherein:
each of x and y is more than 0 (e.g., 1 or 2);
z is 0 or 1;
x+y+z=3;
L is a linker, such as a covalent bond, optionally substituted aliphatic, optionally substituted alkylene, optionally substituted alkenylene, optionally substituted alkynylene, optionally substituted heteroaliphatic, optionally substituted heteroalkylene, optionally substituted heteroalkenylene, optionally substituted heteroalkynylene, optionally substituted aromatic, optionally substituted arylene, optionally substituted heteroaromatic, optionally substituted heteroarylene, oxy (—O—), imino, or silyl;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted;
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl; and
each R″′ is, independently, H, aliphatic, heteroaliphatic, aromatic, heteroaromatic, silyl, or silyloxy, in which any of these may be optionally substituted.

Non-limiting examples of R′, R″, and R″′ are described herein, e.g., such as for amino silane, siloxane, or derivatives thereof.

The precursor can include any combination of R′, NR″₂, and OR′ groups. In one embodiment, the precursor has a formula of (R′)Si(OR″′)₂(NR″₂) or (R′)₂Si(OR″′)₂(NR″₂), wherein each of R′, R″, and R″′ can independently be any described herein. In other embodiments, the precursor has a formula of (R′)₂Si(OR″′)(N[SiR₃]₂), wherein each of R′ and R″′ can independently be any described herein; and R is, independently, H, optionally substituted aliphatic, optionally substituted heteroaliphatic, optionally substituted aromatic, or optionally substituted heteroaromatic.

The precursor can include only amino and oxy-containing groups attached to the silicon atom. In one embodiment, the precursor has a formula of Si(OR″′)₃(NR″₂), Si(OR″′)₂(NR″₂)₂, or Si(OR″′)(NR″₂)₃, wherein each of R″ and R″′ can independently be any described herein. Non-limiting precursors can include, e.g., diethoxy(iso-propylamino)silane (SiH[NHiPr][OEt]₂); diethoxy(tert-butylamino)silane (SiH[NHtBu][OEt]₂); diethoxy(tert-pentylamino)silane (SiH[NHtPe][OEt]₂); di-tert-butoxy(methylamino)silane (SiH[NHMe][OtBu]₂); di-tert-butoxy(ethylamino)silane (SiH[NHEt][OtBu]₂); di-tert-butoxy(iso-propylamino)silane (SiH[NHiPr][OtBu]₂); di-tert-butoxy(n-butylamino)silane (SiH[NHnBu][OtBu]₂); di-tert-butoxy(sec-butylamino)silane (SiH[NHsBu][OtBu]₂); di-tert-butoxy(iso-butylamino)silane (SiH[NHiBu][OtBu]₂); di-tert-butoxy(tert-butylamino) silane (SiH[NHtBu][OtBu]₂); di-tert-pentoxy(methylamino) silane (SiH[NHMe][OtPe]₂); di-tert-pentoxy(ethylamino)silane (SiH[NHEt][OtPe]₂); di-tert-pentoxy(iso-propylamino)silane (SiH[NHiPr][OtPe]₂); di-tert-pentoxy(n-butylamino)silane (SiH[NHnBu][OtPe]₂); di-tert-pentoxy(sec-butylamino)silane (SiH[NHsBu][OtPe]₂); di-tert-pentoxy(iso-butylamino) silane (SiH[NHiBu][OtPe]₂); di-tert-pentoxy(tert-butylamino)silane (SiH[NHtBu][OtPe]₂); dimethoxy(phenylmethylamino)silane (SiH[NPhMe][OMe]₂); diethoxy(phenylmethylamino)silane (SiH[NPhMe][OEt]₂); dimethoxy(phenylmethylamino)methylsilane (SiMe[NPhMe][OMe]₂); diethoxy (phenylmethylamino)methylsilane (SiEt[NPhMe][OEt]₂); and the like.

### Silyl Amines

A silicon-containing precursor can include one or more optionally substituted silyl groups attached to a nitrogen atom, thereby providing a non-limiting silyl amine. In one embodiment, the precursor has a formula of (R″)_{3-y}N(SiR′₃)_{y}, wherein:
y is 1, 2, or 3;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, amino, silyl, or silyloxy, in which any of these may be optionally substituted; or optionally in which two R″ can be taken together, with the nitrogen atom to which each is attached, to form an optionally substituted heterocyclyl.

In another embodiment, the precursor has a formula of (R′₃Si)_{y}(R″)_{2-y}N-L-N(R″)_{2-y}(SiR′₃)_{y}, wherein:
each y is, independently, 0, 1, or 2;
L is a linker, such as a covalent bond, optionally substituted aliphatic, optionally substituted heteroaliphatic, optionally substituted aromatic, optionally substituted heteroaromatic, oxy (—O—), imino, or silyl;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl, optionally in which N-L-N, taken together, forms a multivalent heterocyclyl group.

In one instance, at least one y is not 0. In another embodiment, y can be 0 (e.g., if L includes a carbon atom or a heteroatom). In yet another embodiment, y is 0; and/or L includes optionally substituted aliphatic, optionally substituted alkylene, optionally substituted alkenylene, optionally substituted alkynylene, optionally substituted heteroaliphatic, optionally substituted heteroalkylene, optionally substituted heteroalkenylene, optionally substituted heteroalkynylene, optionally substituted aromatic, optionally substituted arylene, optionally substituted heteroaromatic, optionally substituted heteroarylene, oxy (—O—), imino (e.g., —NR— or —N(SiR₃)—), or silyl (e.g., —SiR₂—), as well as combinations thereof (e.g., —SiR₂—NR—, —NR—SiR₂—, —SiR₂—NR—SiR₂—, and the like). In particular embodiments, each R is, independently, H, optionally substituted aliphatic, optionally substituted alkyl, optionally substituted alkenyl, optionally substituted alkynyl, optionally substituted heteroaliphatic, optionally substituted aromatic, optionally substituted aryl, and optionally substituted heteroaromatic.

In some embodiments, R′ is H, optionally substituted amino (e.g., —NR₂), aliphatic-oxy (e.g., alkoxy or —OR), aliphatic-carbonyl (e.g., alkanoyl or —C(O)R), aliphatic-carbonyloxy (e.g., alkanoyloxy or —OC(O)R), aliphatic-oxycarbonyl (e.g., alkoxycarbonyl or —C(O)OR), silyl (e.g., —SiR₃ or —SiR₂-L-SiR₃), aliphatic-oxy-silyl (e.g., alkoxysilyl or —Si(R)ₐ(OR)_{b}), aminosilyl (e.g., —Si(R)ₐ(NR₂)_{b}), silyloxy (e.g., —O—SiR₃), aliphatic-oxy-silyloxy (e.g., alkoxysilyloxy or —O—Si(R)ₐ(OR)_{b}), aminosilyloxy (e.g., —O—Si(R)ₐ(NR₂)_{b}), aromatic (e.g., aryl), aromatic-oxy (e.g., aryloxy or —OR), hydroxyl (—OH), formyl (—C(O)H), and the like. In particular embodiments, each R is, independently, H, optionally substituted aliphatic, optionally substituted alkyl, optionally substituted alkenyl, optionally substituted alkynyl, optionally substituted heteroaliphatic, optionally substituted aromatic, optionally substituted aryl, and optionally substituted heteroaromatic; a≥0; b≥1; and a+b=3. In some embodiments, two R groups can be taken together, with the nitrogen atom to which each is attached, to form an optionally substituted heterocyclyl. In other embodiments, each R is, independently, H, optionally substituted alkyl, optionally substituted alkenyl, optionally substituted alkynyl, or optionally substituted aryl. L can be any useful linker (e.g., a covalent bond, optionally substituted alkylene, optionally substituted heteroalkylene, oxy, imino, silyl, or the like).

In other embodiments, R″ is H, optionally substituted aliphatic, optionally substituted heteroaliphatic, optionally substituted alkyl, optionally substituted silyl, or optionally substituted silyloxy. In some embodiments, R″ is optionally substituted alkyl (e.g., Me, Et, nPr, iPr, sBu, or tBu). In other embodiments, R″ is —SiR′₃, —SiR₃, —Si(R′)ₐ(OR)_{b}, —Si(R)ₐ(OR)_{b}, —Si(R′)ₐ(NR₂)_{b}, —Si(R)ₐ(NR₂)_{b}, —Si(R′)ₐ(OR)_{b}(NR₂)_{c}, —Si(R)ₐ(OR)_{b}(NR₂)_{c}, —O—SiR′₃, —O—SiR₃, —O—Si(R′)ₐ(OR)_{b}, —O—Si(R)ₐ(OR)_{b}, —O—Si(R′)ₐ(NR₂)_{b}, —O—Si(R)ₐ(NR₂)_{b}, —O—Si(R′)ₐ(OR)_{b}(NR₂)_{c}, or —O—Si(R)ₐ(OR)_{b}(NR₂)_{c} in which each R′ is, independently, H, aliphatic, heteroaliphatic, aromatic, heteroaromatic, amino, hydrazino, azido, hydroxyl, silyl, silyloxy, cyanato, isocyanato, cyano, or isocyano, in which any of these may be optionally substituted; each R is, independently, H, optionally substituted aliphatic, optionally substituted heteroaliphatic, optionally substituted aromatic, or optionally substituted heteroaromatic; each of a, b, and c≥0; and a+b+c=3 or a+b=3 (if c is not present). In particular embodiments, R is H, optionally substituted alkyl, optionally substituted alkenyl, or optionally substituted alkynyl.

The precursor can include at least one R″ group attached to the nitrogen atom. In one embodiment, the precursor has a formula of (R″)N(SiR′₃)₂ or (R″)₂N(SiR′₃), wherein R′ and R″ can be any described herein. In another embodiment, the precursor has a formula of (R″)₂N(SiH₃) or (R″)N(SiH₃)₂, wherein R″ can be any described herein. In particular embodiments, R′ is optionally substituted alkyl, amino, or alkoxy; and R″ is optionally substituted alkyl or amino, optionally wherein two R″ are taken together, with the nitrogen atom to which each are attached, to form a heterocyclyl.

The precursor can include at least one hydrogen atom attached to the nitrogen atom. In one embodiment, the precursor has a formula of (H)N(SiR′₃)₂, wherein R′ can be any described herein. In another embodiment, the precursor has a formula of (H)N(SiR^{Ak}₃)₂, wherein R^{Ak} can be optionally substituted aliphatic, optionally substituted alkyl, optionally substituted alkenyl, or optionally substituted alkynyl.

The precursor can include three silicon atoms attached to the nitrogen atom. In one embodiment, the precursor has a formula of N(SiR′₃)₃, wherein R′ can be any described herein. In another embodiment, the precursor has a formula of N(SiH₃)(SiR′₃)₂, wherein R′ can be any described herein. In yet another embodiment, the precursor has a formula of N(SiH₃)(SiR^{Ak}₃)₂, wherein R^{Ak} can be optionally substituted aliphatic, optionally substituted alkyl, optionally substituted alkenyl, or optionally substituted alkynyl.

The precursor can have two or more nitrogen atoms, in which the precursor includes a N—N bond. In one instance, the precursor has a formula of (R′₃Si)₂N—N(SiR′₃)₂, wherein R′ can be any described herein.

A linker can be present between nitrogen atoms. In one instance, the precursor has a formula of (R′₃Si)(R″)N-L-N(R″)(SiR′₃) or (R′₃Si)₂N-L-N(SiR′₃)₂, wherein R′ and R″ can be any described herein. In some embodiments, L is a covalent bond, optionally substituted alkylene, optionally substituted heteroalkylene, —O—, —SiR₂—, or —Si—. In particular embodiments, at least one of R″ is not H. In another instance, the precursor has a formula of (H₃Si)(R″)N-L-N(R″)(SiH₃), wherein R″ can be any described herein.

The linker can include a silicon atom. In one instance, the precursor has a formula of (R′₃Si)₂N—SiR′₂—N(SiR′₃)₂, wherein R′ can be any described herein. In another instance, the precursor has a formula of (R′₃Si)(R″)N—SiR′₂—N(R″)(SiR′₃) or (R′₃Si)₂N—SiR′₂—N(R″)₂, wherein R′ and R″ can be any described herein.

The linker can include a SiH₂ group. In one instance, the precursor has a formula of (R′₃Si)₂N—SiH₂—N(SiR′₃)₂, wherein R′ can be any described herein. In another instance, the precursor has a formula of (R′₃Si)HN—SiH₂—NH(SiR′₃) or (R′₃Si)₂N—SiH₂—N(R″)₂, wherein R′ and R″ can be any described herein.

A plurality of nitrogen- and silicon-containing moieties may be present within the precursor. In one embodiment, the precursor has a formula of (R′₃Si)(R″)N—SiR′₂—N(R″)—SiR′₂—N(R″)(SiR′₃), wherein R′ and R″ can be any described herein.

Non-limiting precursors can include, e.g., 1,1,3,3-tetramethyldisilazane (NH[SiHMe₂]₂ or TMDS); 1,1,2,3,3-pentamethyldisilazane (NMe[SiHMe₂]₂); 1,1,1,3,3,3-hexamethyldisilazane (NH[SiMe₃]₂ or HMDS); heptamethyldisilazane (NMe[SiMe₃]₂); 1,1,1,3,3,3-hexamethyl-2-ethyldisilazane (NEt[SiMe₃]₂); 1,1,1,3,3,3-hexamethyl-2-isopropyldisilazane (NiPr[SiMe₃]₂); 1,1,1,3,3,3-hexaethyl-2-isopropyldisilazane (NiPr[SiEt₃]₂); 1,1,3,3-tetramethyl-2-isopropyl disilazane (NiPr[SiHMe₂]₂); 1,1,3,3-tetraethyl-2-isopropyldisilazane (NiPr[SiHEt₂]₂); 1,3-diethyltetramethyldisilazane (NH[SiMe₂Et]₂); 1,1,3,3-tetraethyldisilazane (NH[SiHEt₂]₂); 1,1,3,3-tetraethyl-2-methyldisilazane (NMe[SiHEt₂]₂); 1,1,1,3,3,3-hexaethyldisilazane (NH[SiEt₃]₂); 1,1,1,3,3,3-hexaethyl-2-methyldisilazane (NMe[SiEt₃]₂); 1,1,1,2,3,3,3-heptaethyldisilazane (NEt[SiEt₃]₂); 1,2,3-trimethyltrisilazane (N[SiH₂Me]₃); nonamethyl trisilazane (N[SiMe₃]₃); di-iso-propylsilylamine (NiPr₂[SiH₃]); diethylsilylamine (NEt₂[SiH₃]); diisopropylsilylamine (NiPr₂[SiH₃]); di-sec-butylsilylamine (NsBu₂[SiH₃]); di-tert-butyl silylamine (NtBu₂[SiH₃]); disilylmethylamine (NMe[SiH₃]₂); disilylethylamine (NEt[SiH₃]₂); disilylisopropylamine (NiPr[SiH₃]₂); disilyl-tert-butylamine (NtBu[SiH₃]₂); bis(trimethylsilyl)amine (NH[SiMe₃]₂); bis(triethylsilyl)amine (NH[SiEt₃]₂); and the like.

### Silazanes and Derivatives Thereof

A silicon-containing precursor can include one or more amino, silyl, and/or imino groups, thereby providing a silazane or a derivative thereof having one or more Si—N, N—Si—N, Si—N—Si, N—Si—Si, or N—Si—N—Si bonds. In one embodiment, the precursor has a formula of (R″)_{3-y}N(SiR′2-L-SiR′₃)_{y}, wherein:
y is 1, 2, or 3;
L is a linker, such as a covalent bond, optionally substituted aliphatic, optionally substituted heteroaliphatic, optionally substituted aromatic, optionally substituted heteroaromatic, oxy (—O—), imino, or silyl, as well as combinations thereof;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, amino, silyl, or silyloxy, in which any of these may be optionally substituted; or optionally in which two R″ can be taken together, with the nitrogen atom to which each is attached, to form an optionally substituted heterocyclyl.

In another embodiment, the precursor has a formula of (R″)_{3-y}N(SiR′2-L-SiR′₂—NR″₂)_{y}, wherein y is 1, 2, or 3; and each of L, R′, and R″ can be any described herein.

In yet another embodiment, the precursor has a formula of (R″)_{3-y}N(SiR′2-L-NR″₂)_{y}, wherein y is 1, 2, or 3; and each of L, R′, and R″ can be any described herein.

In one embodiment, the precursor has a formula of (R′)₄₋ₓSi(NR″-L-SiR′₃)ₓ, wherein:
x is 1, 2, 3, or 4;
L is a linker, such as a covalent bond, optionally substituted aliphatic, optionally substituted heteroaliphatic, optionally substituted aromatic, optionally substituted heteroaromatic, oxy (—O—), imino, or silyl, as well as combinations thereof;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, amino, silyl, or silyloxy, in which any of these may be optionally substituted; or optionally in which two R″ can be taken together, with the nitrogen atom to which each is attached, to form an optionally substituted heterocyclyl.

In another embodiment, the precursor has a formula of (R″₂N)—(SiR′2-L)_{z}-SiR′₃, wherein z is 1, 2, or 3; and each of L, R′, and R″ can be any described herein.

In some embodiments, L includes optionally substituted aliphatic, optionally substituted alkylene, optionally substituted alkenylene, optionally substituted alkynylene, optionally substituted heteroaliphatic, optionally substituted heteroalkylene, optionally substituted heteroalkenylene, optionally substituted heteroalkynylene, optionally substituted aromatic, optionally substituted arylene, optionally substituted heteroaromatic, optionally substituted heteroarylene, oxy (—O—), imino (e.g., —NR— or —N(SiR₃)—), or silyl (e.g., —SiR₂—), as well as combinations thereof (e.g., —SiR₂—NR—, —NR—SiR₂—, —SiR₂—NR—SiR₂—, and the like). In particular embodiments, each R is, independently, H, optionally substituted aliphatic, optionally substituted alkyl, optionally substituted alkenyl, optionally substituted alkynyl, optionally substituted heteroaliphatic, optionally substituted aromatic, optionally substituted aryl, and optionally substituted heteroaromatic.

In some embodiments, R′ is H, optionally substituted amino (e.g., —NR₂), aliphatic-oxy (e.g., alkoxy or —OR), aliphatic-carbonyl (e.g., alkanoyl or —C(O)R), aliphatic-carbonyloxy (e.g., alkanoyloxy or —OC(O)R), aliphatic-oxycarbonyl (e.g., alkoxycarbonyl or —C(O)OR), silyl (e.g., —SiR₃ or —SiR₂-L-SiR₃), aliphatic-oxy-silyl (e.g., alkoxysilyl or —Si(R)ₐ(OR)_{b}), aminosilyl (e.g., —Si(R)ₐ(NR₂)_{b}), silyloxy (e.g., —O—SiR₃), aliphatic-oxy-silyloxy (e.g., alkoxysilyloxy or —O—Si(R)ₐ(OR)_{b}), aminosilyloxy (e.g., —O—Si(R)ₐ(NR₂)_{b}), aromatic (e.g., aryl), aromatic-oxy (e.g., aryloxy or —OR), hydroxyl (—OH), formyl (—C(O)H), and the like. In particular embodiments, each R is, independently, H, optionally substituted aliphatic, optionally substituted alkyl, optionally substituted alkenyl, optionally substituted alkynyl, optionally substituted heteroaliphatic, optionally substituted aromatic, optionally substituted aryl, and optionally substituted heteroaromatic; a≥0; b≥1; and a+b=3. In some embodiments, two R groups can be taken together, with the nitrogen atom to which each is attached, to form an optionally substituted heterocyclyl. In other embodiments, each R is, independently, H, optionally substituted alkyl, optionally substituted alkenyl, optionally substituted alkynyl, or optionally substituted aryl. L can be any useful linker (e.g., a covalent bond, optionally substituted alkylene, optionally substituted heteroalkylene, oxy, imino, silyl, or the like).

In other embodiments, R″ is H, optionally substituted aliphatic, optionally substituted heteroaliphatic, optionally substituted alkyl, optionally substituted silyl, or optionally substituted silyloxy. In some embodiments, R″ is optionally substituted alkyl (e.g., Me, Et, nPr, iPr, sBu, or tBu). In other embodiments, R″ is —SiR′₃, —SiR₃, —Si(R′)ₐ(OR)_{b}, —Si(R)ₐ(OR)_{b}, —Si(R′)ₐ(NR₂)_{b}, —Si(R)ₐ(NR₂)_{b}, —Si(R′)ₐ(OR)_{b}(NR₂)_{c}, —Si(R)ₐ(OR)_{b}(NR₂)_{c}, —O—SiR′₃, —O—SiR₃, —O—Si(R′)ₐ(OR)_{b}, —O—Si(R)ₐ(OR)_{b}, —O—Si(R′)ₐ(NR₂)_{b}, —O—Si(R)ₐ(NR₂)_{b}, —O—Si(R′)ₐ(OR)_{b}(NR₂)_{c}, or —O—Si(R)ₐ(OR)_{b}(NR₂)_{c} in which each R′ is, independently, H, aliphatic, heteroaliphatic, aromatic, heteroaromatic, amino, hydrazino, azido, hydroxyl, silyl, silyloxy, cyanato, isocyanato, cyano, or isocyano, in which any of these may be optionally substituted; each R is, independently, H, optionally substituted aliphatic, optionally substituted heteroaliphatic, optionally substituted aromatic, or optionally substituted heteroaromatic; each of a, b, and c≥0; and a+b+c=3 or a+b=3 (if c is not present). In particular embodiments, R is H, optionally substituted alkyl, optionally substituted alkenyl, or optionally substituted alkynyl.

The precursor can include one or more disilanyl groups and amino groups. In one embodiment, the precursor has a formula of R″₂N—SiR′₂—SiR′₃, wherein L, R′, and R″ can be any described herein. In other embodiments, the precursor has a formula of R″₂N—SiH₂—SiH₃, wherein R″ is any described herein. In another embodiment, the precursor has a formula of (R″)_{3-y}N—(SiR′₂—SiR′₃)_{y}, wherein y, R′, and R″ can be any described herein. In yet another embodiment, the precursor has a formula of (R″)_{3-y}N—(SiH₂—SiH₃)_{y}, wherein y and R″ can be any described herein.

The precursor can include a bivalent disilanyl group. In one embodiment, the precursor has a formula of R″₂N—SiR′₂—SiR′₂-L-NR″₂, wherein L, R′, and R″ can be any described herein. In another embodiment, the precursor has a formula of R″₂N—SiR′₂—SiR′₂—NR″₂, wherein R′ and R″ can be any described herein.

A linker L can be present between two silyl group. In one embodiment, the precursor has a formula of R″₂N—SiR′₂-L-SiR′₃ or R″N—(SiR′₂-L-SiR′₃)₂, wherein L, R′, and R″ can be any described herein. In another embodiment, the precursor has a formula of R″₂N—SiR′₂-L-SiR′₂—NR″₂, wherein L, R′, and R″ can be any described herein. In yet another embodiment, the precursor has a formula of (R″)_{3-y}N—(SiR′₂-L-SiH₃)_{y}, wherein y, L, R′, and R″ can be any described herein.

The precursor can include —SiH₃ as the silyl group. In one embodiment, the precursor has a formula of R″₂N—SiH₂—SiH₃, wherein R″ can be any described herein. In another embodiment, the precursor has a formula of (R″)N—(SiH₂-L-SiH₃)₂ or (R″)₂N—(SiH₂-L-SiH₃), wherein L and R″ can be any described herein.

The precursor can include a silyl-substituted amino group, such as, e.g., —NR″—SiR′₃, in which R′ and R″ can be any described herein. In one embodiment, the precursor has a formula of (R′)₄₋ₓSi(NR″—SiR′₃)ₓ or (R′)₄₋ₓSi(NH—SiR′₃)ₓ, wherein x is 1, 2, 3, or 4; and in which R′ and R″ can be any described herein. In another embodiment, the precursor has a formula of H₂Si(NR″—SiR′₃)₃, wherein R′ and R″ can be any described herein.

The precursor can include a bis-trisilylamino group, such as, e.g., —N(SiR′₃)₂ in which R′ can be any described herein. In one embodiment, the precursor has a formula of R″₂N—SiR′₂—N(SiR′₃)₂, in which R′ and R″ can be any described herein. In another embodiment, the precursor has a formula of R″₂N—SiH₂—N(SiH₃)₂, in which R′ can be any described herein. In yet another embodiment, the precursor has a formula of (R′₃Si)₂N—[SiR′₂—N(SiR′₃)]_{z}(SiR′₃), wherein z is 0, 1, 2, or 3; and in which R′ and R″ can be any described herein.

The precursor can include a linker L disposed between a silicon atom and a nitrogen atom. In one embodiment, the precursor has a formula of R″₂N—SiR′₂-L-NR″₂, wherein L, R′, and R″ can be any described herein.

The precursor can include a linker L disposed between two nitrogen atoms. In one embodiment, the precursor has a formula of R′₃Si—SiR′₂—NR″-L-NR″—SiR′₂—SiR′₃, wherein L, R′, and R″ can be any described herein.

The linker can include a silylimino group, such as, e.g., —N(SiR′₃)—, in which R′ can be any described herein. In one embodiment, the precursor has a formula of R″₂N—[SiR′₂—N(SiR′₃)]z-SiR′₃ or R″₂N—[N(SiR′₃)]z-SiR′₃, in which z is 1, 2, 3, or more; and wherein R′ and R″ can be any described herein.

The linker can include both a silyl group and an imino group. In one embodiment, the precursor has a formula of R″₂N—[SiR′₂—NR″]_{z}—SiR′₃, in which z is 1, 2, 3, or more; and wherein R′ and R″ can be any described herein.

Non-limiting precursors include, e.g., di-iso-propylaminodisilane ([iPr₂N]—SiH₂—SiH₃); di-sec-butylaminodisilane ([sBu₂N]—SiH₂—SiH₃); methylcyclohexylaminodisilane ([MeCyN]—SiH₂—SiH₃); methylphenylaminodisilane ([MePhN]—SiH₂—SiH₃); piperidinodisilane; 3,5-dimethylpiperidinodisilane; di-iso-propylaminotrisilylamine ([iPr₂N]—SiH₂—N[SiH₃]₂); diethyl aminotrisilylamine ([Et₂N]—SiH₂—N[SiH₃]₂); iso-propylaminotrisilylamine ([iPrHN]—SiH₂—N[SiH₃]₂); and the like.

### Mixed Amines Including Silicon and Oxygen

A silicon-containing precursor can include one or more amino groups substituted with a silyl group, thereby providing a non-limiting mixed amine. In one embodiment, the precursor has a formula of (R″)_{3-y}N[Si(OR″′)ₓR′₃₋ₓ]y, wherein:
each of x and y is, independently, 1, 2, or 3;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted;
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl; and
each R″′ is, independently, H, aliphatic, heteroaliphatic, aromatic, heteroaromatic, silyl, or silyloxy, in which any of these may be optionally substituted.

Non-limiting examples of R′, R″, and R″′ are described herein, e.g., such as for amino silane, siloxane, silyl amine, or derivatives thereof.

The precursor can include any combination of R″ groups and silicon-containing groups. In one embodiment, the precursor has a formula of (R″)_{3-y}N[Si(OR^{Ak})ₓR″^{Ak}₃₋ₓ]y or (R^{Ak})_{3-y}N [Si(OR^{Ak})ₓR^{Ak}₃₋ₓ]_{y}, in which R″, x, and y is any described herein; and wherein R^{Ak} is H, optionally substituted aliphatic, or optionally substituted heteroaliphatic. In particular embodiments, R^{Ak} is H, optionally substituted alkyl, optionally substituted alkylene, or optionally substituted alkynyl. In other embodiments, the precursor has a formula of (R″)_{3-y}N [Si(OR^{Ak})ₓH₃₋ₓ]y or (R″)_{3-y}N[Si(OR^{Ak})H(R^{Ak})]_{y}, in which R″, R^{Ak}, x, and y is any described herein.

The precursor can include two silicon-containing groups. In one embodiment, the precursor has a formula of (R″)N[Si(OR^{Ak})ₓR^{Ak}₃₋ₓ]₂ or (R^{Ak})N[Si(OR^{Ak})ₓR^{Ak}₃₋ₓ]₂, in which R″, R^{Ak}, x, and y is any described herein. In particular embodiments, x is 1 or 2.

The precursor can include a hydrogen atom attached to the nitrogen atom. In one embodiment, the precursor has a formula of (H)_{3-y}N[Si(OR^{Ak})ₓR^{Ak}₃₋ₓ]_{y} or (H)_{3-y}N[Si(OR^{Ak})ₓH₃₋ₓ]y or (H)_{3-y}N[Si(OR^{Ak})H(R^{Ak})]_{y}, in which R^{Ak}, x, and y is any described herein. In particular embodiments, x is 1 or 2.

Non-limiting precursors include, e.g., bis(dimethoxysilyl)amine (NH[Si(OMe)₂H]₂); bis(diethoxysilyl)amine (NH[Si(OEt)₂H]₂); N-iso-propylbis(diethoxysilyl)amine (NiPr[Si(OEt)₂H]₂); bis(methoxymethylsilyl)amine (NH[Si(OMe)MeH]₂); tris(dimethoxysilyl)amine (N[Si(OMe)₂H]₃); tris(methoxymethylsilyl)amine (N[Si(OMe)MeH]₃); tris(diethoxysilyl)amine (N[Si(OEt)₂H]₃); tris(trimethoxysilyl)amine (N[Si(OMe)₃]₃); and the like.

### Cyclic Silazanes

A silicon-containing precursor can include a cyclic group having one or more nitrogen atoms. In one embodiment, the precursor has a formula of [NR″—(SiR′₂)ₙ]_{z}, wherein:
z is 1, 2, 3, 4, 5, or more;
n is 1, 2, or 3;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, amino, silyl, or silyloxy, in which any of these may be optionally substituted; or optionally in which two R″ can be taken together, with the nitrogen atom to which each is attached, to form an optionally substituted heterocyclyl.

In one embodiment, the precursor has a formula of [NR″—(SiR′₂)ₙ-L-(SiR′₂)ₙ]_{z}, wherein:
z is 1, 2, 3, 4, 5, or more;
each n is, independently, 1, 2, or 3;
each L is, independently, a linker, such as a covalent bond, optionally substituted aliphatic, optionally substituted heteroaliphatic, optionally substituted aromatic, optionally substituted heteroaromatic, oxy (—O—), imino, or silyl, as well as combinations thereof,
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, amino, silyl, or silyloxy, in which any of these may be optionally substituted; or optionally in which two R″ can be taken together, with the nitrogen atom to which each is attached, to form an optionally substituted heterocyclyl.

In another embodiment, the precursor has a formula of [NR″-L-NR″—(SiR′₂)ₙ]_{z}, wherein: z is 1, 2, 3, 4, 5, or more; each n is, independently, 1, 2, or 3; and in which R′ and R″ can be any described herein.

In yet another embodiment, the precursor has a formula of [L-(SiR′₂)ₙ]_{z}, wherein: z is 1, 2, 3, 4, 5, or more; each n is, independently, 1, 2, or 3; L is imino (e.g., —NR—), optionally substituted aliphatic, optionally substituted heteroaliphatic, or combinations thereof, and in which R′ can be any described herein. In particular embodiments, if L does not include a heteroatom, then R′ includes one or more heteroatoms (e.g., nitrogen atoms).

In one embodiment, the precursor has a formula of

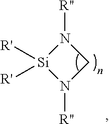

wherein R′ and R″ can be any described herein, and wherein n is 1, 2, 3, or 4.

In another embodiment, the precursor has a formula of

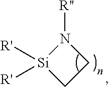

wherein R′ and R″ can be any described herein, and wherein n is 1, 2, 3, or 4.

In yet another embodiment, the precursor has a formula of

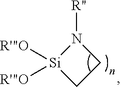

wherein R″ and R″′ can be any described herein, and wherein n is 1, 2, 3, or 4. In particular embodiments, each R″′ is, independently, H, aliphatic, heteroaliphatic, aromatic, heteroaromatic, silyl, or silyloxy, in which any of these may be optionally substituted.

In one embodiment, the precursor has a formula of

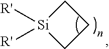

wherein R′ can include a heteroatom (e.g., a nitrogen atom, such as in optionally substituted amino, azido, isocyanato, or optionally substituted hydrazino), and wherein n is 1, 2, 3, or 4.

In some embodiments, L includes optionally substituted aliphatic, optionally substituted alkylene, optionally substituted alkenylene, optionally substituted alkynylene, optionally substituted heteroaliphatic, optionally substituted heteroalkylene, optionally substituted heteroalkenylene, optionally substituted heteroalkynylene, optionally substituted aromatic, optionally substituted arylene, optionally substituted heteroaromatic, optionally substituted heteroarylene, oxy (—O—), imino (e.g., —NR— or —N(SiR₃)—), or silyl (e.g., —SiR₂—), as well as combinations thereof (e.g., —SiR₂—NR—, —NR—SiR₂—, —SiR₂—NR—SiR₂—, and the like). In particular embodiments, each R is, independently, H, optionally substituted aliphatic, optionally substituted alkyl, optionally substituted alkenyl, optionally substituted alkynyl, optionally substituted heteroaliphatic, optionally substituted aromatic, optionally substituted aryl, and optionally substituted heteroaromatic.

In other embodiments, L is an optionally substituted alkylene, and at least one R′ includes an optionally substituted heteroaliphatic, optionally substituted amino, optionally substituted aliphatic-oxy, or optionally substituted alkoxy.

In some embodiments, each R′ is, independently, H, optionally substituted aliphatic, optionally substituted alkyl, optionally substituted alkenyl, optionally substituted alkynyl, optionally substituted aromatic, or optionally substituted aryl. In other embodiments, each R′ is, independently, optionally substituted heteroaliphatic, optionally substituted amino, or optionally substituted alkoxy.

In other embodiments, each R″ is, independently, H, optionally substituted aliphatic, optionally substituted alkyl, optionally substituted alkenyl, optionally substituted alkynyl, optionally substituted silyl, optionally substituted amino, optionally substituted aromatic, optionally substituted aryl, optionally substituted heteroaromatic, or optionally substituted heteroaryl.

Non-limiting precursors include 1,3,3-trimethylcyclodisilazane ([NH—SiMe₂][NH—SiMeH]); hexamethylcyclotrisilazane ([NH—SiMe₂]₃); octamethylcyclotetrasilazane ([NH—SiMe₂]₄); and the like.

### Cyclic Siloxanes

A silicon-containing precursor can include a cyclic group having one or more oxygen atoms. In one embodiment, the precursor has a formula of [L-(SiR′₂)ₙ]_{z}, wherein:
z is 1, 2, 3, 4, 5, or more;
n is 1, 2, or 3;
L is an oxygen-containing linker (e.g., oxy or heteroalkylene); and
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted.

In one embodiment, the precursor has a formula of [O-L′-O—(SiR′₂)ₙ]_{z}, wherein:
z is 1, 2, 3, 4, 5, or more;
n is 1, 2, or 3;
each L′ is, independently, a linker, such as optionally substituted aliphatic, optionally substituted heteroaliphatic, optionally substituted aromatic, optionally substituted heteroaromatic, optionally substituted silyl (e.g., —SiR₂—), optionally substituted alkylene (e.g., —(CH₂)ₙ—, in which n is 1 to 6), and optionally substituted arylene; and in which R′ is any described herein.

In another embodiment, the precursor has a formula of [O—(SiR′₂)ₙ-L-(SiR′₂)ₙ]_{z}, wherein:
z is 1, 2, 3, 4, 5, or more;
each n is, independently, 1, 2, or 3;
each L is, independently, a linker, such as a covalent bond, optionally substituted aliphatic, optionally substituted heteroaliphatic, optionally substituted aromatic, optionally substituted heteroaromatic, oxy (—O—), imino, or silyl, as well as combinations thereof, and in which R′ is any described herein.

In yet another embodiment, the precursor has a formula of [L-(SiR′₂)ₙ]_{z}, wherein: z is 1, 2, 3, 4, 5, or more; each n is, independently, 1, 2, or 3; L is oxy (—O—), optionally substituted aliphatic, optionally substituted heteroaliphatic, or combinations thereof, and in which R′ can be any described herein. In particular embodiments, if L does not include a heteroatom, then R′ includes one or more heteroatoms (e.g., oxygen atoms).

In one embodiment, the precursor has a formula of

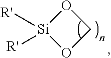

wherein R′ can be any described herein, and wherein n is 1, 2, 3, or 4.

In another embodiment, the precursor has a formula of

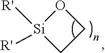

wherein R′ and R″ can be any described herein, and wherein n is 1, 2, 3, or 4.

In yet another embodiment, the precursor has a formula of

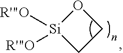

wherein R″′ can be any described herein, and wherein n is 1, 2, 3, or 4. In particular embodiments, each R″′ is, independently, H, aliphatic, heteroaliphatic, aromatic, heteroaromatic, silyl, or silyloxy, in which any of these may be optionally substituted.

In one embodiment, the precursor has a formula of

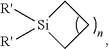

wherein R′ can include a heteroatom (e.g., an oxygen atom, such as in optionally substituted aliphatic-oxy, aliphatic-oxycarbonyl, aliphatic-carbonyl, aliphatic-carbonyloxy, optionally substituted alkoxy, optionally substituted alkoxycarbonyl, optionally substituted alkanoyl, optionally substituted alkanoyloxy, and the like), and wherein n is 1, 2, 3, or 4.

In some embodiments, each R′ is, independently, H, optionally substituted aliphatic, optionally substituted alkyl, optionally substituted alkenyl, optionally substituted alkynyl, optionally substituted aminoalkyl, optionally substituted aromatic, or optionally substituted aryl. In other embodiments, each R′ is, independently, optionally substituted heteroaliphatic, optionally substituted amino, or optionally substituted alkoxy.

Non-limiting precursors include, e.g., tetramethylcyclotetrasiloxane ([OSiHMe]₄ or TMCTS); hexamethylcyclotetrasiloxane ([OSiMe₂OSiHMe]₂ or HMCTS); octamethyl cyclotetrasiloxane ([OSiMe₂]₄, C₈H₂₄O₄Si₄, or OMCTS); decamethylcyclopentasiloxane ([OSiMe₂]₅ or C₁₀H₃₀O₅Si₅); 2-dimethylamino-2,4,4,6,6-pentamethylcyclotrisiloxane ([OSiMe₂]₂[OSiMe(NMe₂)]); 2-dimethylamino-2,4,4,6,6,8,8-heptamethylcyclotetrasiloxane ([OSiMe₂]₃[OSiMe(NMe₂)]); and the like.

### Amino Siloxane and Derivatives Thereof

A silicon-containing precursor can include siloxane or a derivative thereof and having one or more amino substitutions, thereby providing a siloxane or a derivative thereof having one or more Si—O, O—Si—O, or Si—O—Si bonds and having one or more —NR₂ substitutions. In one embodiment, the precursor has a formula of (R″)_{3-y}N[SiR′₂—(OSiR′₂)_{z}—R′]_{y}, wherein:
y is 1, 2, or 3;
z is 1, 2, 3, or more;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl.

In another embodiment, the precursor has a formula of (R″)_{3-y}N [(SiR′₂—O)_{z}—SiR′₃]_{y}, wherein R′, R″, y, and z can be any described herein.

The precursor can include an optionally substituted amino group with an optionally substituted silyl group. In one embodiment, the precursor has a formula of R″₂N—SiR′₂—(OSiR′₂)_{z}—R′ or R″₂N—SiR′₂—O—SiR′₃, wherein R′, R″, and z can be any described herein. In another embodiment, the precursor has a formula of R″₂N(SiR′₂—O)_{z}—SiR′₃, wherein R′, R″, and z can be any described herein.

The precursor can include two optionally substituted amino group. In one embodiment, the precursor has a formula of R″₂N—SiR′₂—(OSiR′₂)_{z}—NR″₂, wherein R′, R″, and z can be any described herein.

In some embodiments, R′ is H, optionally substituted aliphatic, optionally substituted alkyl, optionally substituted alkenyl, or optionally substituted alkynyl. In other embodiments, R″ is H, optionally substituted aliphatic, optionally substituted alkyl, optionally substituted alkenyl, or optionally substituted alkynyl. In particular embodiments, z is 1, 2, or 3.

Non-limiting precursors can include, e.g., 1-dimethylamino-pentamethyldisiloxane (Me₂N—SiMe₂-OSiMe₃); 1-diethylamino-pentamethyldisiloxane (Et₂N—SiMe₂-OSiMe₃); 1-ethylmethylamino-pentamethyldisiloxane (EtMeN—SiMe₂-OSiMe₃); 1,3-bis(dimethylamino)tetramethyldisiloxane (Me₂N—SiMe₂-OSiMe₂-NMe₂); 1-dimethylamino-heptamethyltrisiloxane (Me₂N—SiMe₂-[OSiMe₂]₂-Me); 1,5-bis(dimethylamino) hexamethyltrisiloxane (Me₂N—SiMe₂-[OSiMe₂]₂—NMe₂); and the like.

### Silanols, Including Alkyl Silanols or Alkoxy Silanols

A silicon-containing precursor can include one or more hydroxyl groups, thereby providing a non-limiting silanol. In one embodiment, the precursor has a formula of (R′)₄₋ₓSi(OH)ₓ, wherein:
x is 1, 2, 3, or 4; and
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted.

In other embodiments, the precursor has a formula of (R′)_{z}Si(OH)ₓ(OR″′)_{y}, wherein:
x is 1, 2, 3, or 4;
each of y and z is, independently, 0, 1, 2, or 3;
x+y+z=4;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″′ is, independently, H, aliphatic, heteroaliphatic, aromatic, heteroaromatic, silyl, or silyloxy, in which any of these may be optionally substituted.

The precursor can have one hydroxyl group. In one embodiment, the precursor has a formula of (R′)₃Si(OH), in which each R′ can be any described herein. In another embodiment, the precursor has a formula of Si(OH)(OR″′)₃, in which each R″′ can be any described herein. In particular embodiments, R″′ is optionally substituted alkyl (e.g., Me, Et, nPr, iPr, sBu, or tBu), in which the optionally substituted alkyl is linear, branched, substituted, or unsubstituted.

Non-limiting precursors include, e.g., tri(t-butoxy)silanol (SiOH[OtBu]₃); tri(t-pentoxy)silanol (SiOH[OtPe]₃); and the like.

### Carbonyloxy Silanes

A silicon-containing precursor can include one or more optionally substituted aliphatic-carbonyloxy groups, thereby providing a non-limiting carbonyloxy silane. In one embodiment, the precursor has a formula of (R′)₄₋ₓSi(OC(O)—R″″)ₓ, wherein:
x is 1, 2, 3, or 4;
each R′ is, independently, H, aliphatic, aliphatic-carbonyl, aliphatic-oxy, aliphatic-oxycarbonyl, heteroaliphatic, heteroaliphatic-carbonyl, heteroaliphatic-oxy, heteroaliphatic-oxycarbonyl, aromatic, aromatic-carbonyl, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″″ is, independently, H, aliphatic, heteroaliphatic, aromatic, heteroaromatic, amino, or aminooxy, in which any of these may be optionally substituted.

In another embodiment, the precursor has a formula of (R″″—C(O)O)ₓ(R′)₃₋ₓSi-L-Si(R′)₃₋ₓ(OC(O)—R″″)ₓ, wherein:
each x is, independently, 0, 1, 2, or 3;
L is a linker, such as a covalent bond, optionally substituted aliphatic, optionally substituted heteroaliphatic, optionally substituted aromatic, optionally substituted heteroaromatic, oxy (—O—), imino, or silyl;
each R′ is, independently, H, aliphatic, aliphatic-carbonyl, aliphatic-oxy, aliphatic-oxycarbonyl, heteroaliphatic, heteroaliphatic-carbonyl, heteroaliphatic-oxy, heteroaliphatic-oxycarbonyl, aromatic, aromatic-carbonyl, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″″ is, independently, H, aliphatic, heteroaliphatic, aromatic, heteroaromatic, amino, or aminooxy, in which any of these may be optionally substituted.

In some embodiments, R′ is H, optionally substituted amino (e.g., —NR₂), aliphatic-oxy (e.g., alkoxy or —OR), aliphatic-carbonyl (e.g., alkanoyl or —C(O)R), aliphatic-oxycarbonyl (e.g., alkoxycarbonyl or —C(O)OR), silyl (e.g., —SiR₃), aliphatic-oxy-silyl (e.g., alkoxysilyl or —Si(R)ₐ(OR)_{b}), aminosilyl (e.g., —Si(R)ₐ(NR₂)_{b}), silyloxy (e.g., —O—SiR₃), aliphatic-oxy-silyloxy (e.g., alkoxysilyloxy or —O—Si(R)ₐ(OR)_{b}), aminosilyloxy (e.g., —O—Si(R)ₐ(NR₂)_{b}), aromatic (e.g., aryl), aromatic-oxy (e.g., aryloxy or —OR), hydroxyl (—OH), formyl (—C(O)H), and the like. In particular embodiments, each R is, independently, H, optionally substituted aliphatic, optionally substituted alkyl, optionally substituted alkenyl, optionally substituted alkynyl, optionally substituted heteroaliphatic, optionally substituted aromatic, optionally substituted aryl, and optionally substituted heteroaromatic; a≥0; b≥1; and a+b=3. In some embodiments, two R groups can be taken together, with the nitrogen atom to which each is attached, to form an optionally substituted heterocyclyl. In other embodiments, each R is, independently, H, optionally substituted alkyl, optionally substituted alkenyl, optionally substituted alkynyl, or optionally substituted aryl.

In some embodiments, R″″ is H, optionally substituted alkyl, optionally substituted alkenyl, optionally substituted alkynyl, optionally substituted alkoxy, optionally substituted aryloxy, optionally substituted amino, or optionally substituted aminooxy.

Non-limiting precursors include those having a formula of (R′)₂Si(OC(O)—R″″)₂, wherein R′ and R″″ can be any described herein.

### Apparatuses

The present disclosure also encompasses apparatuses configured to perform the methods described herein. In one aspect, the apparatus for processing semiconductor substrates, the apparatus includes: at least one process chamber including a pedestal for holding a substrate; at least one outlet for coupling to a vacuum; one or more process gas inlets coupled to one or more organic silicon-containing precursor gas sources; one or more process gas inlets coupled to one or more nitrogen-containing reactant gas sources; and a controller for controlling operations in the apparatus, comprising machine-readable instructions for: introducing an organic silicon-containing precursor gas and a nitrogen-containing reactant gas in temporally separated pulses to form silicon nitride on a surface of the substrate by thermal atomic layer deposition, wherein a pulse of the silicon-containing precursor gas and a pulse of the nitrogen-containing reactant gas constitutes one thermal atomic layer deposition cycle, thereby depositing a film. In one embodiment, a carbon content of the film can be modified by changing a process temperature.

In another aspect, the apparatus for processing semiconductor substrates, the apparatus includes: at least one process chamber including a pedestal for holding a substrate; at least one outlet for coupling to a vacuum; one or more process gas inlets coupled to one or more organic silicon-containing precursor gas sources; one or more process gas inlets coupled to one or more nitrogen-containing reactant gas sources; one or more plasma sources; and a controller for controlling operations in the apparatus, comprising machine-readable instructions for: introducing an organic silicon-containing precursor gas and a nitrogen-containing reactant gas in temporally separated pulses to form silicon nitride on a surface of the substrate by thermal atomic layer deposition, wherein a pulse of the silicon-containing precursor gas and a pulse of the nitrogen-containing reactant gas constitutes one thermal atomic layer deposition cycle; and exposing the surface of the substrate to radical species form the one or more plasma sources. In particular embodiments, the radical species includes a nitrogen-containing radical.

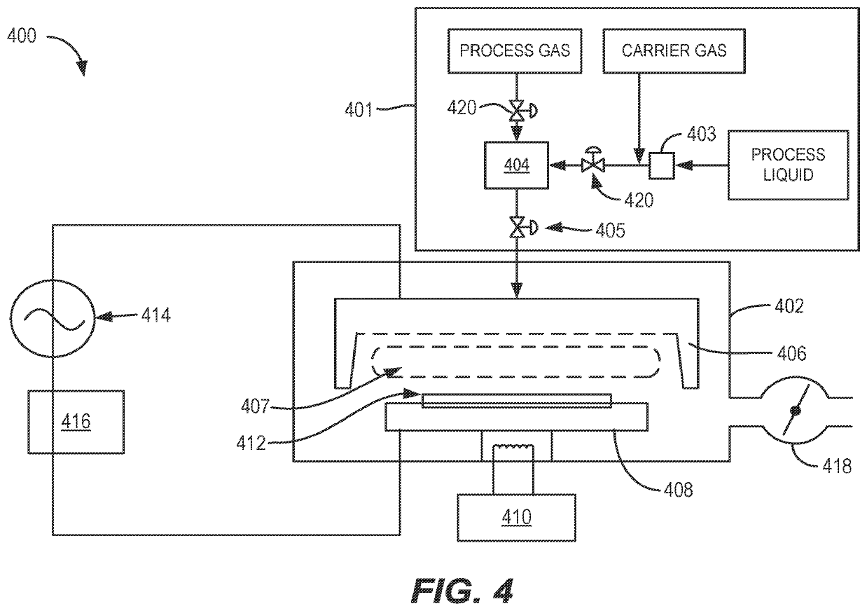

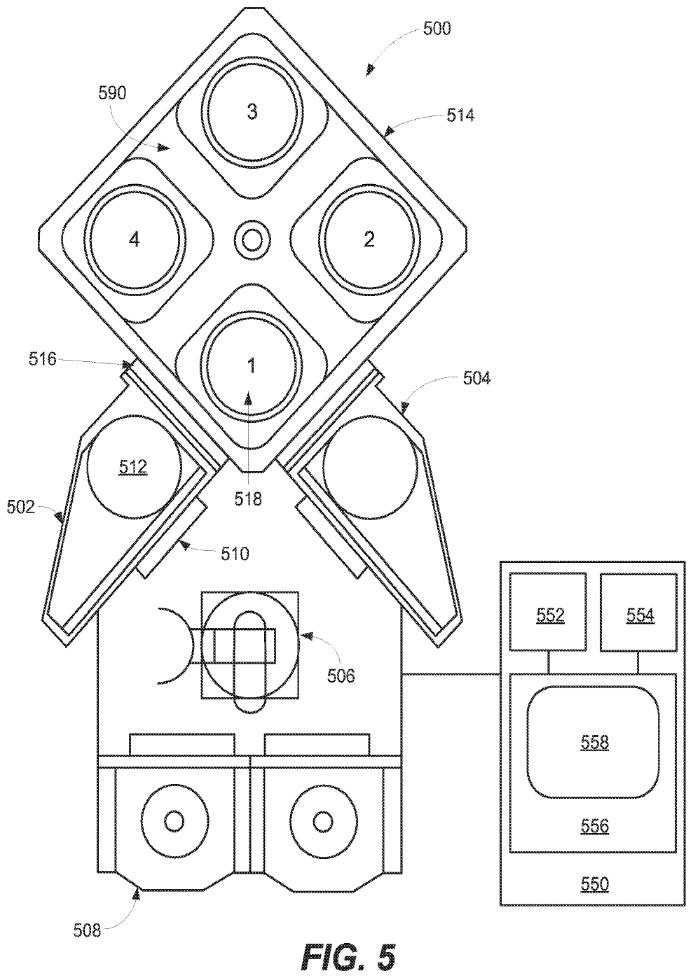

FIG. 4 schematically shows an embodiment of a process station 400 that may be used to deposit material using atomic layer deposition (ALD) and/or chemical vapor deposition (CVD), either of which may be plasma enhanced. For simplicity, the process station 400 is depicted as a standalone process station having a process chamber body 402 for maintaining a low-pressure environment. However, it will be appreciated that a plurality of process stations 400 may be included in a common process tool environment. Further, it will be appreciated that, in some embodiments, one or more hardware parameters of process station 400, including those discussed in detail below, may be adjusted programmatically by one or more computer controllers.

Process station 400 fluidly communicates with reactant delivery system 401 for delivering process gases to a distribution showerhead 406. Reactant delivery system 401 includes a mixing vessel 404 for blending and/or conditioning process gases for delivery to showerhead 406. One or more mixing vessel inlet valves 420 may control introduction of process gases to mixing vessel 404. Similarly, a showerhead inlet valve 405 may control introduction of process gasses to the showerhead 406.

Some reactants, like any silicon-containing precursor herein, may be stored in liquid form prior to vaporization at and subsequent delivery to the process station. For example, the embodiment of FIG. 4 includes a vaporization point 403 for vaporizing liquid reactant to be supplied to mixing vessel 404. In some embodiments, vaporization point 403 may be a heated vaporizer. The reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve sweeping and/or evacuating the delivery piping to remove residual reactant. However, sweeping the delivery piping may increase process station cycle time, degrading process station throughput. Thus, in some embodiments, delivery piping downstream of vaporization point 403 may be heat traced. In some examples, mixing vessel 404 may also be heat traced. In one non-limiting example, piping downstream of vaporization point 403 has an increasing temperature profile extending from approximately 100° C. to approximately 150° C. at mixing vessel 404.

In some embodiments, reactant liquid may be vaporized at a liquid injector. For example, a liquid injector may inject pulses of a liquid reactant into a carrier gas stream upstream of the mixing vessel. In one scenario, a liquid injector may vaporize reactant by flashing the liquid from a higher pressure to a lower pressure. In another scenario, a liquid injector may atomize the liquid into dispersed microdroplets that are subsequently vaporized in a heated delivery pipe. It will be appreciated that smaller droplets may vaporize faster than larger droplets, reducing a delay between liquid injection and complete vaporization. Faster vaporization may reduce a length of piping downstream from vaporization point 403. In one scenario, a liquid injector may be mounted directly to mixing vessel 404. In another scenario, a liquid injector may be mounted directly to showerhead 406.

In some embodiments, a liquid flow controller upstream of vaporization point 403 may be provided for controlling a mass flow of liquid for vaporization and delivery to process station 400. For example, the liquid flow controller (LFC) may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, the LFC may be dynamically switched from a feedback control mode to a direct control mode by disabling a sense tube of the LFC and the PID controller.

Showerhead 406 distributes process gases toward substrate 412. In the embodiment shown in FIG. 4, substrate 412 is located beneath showerhead 406, and is shown resting on a pedestal 408. It will be appreciated that showerhead 406 may have any suitable shape, and may have any suitable number and arrangement of ports for distributing processes gases to substrate 412.

In some embodiments, a microvolume 407 is located beneath showerhead 406. Performing an ALD and/or CVD process in a microvolume rather than in the entire volume of a process station may reduce reactant exposure and sweep times, may reduce times for altering process conditions (e.g., pressure, temperature, etc.), may limit an exposure of process station robotics to process gases, etc. Example microvolume sizes include, but are not limited to, volumes between 0.1 liter and 2 liters. This microvolume also impacts productivity throughput. While deposition rate per cycle drops, the cycle time also simultaneously reduces. In certain cases, the effect of the latter is dramatic enough to improve overall throughput of the module for a given target thickness of film.

In some embodiments, pedestal 408 may be raised or lowered to expose substrate 412 to microvolume 407 and/or to vary a volume of microvolume 407. For example, in a substrate transfer phase, pedestal 408 may be lowered to allow substrate 412 to be loaded onto pedestal 408. During a deposition process phase, pedestal 408 may be raised to position substrate 412 within microvolume 407. In some embodiments, microvolume 407 may completely enclose substrate 412 as well as a portion of pedestal 408 to create a region of high flow impedance during a deposition process.

Optionally, pedestal 408 may be lowered and/or raised during portions the deposition process to modulate process pressure, reactant concentration, etc., within microvolume 407. In one scenario where process chamber body 402 remains at a base pressure during the deposition process, lowering pedestal 408 may allow microvolume 407 to be evacuated. Example ratios of microvolume to process chamber volume include, but are not limited to, volume ratios between 1:100 and 1:10. It will be appreciated that, in some embodiments, pedestal height may be adjusted programmatically by a suitable computer controller.

In another scenario, adjusting a height of pedestal 408 may allow a plasma density to be varied during plasma activation and/or treatment cycles included in the deposition process. At the conclusion of the deposition process phase, pedestal 408 may be lowered during another substrate transfer phase to allow removal of substrate 412 from pedestal 408.

While the example microvolume variations described herein refer to a height-adjustable pedestal, it will be appreciated that, in some embodiments, a position of showerhead 406 may be adjusted relative to pedestal 408 to vary a volume of microvolume 407. Further, it will be appreciated that a vertical position of pedestal 408 and/or showerhead 406 may be varied by any suitable mechanism within the scope of the present disclosure. In some embodiments, pedestal 408 may include a rotational axis for rotating an orientation of substrate 412. It will be appreciated that, in some embodiments, one or more of these example adjustments may be performed programmatically by one or more suitable computer controllers.

Returning to the embodiment shown in FIG. 4, showerhead 406 and pedestal 408 electrically communicate with RF power supply 414 and matching network 416 for powering a plasma. In some embodiments, the plasma energy may be controlled by controlling one or more of a process station pressure, a gas concentration, an RF source power, an RF source frequency, and a plasma power pulse timing. For example, RF power supply 414 and matching network 416 may be operated at any suitable power to form a plasma having a desired composition of radical species. Examples of suitable powers are included above. Likewise, RF power supply 414 may provide RF power of any suitable frequency. In some embodiments, RF power supply 414 may be configured to control high- and low-frequency RF power sources independently of one another. Example low-frequency RF frequencies may include, but are not limited to, frequencies between 50 kHz and 1000 kHz. Example high-frequency RF frequencies may include, but are not limited to, frequencies between 1.8 MHz and 2.45 GHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, the plasma may be controlled via input/output control (IOC) sequencing instructions. In one example, the instructions for setting plasma conditions for a plasma process phase may be included in a corresponding plasma activation recipe phase of a deposition process recipe. In some cases, process recipe phases may be sequentially arranged, so that all instructions for a deposition process phase are executed concurrently with that process phase. In some embodiments, instructions for setting one or more plasma parameters may be included in a recipe phase preceding a plasma process phase. For example, a first recipe phase may include instructions for setting a flow rate of an inert and/or an organic silicon-containing precursor gas, instructions for setting a plasma generator to a power set point, and time delay instructions for the first recipe phase. A second, subsequent recipe phase may include instructions for modulating or stopping a flow rate of an inert and/or a reactant gas, and instructions for modulating a flow rate of a carrier or purge gas and time delay instructions for the second recipe phase. A third recipe phase may include instructions for modulating a flow rate of a nitrogen-containing gas, instructions for modulating the flow rate of a carrier or purge gas, and time delay instructions for the third recipe phase. A fourth, subsequent recipe phase may include instructions for modulating or stopping a flow rate of an inert and/or a reactant gas, and instructions for modulating a flow rate of a carrier or purge gas and time delay instructions for the fourth recipe phase. A fifth, subsequent recipe phase may include instructions for enabling the plasma generator and time delay instructions for the fifth recipe phase. A sixth recipe phase may include instructions for disabling the plasma generator and time delay instructions for the sixth recipe phase. A seventh subsequent recipe phase may include instructions for modulating or stopping a flow rate of an inert and/or a reactant gas, and instructions for modulating a flow rate of a carrier or purge gas and time delay instructions for the seventh recipe phase. It will be appreciated that these recipe phases may be further subdivided and/or iterated in any suitable way within the scope of the present disclosure.

In some deposition processes, plasma strikes last on the order of a few seconds or more in duration. In certain implementations, much shorter plasma strikes may be used. These may be on the order of 10 ms to 1 second, typically, about 20 to 80 ms, with 50 ms being a specific example. Such very short RF plasma strikes require extremely quick stabilization of the plasma.

To accomplish this, the plasma generator may be configured such that the impedance match is set preset to a particular voltage, while the frequency is allowed to float. Conventionally, high-frequency plasmas are generated at an RF frequency at about 13.56 MHz. In various embodiments disclosed herein, the frequency is allowed to float to a value that is different from this standard value. By permitting the frequency to float while fixing the impedance match to a predetermined voltage, the plasma can stabilize much more quickly, a result which may be important when using the very short plasma strikes associated with some types of deposition cycles.

In some embodiments, pedestal 408 may be temperature controlled via heater 410. Further, in some embodiments, pressure control for deposition process station 400 may be provided by butterfly valve 418. As shown in the embodiment of FIG. 4, butterfly valve 418 throttles a vacuum provided by a downstream vacuum pump (not shown). However, in some embodiments, pressure control of process station 400 may also be adjusted by varying a flow rate of one or more gases introduced to process station 400.

FIG. 5 shows a schematic view of an embodiment of a multi-station processing tool 500 with an inbound load lock 502 and an outbound load lock 504, either or both of which may comprise a remote plasma source. A robot 506, at atmospheric pressure, is configured to move wafers from a cassette loaded through a pod 508 into inbound load lock 502 via an atmospheric port 510. A wafer is placed by the robot 506 on a pedestal 512 in the inbound load lock 502, the atmospheric port 510 is closed, and the load lock is pumped down. Where the inbound load lock 502 comprises a remote plasma source, the wafer may be exposed to a remote plasma treatment in the load lock prior to being introduced into a processing chamber 514. Further, the wafer also may be heated in the inbound load lock 502 as well, for example, to remove moisture and adsorbed gases. Next, a chamber transport port 516 to processing chamber 514 is opened, and another robot (not shown) places the wafer into the reactor on a pedestal of a first station shown in the reactor for processing. While the embodiment depicted in FIG. 5 includes load locks, it will be appreciated that, in some embodiments, direct entry of a wafer into a process station may be provided.

The depicted processing chamber 514 comprises four process stations, numbered from 1 to 4 in the embodiment shown in FIG. 5. Each station has a heated pedestal (shown at 518 for station 1), and gas line inlets. It will be appreciated that in some embodiments, each process station may have different or multiple purposes. While the depicted processing chamber 514 comprises four stations, it will be understood that a processing chamber according to the present disclosure may have any suitable number of stations. For example, in some embodiments, a processing chamber may have five or more stations, while in other embodiments a processing chamber may have three or fewer stations.

FIG. 5 also depicts an embodiment of a wafer handling system 590 for transferring wafers within processing chamber 514. In some embodiments, wafer handling system 590 may transfer wafers between various process stations and/or between a process station and a load lock. It will be appreciated that any suitable wafer handling system may be employed. Non-limiting examples include wafer carousels and wafer handling robots. FIG. 5 also depicts an embodiment of a system controller 550 employed to control process conditions and hardware states of process tool 500. System controller 550 may include one or more memory devices 556, one or more mass storage devices 554, and one or more processors 552. Processor 552 may include a CPU or computer, analog and/or digital input/output connections, stepper motor controller boards, etc.

In some embodiments, system controller 550 controls all of the activities of process tool 500. System controller 550 executes system control software 558 stored in mass storage device 554, loaded into memory device 556, and executed on processor 552. System control software 558 may include instructions for controlling the timing, mixture of gases, chamber and/or station pressure, chamber and/or station temperature, purge conditions and timing, wafer temperature, RF power levels, RF frequencies, substrate, pedestal, chuck and/or susceptor position, and other parameters of a particular process performed by process tool 500. System control software 558 may be configured in any suitable way. For example, various process tool component subroutines or control objects may be written to control operation of the process tool components necessary to carry out various process tool processes in accordance with the disclosed methods. System control software 558 may be coded in any suitable computer readable programming language.

In some embodiments, system control software 558 may include input/output control (IOC) sequencing instructions for controlling the various parameters described above. For example, each phase of a hybrid ALD or PEALD process may include one or more instructions for execution by system controller 550. The instructions for setting process conditions for a hybrid ALD or PEALD process phase may be included in a corresponding hybrid ALD or PEALD recipe phase. In some embodiments, the hybrid ALD or PEALD recipe phases may be sequentially arranged, so that all instructions for a hybrid ALD or PEALD process phase are executed concurrently with that process phase.

Other computer software and/or programs stored on mass storage device 554 and/or memory device 556 associated with system controller 550 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 518 and to control the spacing between the substrate and other parts of process tool 500.

A process gas control program may include code for controlling gas composition and flow rates and optionally for flowing gas into one or more process stations prior to deposition in order to stabilize the pressure in the process station. The process gas control program may include code for controlling gas composition and flow rates within any of the disclosed ranges. A pressure control program may include code for controlling the pressure in the process station by regulating, for example, a throttle valve in the exhaust system of the process station, a gas flow into the process station, etc. The pressure control program may include code for maintaining the pressure in the process station within any of the disclosed pressure ranges.

A heater control program may include code for controlling the current to a heating unit that is used to heat the substrate. Alternatively, the heater control program may control delivery of a heat transfer gas (such as helium) to the substrate. The heater control program may include instructions to maintain the temperature of the substrate within any of the disclosed ranges.

A plasma control program may include code for setting RF power levels and frequencies applied to the process electrodes in one or more process stations, for example using any of the RF power levels disclosed herein. The plasma control program may also include code for controlling the duration of each plasma exposure.

In some embodiments, there may be a user interface associated with system controller 550. The user interface may include a display screen, graphical software displays of the apparatus and/or process conditions, and user input devices such as pointing devices, keyboards, touch screens, microphones, etc.

In some embodiments, parameters adjusted by system controller 550 may relate to process conditions. Non-limiting examples include process gas composition and flow rates, temperature, pressure, plasma conditions (such as RF power levels, frequency, and exposure time), etc. These parameters may be provided to the user in the form of a recipe, which may be entered utilizing the user interface.

Signals for monitoring the process may be provided by analog and/or digital input connections of system controller 550 from various process tool sensors. The signals for controlling the process may be output on the analog and digital output connections of process tool 500. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

Any suitable chamber may be used to implement the disclosed embodiments. Example deposition apparatuses include, but are not limited to, apparatus from the ALTUS© product family, the VECTOR® product family, and/or the SPEED® product family, each available from Lam Research Corp., of Fremont, California, or any of a variety of other commercially available processing systems. Two or more of the stations may perform the same functions. Similarly, two or more stations may perform different functions. Each station can be designed/configured to perform a particular function/method as desired.

In some implementations, a controller 550 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

### CONCLUSION

Although the foregoing embodiments have been described in some detail for purposes of clarity of understanding, it will be apparent that certain changes and modifications may be practiced within the scope of the appended claims. Embodiments disclosed herein may be practiced without some or all of these specific details. In other instances, well-known process operations have not been described in detail to not unnecessarily obscure the disclosed embodiments. Further, while the disclosed embodiments will be described in conjunction with specific embodiments, it will be understood that the specific embodiments are not intended to limit the disclosed embodiments. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method of depositing a film, the method comprising:
exposing a substrate within a chamber to an organic silicon-containing precursor;
exposing the substrate to a nitrogen-containing reactant; and
exposing the substrate to a radical species, thereby forming a film comprising silicon nitride.

2. The method of claim 1, wherein the film comprises a doped silicon nitride.

3. The method of claim 2, wherein the doped silicon nitride comprises carbon-doped silicon nitride.

4. The method of claim 1, wherein the film comprises a conformal film.

5. The method of claim 1, wherein the organic silicon-containing
precursor comprises a structure of formula (I):
Si(R′)₄,
wherein at least one R′ includes a carbon atom.

6. The method of claim 1, wherein the organic silicon-containing
precursor comprises a structure of formula (II):
(R′)₃Si-[L-Si(R′)₂]—R′,
wherein at least one R′ includes a carbon atom and L is a linker.

7. The method of claim 1, wherein the nitrogen-containing reactant comprises ammonia (NH₃), singly deuterated ammonia (NH₂D), doubly deuterated ammonia (NHD₂), or triply deuterated ammonia (ND₃).

8. The method of claim 1, wherein said exposing the substrate to the nitrogen-containing reactant comprises providing the nitrogen-containing reactant in the presence of hydrogen (H₂).

9. The method of claim 1, wherein said exposing the substrate to a radical species comprises a source gas selected from the group consisting of ammonia (NH₃), nitrogen (N₂), and hydrogen (H₂).

10. The method of claim 1, wherein the radical species comprises a nitrogen-containing radical in a remote plasma.

11. (canceled)

12. The method of claim 1, further comprising repeating said exposing the substrate to the organic silicon-containing precursor, said exposing the substrate to the nitrogen-containing reactant, and said exposing the substrate to the radical species in cycles to form the film.

13. The method of claim 1, wherein the method comprises a remote plasma-based atomic layer deposition process.

14. A method of depositing a film, the method comprising:
depositing a carbon- and silicon-containing layer on a surface of a substrate, wherein the substrate is provided within a chamber;
thermally converting the carbon- and silicon-containing layer in the presence of a nitrogen-containing reactant to form a doped silicon nitride; and
plasma treating the doped silicon nitride in the presence of a source gas, thereby forming the film.

15. The method of claim 14, wherein said depositing comprises exposing the surface of the substrate to an organic silicon-containing precursor.

16. (canceled)

17. The method of claim 14, wherein said thermally converting comprises exposing the surface of the substrate to the nitrogen-containing reactant.

18. The method of claim 17, wherein the nitrogen-containing reactant comprises ammonia (NH₃) and optionally with hydrogen (H₂).

19. The method of claim 14, wherein said plasma treating comprises exposing the substrate to a radical species within the source gas.

20. The method of claim 19, wherein the radical species comprises a nitrogen-containing radical; and wherein the source gas is selected from the group consisting of ammonia (NH₃), nitrogen (N₂), and hydrogen (H₂).

21. (canceled)

22. The method of claim 14, further comprising repeating said depositing, said thermally converting, and said plasma treating in cycles to form the film.

23. The method of claim 14, wherein the film comprises a conformal, carbon-doped silicon nitride film.
